(19) United States
(12) Patent Application Publication
(10) Pub. No.: US 2022/0326613 A1
(43) Pub. Date: Oct. 13, 2022

(54) PHOTOSENSITIVE TRANSFER MATERIAL AND METHOD OF PRODUCING THE SAME, METHOD OF PRODUCING PATTERNED METAL CONDUCTIVE MATERIAL, FILM, TOUCH PANEL, METHOD OF SUPPRESSING DETERIORATION, AND LAMINATE

(71) Applicant: FUJIFILM Corporation, Tokyo (JP)

(72) Inventors: Keigo UEKI, Shizuoka (JP); Yuichi FUKUSHIGE, Shizuoka (JP); Kentaro TOYOOKA, Shizuoka (JP); Tomoki MATSUDA, Shizuoka (JP); Satoru YAMADA, Shizuoka (JP)

(73) Assignee: FUJIFILM Corporation, Tokyo (JP)

(21) Appl. No.: 17/841,143

(22) Filed: Jun. 15, 2022

Related U.S. Application Data
(63) Continuation of application No. PCT/JP2020/046752, filed on Dec. 15, 2020.

(30) Foreign Application Priority Data
Dec. 18, 2019 (JP) 2019-228174
Feb. 26, 2020 (JP) 2020-030705
Jun. 29, 2020 (JP) 2020-112165
Oct. 5, 2020 (JP) 2020-168543
Nov. 11, 2020 (JP) 2020-188157

(51) Int. Cl. G03F 7/033; G03F 7/11; G03F 7/038

(52) U.S. Cl. CPC G03F 7/033; G03F 7/11; G03F 7/038

(57) ABSTRACT

A photosensitive transfer material including a temporary support, and a photosensitive layer that contains a binder polymer and a compound A containing at least one group selected from the group consisting of a metal reducing group and a metal coordinating group and a method of producing the same, a method of producing a patterned metal conductive material using the photosensitive transfer material, a film including a metal and a resin layer that contains the compound A, a touch panel including the film, and a method of suppressing deterioration in which in a film including a metal and a resin layer, the resin layer contains the compound A.

### CROSS-REFERENCE TO RELATED APPLICATIONS

This application is a Continuation of International Application No. PCT/JP2020/046752 filed on Dec. 15, 2020, which claims priority to Japanese Patent Application No. 2019-228174 filed on Dec. 18, 2019, Japanese Patent Application No. 2020-030705 filed on Feb. 26, 2020, Japanese Patent Application No. 2020-112165 filed on Jun. 29, 2020, Japanese Patent Application No. 2020-168543 filed on Oct. 5, 2020, and Japanese Patent Application No. 2020-188157 filed on Nov. 11, 2020. The entire contents of these applications are incorporated herein by reference.

### BACKGROUND OF THE INVENTION

### 1. Field of the Invention

The present disclosure relates to a photosensitive transfer material and a method of producing the same, a method of producing a patterned metal conductive material, a film, a touch panel, a method of suppressing deterioration, and a laminate.

### 2. Description of the Related Art

In recent years, in electronic devices such as a mobile phone, a car navigator, a personal computer, a ticket vending machine, or a terminal of the bank, a tablet-type input device is disposed on a surface of a liquid crystal device or the like. In such an electronic device, while referring to an instruction image displayed in an image display region of a liquid crystal device, information corresponding to the instruction image can be input by touching a portion where the instruction image is displayed, with a finger or a touch pen.

The input device described above (hereinafter, also referred to as a “touch panel”) includes a resistance film-type input device, a capacitive input device, and the like. A capacitive input device is advantageous in that a transmittance conductive film may be simply formed on one sheet of substrate. As such a capacitive input device, for example, there is a device in which electrode patterns are extended in directions intersecting each other, and which detects an input position by detecting a change of electrostatic capacity between electrodes, in a case where a finger or the like touches.

For the purpose of protecting electrode patterns or lead wires (for example, metal wires such as copper wires) put together on a frame portion, a transparent resin layer is provided in the capacitive input device. A photosensitive resin composition is used as a material for forming such a transparent resin layer.

As a method of suppressing deterioration of a metal in the related art, a method described in JP2016-001608A is known.

In JP2016-001608A, a method of suppressing deterioration of a metal fiber in a film including a metal fiber and a resin layer that contains a metal additive is disclosed.

Furthermore, in the related art, an optical laminate described in WO2015/143383A is known.

In WO2015/143383A, the optical laminate that includes a conductive film including a silver nanowire or a silver mesh pattern, and contains a light stabilizer containing a transition metal salt or a transition metal complex is disclosed.

### SUMMARY OF THE INVENTION

An object to be solved by an embodiment of the present invention is to provide a photosensitive transfer material having excellent moisture-heat resistance of a metal in a case where a photosensitive layer that has been transferred comes into contact with a metal or a layer containing a metal, a method of producing the same, and a method of producing a patterned metal conductive material using the above-described photosensitive transfer material.

An object to be solved by another embodiment of the present invention is to provide a film, a touch panel, and a laminate having excellent moisture-heat resistance of a metal used.

An object to be solved by still another embodiment of the present invention is to provide a method of suppressing deterioration, which is excellent in moisture-heat resistance of a metal used.

The means for achieving the above-described object includes the following aspects.

<1> A photosensitive transfer material including a temporary support and a photosensitive layer that contains a binder polymer and a compound A containing at least one group selected from the group consisting of a metal reducing group and a metal coordinating group.

<2> The photosensitive transfer material according to <1>, in which the compound A includes a compound containing the metal reducing group.

<3> The photosensitive transfer material according to <2>, in which the metal reducing group is an aldehyde group.

<4> The photosensitive transfer material according to any one of <1> to <3>, in which the compound A includes a compound containing the metal coordinating group.

<5> The photosensitive transfer material according to <4>, in which the metal coordinating group is a thioether group.

<6> The photosensitive transfer material according to <4>, in which the metal coordinating group is a mercapto group.

<7> The photosensitive transfer material according to <6>, in which the mercapto group is a mercapto group substituted with an aryl group.

<8> The photosensitive transfer material according to any one of <1> to <7>, in which an I/O ratio of the compound A is 0.20 or more.

<9> The photosensitive transfer material according to any one of <1> to <8>, in which an integrated absorbance value of the compound A at a wavelength range of 250 nm to 400 nm is 0 or more and 30 or less.

<10> The photosensitive transfer material according to any one of <1> to <9>, in which the compound A includes a compound containing a metal reducing group and a metal coordinating group.

<11> The photosensitive transfer material according to any one of <1> to <10>, in which a content of chloride ions of the photosensitive layer is 50 ppm or less with respect to a total mass of the photosensitive layer.

<12> The photosensitive transfer material according to any one of <1> to <11>, in which a content of the compound A of the photosensitive layer is 0.01% by mass or more and 10% by mass or less with respect to a total mass of the photosensitive layer.

<13> The photosensitive transfer material according to any one of <1> to <12>, in which the photosensitive layer contains a hydrogen donating compound.

<14> A method of producing the photosensitive transfer material according to any one of <1> to <13>, the method comprising a step of preparing the temporary support, and a step of forming the photosensitive layer on one side of the temporary support.

<15> The method of producing the photosensitive transfer material according to <14>, further comprising a step of surface-reforming a surface on the one side of the temporary support between the step of preparing the temporary support and the step of forming the photosensitive layer.

<16> A method of producing a patterned metal conductive material comprising, in the following order, a step of transferring at least the photosensitive layer in the photosensitive transfer material according to any one of <1> to <13> to a substrate having a metal conductive material on a surface, a step of performing pattern exposure on the photosensitive layer, and a step of developing the photosensitive layer to form a pattern.

<17> A film comprising a metal, and a resin layer that contains a binder polymer, and a compound A containing at least one group selected from the group consisting of a metal reducing group and a metal coordinating group.

<18> The film according to <17>, in which the compound A includes a compound containing the metal reducing group.

<19> The film according to <18>, in which the metal reducing group is an aldehyde group.

<20> The film according to any one of <17> to <19>, in which the compound A includes a compound containing the metal coordinating group.

<21> The film according to <20>, in which the metal coordinating group is a thioether group.

<22> The film according to <20>, in which the metal coordinating group is a mercapto group.

<23> The film according to <22>, in which the mercapto group is a mercapto group substituted with an aryl group.

<24> The film according to any one of <17> to <23>, in which an I/O ratio of the compound A is 0.20 or more.

<25> The film according to any one of <17> to <24>, in which an integrated absorbance value of the compound A at a wavelength range of 250 nm to 400 nm is 0 or more and 30 or less.

<26> The film according to any one of <17> to <25>, in which the compound A includes a compound containing a metal reducing group and a metal coordinating group.

<27> The film according to any one of <17> to <26>, in which a content of chloride ions of the resin layer is 50 ppm or less with respect to a total mass of the resin layer.

<28> The film according to any one of <17> to <27>, in which a content of the compound A of the resin layer is 0.01% by mass or more and 10% by mass or less with respect to a total mass of the resin layer.

<29> The film according to any one of <17> to <28>, in which the metal is a metal fiber.

<30> The film according to any one of <17> to <29>, in which the metal includes silver.

<31> A touch panel comprising the film according to any one of <17> to <30>.

<32> A method of suppressing deterioration of a metal in a film including the metal and a resin layer, in which the resin layer contains a compound A containing at least one group selected from the group consisting of a metal reducing group and a metal coordinating group.

<33> The method of suppressing deterioration according to <32>, in which the compound A includes a compound containing the metal reducing group.

<34> The method of suppressing deterioration according to <33>, in which the metal reducing group is an aldehyde group.

<35> The method of suppressing deterioration according to any one of <32> to <34>, in which the compound A includes a compound containing the metal coordinating group.

<36> The method of suppressing deterioration according to <35>, in which the metal coordinating group is a thioether group.

<37> The method of suppressing deterioration according to <35>, in which the metal coordinating group is a mercapto group.

<38> The method of suppressing deterioration according to <37>, in which the mercapto group is a mercapto group substituted with an aryl group.

<39> he method of suppressing deterioration according to any one of <32> to <38>, in which an I/O ratio of the compound A is 0.20 or more.

<40> The method of suppressing deterioration according to any one of <32> to <39>, in which an integrated absorbance value of the compound A at a wavelength range of 250 nm to 400 nm is 0 or more and 30 or less.

<41> The method of suppressing deterioration according to any one of <32> to <40>, in which the compound A includes a compound containing a metal reducing group and a metal coordinating group.

<42> The method of suppressing deterioration according to any one of <32> to <41>, in which a content of chloride ions of the resin layer is 50 ppm or less with respect to a total mass of the resin layer.

<43> The method of suppressing deterioration according to any one of <32> to <42>, in which a content of the compound A of the resin layer is 0.01% by mass or more and 10% by mass or less with respect to a total mass of the resin layer.

<44> The method of suppressing deterioration according to any one of <32> to <43>, in which the metal is a metal fiber.

<45> The method of suppressing deterioration according to any one of <32> to <44>, in which the metal includes silver.

<46> A laminate comprising, in the following order, a substrate having a surface on which a metal conductive material is disposed, a resin layer contains a compound A containing at least one group selected from the group consisting of a metal reducing group and a metal coordinating group, and a UV absorbing layer in which an integrated absorbance for each 1 nm in a wavelength range of 300 nm to 400 nm is 10 or more.

<47> The laminate according to <46>, in which the compound A contains at least one group selected from the group consisting of a thioether group and a mercapto group, as the metal coordinating group.

<48> The laminate according to <46> or <47>, in which the compound A has an aromatic ring in a molecule.

According to the embodiment of the present invention, it is possible to provide the photosensitive transfer material having excellent moisture-heat resistance of a metal in a case where a photosensitive layer that has been transferred comes into contact with a metal or a layer containing a metal, a method of producing the same, and the method of producing a patterned metal conductive material using the above-described photosensitive transfer material.

According to another embodiment of the present invention, it is possible to provide the film, the touch panel, and the laminate having excellent moisture-heat resistance of a metal used.

According to still another embodiment of the present invention, it is possible to provide the method of suppressing deterioration, which is excellent in moisture-heat resistance of a metal used.

### BRIEF DESCRIPTION OF THE DRAWINGS

FIG. 1 is a schematic cross-sectional view showing an example of a photosensitive transfer material according to the present disclosure.

FIG. 2 is a schematic cross-sectional view showing another example of the photosensitive transfer material according to the present disclosure.

FIG. 3 is a schematic cross-sectional view showing still another example of the photosensitive transfer material according to the present disclosure.

FIG. 4 is a schematic cross-sectional view showing one specific example of a touch panel according to the present disclosure.

FIG. 5 is a schematic cross-sectional view showing another specific example of the touch panel according to the present disclosure.

FIG. 6 is a schematic plane view showing another specific example of the touch panel according to the present disclosure.

FIG. 7 is a cross-sectional view taken along line A-A of FIG. 6.

### DESCRIPTION OF THE PREFERRED EMBODIMENTS

Hereinafter, the contents of the present disclosure will be described in detail. The configuration elements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in the present specification, the upper limit value or the lower limit value described in one range of numerical values may be replaced with an upper limit value or a lower limit value of the range of numerical values described in other stages. In addition, in a range of numerical values described in the present specification, the upper limit value or the lower limit value of the range of numerical values may be replaced with values shown in the examples.

Regarding a term, group (atomic group) of the present disclosure, a term with no description of “substituted” and “unsubstituted” includes both a group not containing a substituent and a group containing a substituent. For example, an “alkyl group” not only includes an alkyl group not containing a substituent (unsubstituted alkyl group), but also an alkyl group containing a substituent (substituted alkyl group).

In addition, in the present disclosure, “% by mass” is identical to “% by weight” and “part by mass” is identical to “part by weight”.

Further, in the present disclosure, a combination of two or more preferred aspects is the more preferred aspects.

In the present disclosure, in a case where a plurality of substances corresponding to components are present in a composition, an amount of each component in the composition means a total amount of the plurality of substances present in the composition, unless otherwise noted.

In the present disclosure, a term “step” not only includes an independent step, but also includes a step, in a case where the step may not be distinguished from the other step, as long as the expected object of the step is achieved.

In the present disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number-average molecular weight (Mn) of the present disclosure, unless otherwise noted, are detected by a gel permeation chromatography (GPC) analysis device using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the present disclosure, unless otherwise specified, a molecular weight of a compound having a molecular weight distribution is a weight-average molecular weight.

In the present disclosure, unless otherwise specified, a ratio of constitutional units of a polymer is a molar ratio.

In the present disclosure, unless otherwise specified, a refractive index is a value at a wavelength of 550 nm measured at 25° C. with an ellipsometer.

Hereinafter, the present disclosure will be described in detail.

(Photosensitive Transfer Material)

A photosensitive transfer material according to the embodiment of the present disclosure (hereinafter, also simply referred to as a “transfer material”) includes a temporary support and a photosensitive layer that contains a binder polymer and a compound A (simply, referred to as a “compound A”) containing at least one group selected from the group consisting of a metal reducing group and a metal coordinating group.

As a result of intensive research conducted by the present inventor, the present inventor has employed the above-described configuration to found that it is possible to provide a photosensitive transfer material having excellent moisture-heat resistance of a metal in a case where a photosensitive layer that has been transferred comes into contact with a metal or a layer containing a metal.

The action mechanism of the excellent effects obtained by employing the above-described configuration is not clear, but is presumed as follows:

the photosensitive layer contains the compound A, the photosensitive layer is transferred to a metal or a layer containing a metal, the compound A moves in the photosensitive layer to adhere to the metal or to exist in the vicinity thereof, or the compound A is diffused in the transferred layer containing the metal, and the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed.

<Temporary Support>

The photosensitive transfer material according to the embodiment of the present disclosure includes a temporary support.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxial stretching polyethylene terephthalate film), a cellulose triacetate film, a polystyrene film, a polyimide film, and a polycarbonate film.

Among these, as the temporary support, a biaxial stretching polyethylene terephthalate film is particularly preferable.

In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

The total light transmittance of the temporary support is preferably 80% or more, and more preferably 85% or more.

From the viewpoint of pattern formation during pattern exposure through the temporary support and transparency of the temporary support, it is preferable that the haze of the temporary support is small. Specifically, the haze value of the temporary support is preferably 2% or less, more preferably 0.5% or less, and particularly preferably 0.1% or less.

From the viewpoint of pattern formation during pattern exposure through the temporary support and transparency of the temporary support, it is preferable that the number of fine particles, foreign substances, and defects included in the temporary support is small. The number of fine particles, foreign substances, and defects having a diameter of 1 μm or more is preferably 50 pieces/10 mm² or less, more preferably 10 pieces/10 mm² or less, still more preferably 3 pieces/10 mm² or less, and particularly preferably 0 pieces/10 mm².

From the viewpoint of imparting handleability, a layer (lubricant layer) containing fine particles may be provided on the surface of the temporary support. The lubricant layer may be provided on one surface of the temporary support, or on both surfaces thereof. The diameter of each of the particles included in the lubricant layer can be, for example, 0.05 μm to 0.8 μm. In addition, the layer thickness of the lubricant layer can be, for example, 0.05 μm to 1.0 μm.

The thickness of the temporary support is not particularly limited, but is preferably 5 μm to 200 μm. In addition, from the viewpoint of ease of handling and general-purpose properties, the thickness of the temporary support is more preferably 10 μm to 150 μm and still more preferably 10 to 50 μm.

Preferred aspects of the temporary support are described in, for example, paragraphs 0017 and 0018 of JP2014-85643A, paragraphs 0019 to 0026 of JP2016-27363A, paragraphs 0041 to 0057 of WO2012/081680A, and paragraphs 0029 to 0040 of WO2018/179370A, and the contents of these publications are incorporated in the present specification.

Examples of the temporary support include LUMIRROR (registered trademark) 16FB40 and LUMIRROR (registered trademark) 16QS62 (16KS40) (all of which are Toray Industries, Inc.), and COSMOSHINE (registered trademark) A4100, COSMOSHINE (registered trademark) A4300, and COSMOSHINE (registered trademark) A8300 (all of which are TOYOBO Co., Ltd.).

In addition, particularly preferred aspects of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

In order to improve the adhesiveness between the temporary support and the photosensitive layer, a contact surface side of the temporary support where the temporary support comes into contact with the photosensitive layer may be subjected to surface-reforming by ultraviolet (UV) irradiation, corona discharge, plasma, or the like.

In a case where the surface-reforming is carried out by the UV irradiation, the exposure amount is preferably 10 mJ/cm² to 2,000 mJ/cm², more preferably 50 mJ/cm² to 1,000 mJ/cm², still more preferably 50 mJ/cm² to 500 mJ/cm², and particularly preferably 50 mJ/cm² to 200 mJ/cm². By the exposure amount being within the above range, the adhesiveness between the photosensitive layer and the temporary support and peelability of the protective film are excellent.

Examples of a light source for the UV irradiation include a low pressure mercury lamp, a high pressure mercury lamp, a super high pressure mercury lamp, a carbon arc lamp, a metal halide lamp, a xenon lamp, a chemical lamp, an electrodeless discharge lamp, and a light emitting diode (LED), all of which emit light in a wavelength range of 150 nm to 450 nm.

The irradiation amount of light is not particularly limited, and is preferably an amount within the above exposure amount range. The lamp output and the illuminance are not particularly limited.

<Photosensitive Layer>

The photosensitive transfer material according to the embodiment of the present disclosure includes the binder polymer and the photosensitive layer containing the compound A on the temporary support, and the compound A is a compound containing at least one group selected from the group consisting of a metal reducing group and a metal coordinating group.

The photosensitive layer may be a negative-type photosensitive layer or a positive photosensitive layer, but is preferably a negative-type photosensitive layer.

<<Compound A>>

The photosensitive layer contains the compound A having at least one group selected from the group consisting of a metal reducing group and a metal coordinating group.

From the viewpoint of moisture-heat resistance of metal, the above-described compound A is preferably a compound having a metal reducing group.

Since the above-described compound A has a metal reducing group, it is presumed that ionization of metals can be suppressed and moisture-heat resistance of metals, particularly metal electrodes, can be improved.

From the viewpoint of moisture-heat resistance of metal, the above-described compound A is preferably a compound having a metal coordinating group.

Since the above-described compound A has a metal coordinating group, it is presumed that it is possible to suppress approach of harmful substances such as halogens to metals and oxidation and ionization of metals, and to improve moisture-heat resistance of metal electrodes.

In addition, from the viewpoint of moisture-heat resistance of metal, the above-described compound A is preferably a compound having a metal reducing group and a metal coordinating group.

Since the compound A has both the metal reducing group and the metal coordinating group, in addition to the above-described effects, reducing property of the metal reducing group can be exhibited in the vicinity of the metal due to coordination of the metal coordinating group to the metal. Therefore, the moisture-heat resistance of the metal can be improved more effectively.

It is sufficient that the above-described metal reducing group is a group capable of reducing at least one target metal.

Examples of the above-described metal reducing group include groups with triple bonds such as aldehyde groups, amino groups, acetylene groups, and propargyl groups; a residue in which one hydrogen atom is removed from at least one compound selected from the group consisting of hydroxylamines, hydroxamic acids, hydroxyureas, hydroxyurethanes, hydroxysemicarbazides, reductones (including reductone derivatives), anilines, phenols (including polyphenols such as chroman-6-ols, 2,3-dihydrobenzofuran-5-ols, aminophenols, sulfonamidephenols, hydroquinones, catechols, resorcinols, benzenetriols, and bisphenols), acylhydrazines, carbamoylhydrazines, and 3-pyrazolidones.

Among these, as the above-described metal reducing group, from the viewpoint of metal reducing ability and moisture-heat resistance of metal, an aldehyde group or a primary to tertiary amino group is preferable, an aldehyde group or a primary amino group is more preferable, and an aldehyde group is particularly preferable.

It is sufficient that the above-described metal coordinating group is a group which directly coordinates with at least one target metal or a group which promotes coordination with the metal.

Specific examples of the above-described metal coordinating group include a mercapto group (or a salt thereof), a thione group (—C(═S)—), a heterocyclic group containing at least one atom selected from the group consisting of a nitrogen atom, a sulfur atom, a selenium atom, and a tellurium atom, a thioether group, a disulfide group, a cationic group, and an ethynyl group.

The mercapto group (or a salt thereof) in the above-described metal coordinating group is preferably a mercapto group (or a salt thereof) which is substituted with a heterocyclic group, an aryl group, or an alkyl group, more preferably a mercapto group (or a salt thereof) which is substituted with a heterocyclic group or an aryl group, still more preferably a mercapto group (or a salt thereof) which is substituted with an aromatic heterocyclic group or an aryl group, and particularly preferably a mercapto group which is substituted with an aryl group.

The heterocyclic group is an aromatic or non-aromatic heterocyclic group, which is monocyclic or fused and has at least 5- to 7-membered ring, and examples thereof include an imidazole ring group, a thiazole ring group, an oxazole ring group, a benzimidazole ring group, a benzothiazole ring group, a benzoxazole ring group, a triazole ring group, a thiadiazole ring group, an oxadiazole ring group, a tetrazole ring group, a purine ring group, a pyridine ring group, a quinoline ring group, an isoquinoline ring group, a pyrimidine ring group, and a triazine ring group. In addition, the heterocyclic group may be a heterocyclic group containing a quaternized nitrogen atom, and in this case, the substituted mercapto group may be dissociated to be mesoionic.

In a case where the mercapto group forms a salt, examples of a counter ion include cations of alkali metals, alkaline earth metals, and heavy metals (such as L⁺, N⁺, K⁺, Mg²⁺, Ag⁺, or Zn²⁺), an ammonium ion, a heterocyclic group containing a quaternized nitrogen atom, and a phosphonium ion.

In addition, the mercapto group in the above-described metal coordinating group may be tautomerized to be a thione group.

The thione group in the above-described metal coordinating group also includes a chain or cyclic thioamide group, a thioureide group, a thiourethane group, or a dithiocarbamic acid ester group.

The heterocyclic group containing at least one atom selected from the group consisting of a nitrogen atom, a sulfur atom, a selenium atom, and a tellurium atom in the metal coordinating group is a nitrogen-containing heterocyclic group having a —NH— group as a partial structure of the heterocyclic ring capable of forming an iminoated metal, or a heterocyclic group having a “—S—” group or a “—Se—” group or a “—Te—” group or a “═N—” group as a partial structure of the heterocyclic ring, which can be coordinated to a metal ion by a coordination bond, and former examples include a benzotriazole group, a triazole group, an indazole group, a pyrazole group, a tetrazole group, a benzimidazole group, an imidazole group, a purine group, and the like, and latter examples include a thiophene group, a thiazole group, an oxazole group, a benzothiophene group, a benzothiazole group, a benzoxazole group, a thiadiazole group, an oxadiazole group, a triazine group, a selenoazole group, a benzoselenoazole group, a tellurazole group, a benzotellurazole group, and the like.

Examples of the thioether group (sulfide group) or disulfide group in the above-described metal coordinating group include all groups having a partial structure of —S— or —S—S—. Examples of the thioether group or disulfide group include an alkylthio group, an arylthio group, an alkyldisulfide group, and an aryldisulfide group.

The cationic group in the above-described metal coordinating group is preferably a group having a cation on the nitrogen atom. Specific examples thereof include a primary to quaternary ammonio group and a group which includes a nitrogen-containing heterocyclic group containing a quaternized nitrogen atom. Examples of the nitrogen-containing heterocyclic group containing a quaternized nitrogen atom include a pyridinio group, a quinolinio group, an isoquinolinio group, and an imidazolio group.

The ethynyl group in the above-described metal coordinating group means a —CCH group, and the hydrogen atom in the —CCH group may be substituted.

In addition, the above-described metal coordinating group may have any substituent.

Furthermore, specific examples of the above-described metal coordinating group include those described in pages 4 to 7 of the specification of JP1999-95355A (JP-H11-95355A).

Among these, as the above-described metal coordinating group, from the viewpoint of coordination ability to metal and moisture-heat resistance of metal, the thioether group, the mercapto group, or the heterocyclic group containing at least one atom selected from the group consisting of a nitrogen atom, a sulfur atom, a selenium atom, and a tellurium atom is preferable, the thioether group, the mercapto group, or the heterocyclic group containing at least one atom selected from the group consisting of a nitrogen atom and a sulfur atom is more preferable, and the thioether group or the mercapto group is still more preferable.

The molecular weight of the above-described compound A is preferably 100 to 10,000, more preferably 120 to 1,000, and still more preferably 120 to 500. By setting the molecular weight of the above-described compound A within the above-described range, volatilization of the compound A in the producing process and durability test can be suppressed, diffusivity in the photosensitive layer and the layer that has been transferred and has come into contact is also excellent, and the moisture-heat resistance of the metal is more excellent.

The I/O ratio (ratio of the inorganicity value (I value) to the organicity value (0 value)) of the compound A is not particularly limited, but is preferably 0.20 to 1.50, more preferably 0.20 to 1.00, still more preferably 0.25 to 1.00, and particularly preferably 0.35 to 1.0 in terms of moisture-heat resistance. By having the I/O ratio of the compound A within the above range, the compound A can be uniformly compatible with the photosensitive layer, can be efficiently diffused into the layer that has been transferred and has come into contact, and is more excellent in the moisture-heat resistance of the metal.

The I/O ratio is calculated by a calculation method in the organic conceptual diagram. The organic conceptual diagram was proposed by Fujita and others and is an effective method of predicting various physicochemical properties from chemical structures of organic compounds (see Organic Conceptual Diagram—Basic and Application—authored by Yoshio Koda, Sankyo Publishing Co., Ltd. (1984)). Polarity of an organic compound depends on the number of carbon atoms or substituents thereof. Therefore, based on a case where the organicity value of a methylene group is regarded as being 20 and the inorganicity value of a hydroxyl group is regarded as being 100, the organicity values and inorganicity values of other substituents are determined, and the organicity values and inorganicity values of organic compounds are calculated. An organic compound having a large inorganicity value has high polarity, and an organic compound having a large organicity value has low polarity.

The specific calculation method of the I value, the 0 value, and the I/O ratio is published as an organic conceptual diagram calculation sheet for Excel (http://www.ecosci.jp/sheet/orgs_help.html), which is authored by Homma and others who is the co-author of “New Edition Organic Conceptual Diagram Basic and Application”, and the calculation can be performed by using this.

From the viewpoint of Xe durability of a metal, the compound A preferably does not have an absorption in a wavelength range of 250 nm to 400 nm.

In the compound A, the sum of absorbance at 250 nm to 400 nm measured by a method described later is preferably 0 to 30, more preferably 0 to 20, and still more preferably 0 to 5. By setting the sum of absorbances of the compound A within the above range, decomposition of the compound A due to Xe exposure can be suppressed, and the moisture-heat resistance of the metal is more excellent.

Since the xenon (Xe) lamp has a distribution close to a spectral energy distribution of sunlight, excellent durability against Xe exposure (Xe durability) also indicates high durability against sunlight.

From the viewpoint of moisture-heat resistance of metal, the number of metal reducing groups in the above-described compound A is preferably 1 or more, more preferably 1 to 6, still more preferably 1 to 3, and particularly preferably 1. In a case where the number of metal reducing groups is 2 or more, the metal reducing groups may be the same or different groups.

From the viewpoint of moisture-heat resistance of metal, the number of metal coordinating groups in the above-described compound A is preferably 1 or more, more preferably 1 to 6, still more preferably 1 to 3, and particularly preferably 1. In a case where the number of metal coordinating groups is 2 or more, the metal coordinating groups may be the same or different groups.

From the viewpoint of moisture-heat resistance of metal, as the above-described compound A, a compound represented by Formula (D1) is preferable, and a compound represented by Formula (D2) is more preferable.

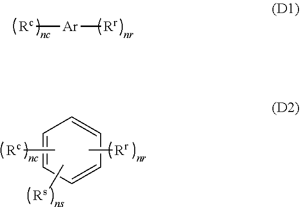

In Formulae D1 and D2, Ar represents a group obtained by removing (nr+nc) hydrogen atoms on an aromatic ring or an aromatic heterocyclic ring from an aromatic ring compound or an aromatic heterocyclic compound, R^{r}'s each independently represent a metal reducing group, R^{c}'s each independently represent a metal coordinating group, R^{s}'s each independently represent a substituent, nr represents an integer of 0 to 3, nc represents an integer of 0 to 3, ns represents an integer of 0 or more, a value of nr+nc is an integer of 1 to 6, and in Formula D2, a value of nr+nc+ns is an integer of 1 to 6.

Ar is preferably a group obtained by removing (nr+nc) hydrogen atoms on an aromatic ring or a heterocyclic ring from benzene, naphthalene, anthracene, phenanthrene, thiadiazole, thiazole, or benzotriazole, which may have a substituent, and more preferably a group obtained by removing (nr+nc) hydrogen atoms on an aromatic ring from benzene or naphthalene, which may have a substituent. The substituent in Ar is not particularly limited, and preferred examples thereof include substituents in R^{s}, which will be described later.

Preferred examples of the metal reducing group in R^{r} include the above-described metal reducing groups.

Preferred examples of the metal coordinating group in R^{c} include the above-described metal coordinating groups.

The substituent in R^{s} is not particularly limited as long as it is a group other than the above-described metal reducing group and the above-described metal coordinating group, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, and a nitro group.

nr is preferably an integer of 1 to 3, more preferably 1 or 2, and particularly preferably 1.

nc is preferably an integer of 1 to 3, more preferably 1 or 2, and particularly preferably 1.

ns is preferably an integer of 0 to 4 and more preferably an integer of 0 to 2.

From the viewpoint of the moisture-heat resistance of the metal and the Xe durability, the compound A is preferably a compound having one or more thioether bonds and two or more ester bonds, more preferably a compound having one or more thioether bonds and two ester bonds, and still more preferably a compound represented by the following Formula D3.

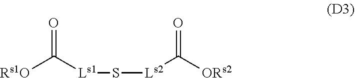

In Formula D3, R^{s1} and R^{s2} each independently represent an alkyl group, and L^{s1} and L^{s2} each independently represent an alkylene group or a group obtained by one or more thioether bonds and two or more alkylene groups being bonded to each other.

From the viewpoint of the moisture-heat resistance, Xe durability, and temporal stability of the metal, R^{s1} and R^{s2} are each independently preferably an alkyl group having 1 to 20 carbon atoms, more preferably an alkyl group having 1 to 12 carbon atoms, and still more preferably an alkyl group having 1 to 7 carbon atoms.

The alkyl group in R^{s1} and R^{s2} may be a linear alkyl group, a branched alkyl group, or an alkyl group having a ring structure, but from the viewpoint of the moisture-heat resistance and Xe durability of the metal, a linear or branched alkyl group is preferable, and a linear alkyl group is more preferable.

From the viewpoint of the moisture-heat resistance, Xe durability, and temporal stability of the metal, L^{s1} and L^{s2} are each independently preferably an alkylene group or a group obtained by one thioether bond and two alkylene groups being bonded to each other, and more preferably an alkylene group.

The alkylene group in L^{s1} and L^{s2} may be a linear alkylene group, a branched alkylene group, or an alkylene group having a ring structure, but from the viewpoint of the moisture-heat resistance and Xe durability of the metal, a linear or branched alkylene group is preferable, and a linear alkylene group is more preferable.

From the viewpoint of the moisture-heat resistance and Xe durability of the metal, the alkylene group in L^{s1} and L^{s2} preferably has 1 to 8 carbon atoms, more preferably has 1 to 3 carbon atoms, and particularly preferably has 2 carbon atoms.

The photosensitive layer may contain only one kind of compound A, or may contain two or more kinds of compounds A.

A content of the compound A in the photosensitive layer is preferably 0.01% by mass to 10% by mass, more preferably 1.0% by mass to 10% by mass, still more preferably 1.0% by mass to 6.0% by mass, and particularly preferably 2.0% by mass to 4.0% by mass with respect to a total mass of the above-described photosensitive layer. By setting the content of the compound A within the above-described range, the moisture-heat resistance of the metal can be improved.

In a case where the compound A has a mercapto group as the metal coordinating group, the content of the compound A in the photosensitive layer is preferably 0.001% by mass to 1.0% by mass, more preferably 0.01% by mass to 1.0% by mass, still more preferably 0.01% by mass to 0.5% by mass, and particularly still more preferably 0.05% by mass to 0.3% by mass with respect to a total mass of the above-described photosensitive layer.

The present inventors presume that a mercapto group has a strong coordinating power with respect to a metal and can contribute to obtain an effect of improving the moisture-heat resistance even at a low content.

The compound A used in the present disclosure will be exemplified below, the present disclosure is not limited thereto.

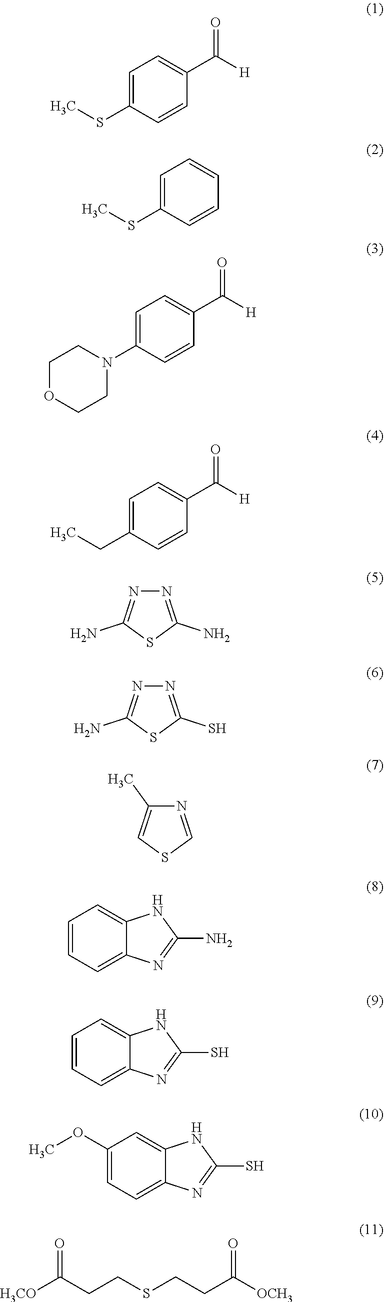

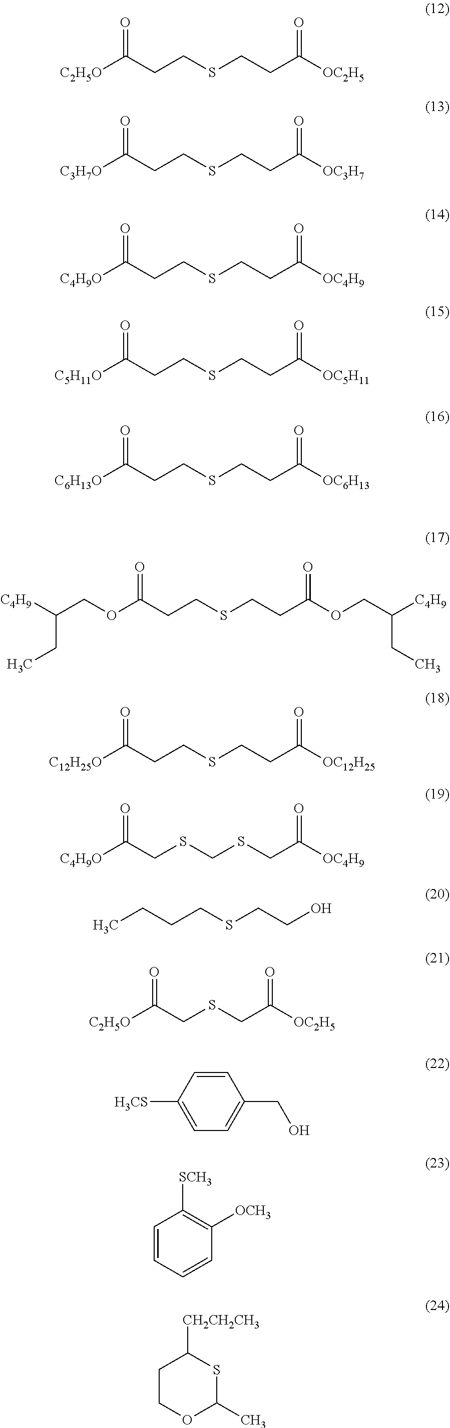

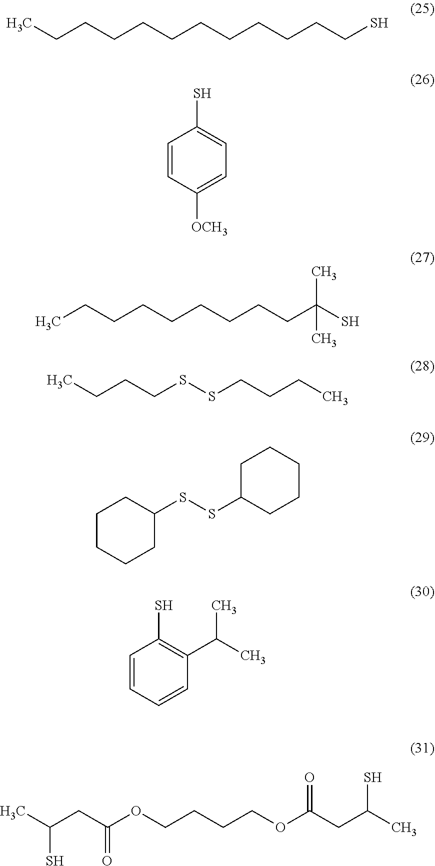

Examples of the compound A containing a mercapto group include alkylthiol compounds such as 1-octanethiol, 1-nonanethiol, 1-decanethiol, 1-undecanethiol, 1-dodecanethiol, tert-dodecyl mercaptan, 2,4,6-trimethyl-2-nonanethiol, 2,3,3,4,4,5-hexamethyl-2-hexanethiol, 1-tridecanethiol, 1-tetradecanethiol, 1-pentadecanethiol, 1-hexadecanethiol, 1-heptadecanethiol, 1-octadecanethiol, and 1-nonadecanethiol; thiol compounds containing an ester bond such as 3-mercaptohexyl acetate, Karenz (registered trademark) MT-BD1, Karenz (registered trademark) MT-TPMB, and Karenz (registered trademark) MT-PE1 (all of which are manufactured by SHOWA DENKO K.K.); aromatic thiol compounds such as 4-methoxybenzene thiol, 2-isopropylbenzene thiol, 5-tert-butyl-2-methylbenzene thiol, biphenyl-4-thiol, 9-mercaptofluorene, 1-naphthalene thiol, 2-naphthalene thiol, and 9-anthracene thiol.

Since the compound A containing a mercapto group can suppress a reaction between an ethylenically unsaturated compound and the mercapto group, an aromatic thiol compound, a secondary thiol compound, or a tertiary thiol compound is preferably used from the viewpoint of preservation stability of the photosensitive transfer material.

Furthermore, preferable examples of the compound A in the present disclosure also include specific compounds 1 to 30 and 1″-1 to 1″-77 described in pages 73 to 87 of EP1308776A2.

<<Binder Polymer>>

The photosensitive layer contains a binder polymer, and preferably contains the binder polymer and a polymerizable compound from the viewpoint of adhesiveness to the metal and hardness of the obtained resin layer on which a pattern has been formed. In addition, in a case where the photosensitive layer does not include a polymerizable compound, the binder polymer preferably includes a binder polymer having a polymerizable group (preferably, an ethylenically unsaturated group).

From the viewpoint of developability, the binder polymer preferably includes an alkali-soluble resin and is more preferably an alkali-soluble resin.

In the present disclosure, the “alkali-soluble” means that the solubility in 100 g of aqueous solution of 1% by mass sodium carbonate at 22° C. is 0.1 g or more.

From a viewpoint of developability, for example, the binder polymer is preferably a binder polymer having an acid value of 60 mgKOH/g or more and more preferably an alkali-soluble resin having an acid value of 60 mgKOH/g or more.

In addition, from the viewpoint that it is easy to form a robust film by thermally crosslinking with a crosslinking component by heating, for example, the binder polymer is still more preferably a resin (so-called a carboxy group-containing resin) having an acid value of 60 mgKOH/g or more and having a carboxy group, and particularly preferably a (meth)acrylic resin (so-called a carboxy group-containing (meth)acrylic resin) having an acid value of 60 mgKOH/g or more and having a carboxy group.

In a case where the binder polymer is a resin having a carboxy group, for example, the three-dimensional crosslinking density can be increased by adding blocked isocyanate and thermally crosslinking. In addition, in a case where the carboxy group of the resin having a carboxy group is dehydrated and hydrophobized, moisture-heat resistance can be improved.

The carboxy group-containing (meth)acrylic resin (hereinafter, also referred to as a “specific polymer A”) having an acid value of 60 mgKOH/g or more is not particularly limited as long as the above-described conditions of acid value are satisfied, and a known (meth)acrylic resin can be appropriately selected and used.

For example, a carboxy group-containing (meth)acrylic resin having an acid value of 60 mgKOH/g or more among polymers described in paragraph 0025 of JP2011-95716A, a carboxy group-containing (meth)acrylic resin having an acid value of 60 mgKOH/g or more among polymers described in paragraphs 0033 to 0052 of JP2010-237589A, and the like can be preferably used as the specific polymer A in the present disclosure.

Here, the (meth)acrylic resin indicates to a resin containing at least one of a constitutional unit derived from (meth)acrylic acid or a constitutional unit derived from a (meth)acrylic acid ester.

A total ratio of the constitutional unit derived from (meth)acrylic acid and the constitutional unit derived from (meth)acrylic acid ester in the (meth)acrylic resin is preferably 30 mol % or more and more preferably 50 mol % or more.

The polymer A may have any of a linear structure, a branched structure and an alicyclic structure in the side chain.

The copolymerization ratio of the monomer having a carboxy group in the specific polymer A is preferably 5% by mass to 50% by mass, more preferably 5% by mass to 40% by mass, and still more preferably 10% by mass to 30% by mass with respect to 100% by mass of the specific polymer A.

In addition, from a viewpoint of moisture permeability and hardness after curing, the binder polymer (particularly, the specific polymer A) preferably has a constitutional unit having an aromatic ring.

Examples of a monomer forming the constitutional unit having an aromatic ring include a monomer having an aralkyl group, styrene, and a polymerizable styrene derivative (for example, methylstyrene, vinyltoluene, tert-butoxystyrene, acetoxystyrene, 4-vinylbenzoic acid) styrene dimer, styrene trimer, and the like). Among these, a monomer having an aralkyl group or styrene is preferable.

Examples of the aralkyl group include a substituted or unsubstituted phenylalkyl group, and a substituted or unsubstituted benzyl group is preferable.

Examples of the monomer having a phenylalkyl group other than the benzyl group include phenylethyl (meth)acrylate and the like.

Examples of the monomer having a benzyl group include (meth)acrylate having a benzyl group, for example, benzyl (meth)acrylate, chlorobenzyl (meth)acrylate, and the like; a vinyl monomer having a benzyl group, for example, vinylbenzyl chloride, vinylbenzyl alcohol, and the like. Among these, benzyl (meth)acrylate is preferable.

The constitutional unit having an aromatic ring is preferably a constitutional unit derived from a styrene compound.

In a case where the binder polymer includes the constitutional unit having an aromatic ring, the content of the constitutional unit having an aromatic ring is preferably 5% by mass to 90% by mass, more preferably 10% by mass to 70% by mass, and still more preferably 20% by mass to 50% by mass with respect to a total mass of the binder polymer.

In addition, the binder polymer (particularly the specific polymer A) preferably contains a constitutional unit having an aliphatic cyclic skeleton from a viewpoint of tackiness and hardness after curing. The aliphatic cyclic skeleton may be a monocyclic skeleton or a polycyclic skeleton.

Examples of a monomer forming the constitutional unit having an aliphatic cyclic skeleton include dicyclopentanyl (meth)acrylate, cyclohexyl (meth)acrylate, and isobornyl (meth)acrylate.

Examples of an aliphatic ring included in the constitutional unit having an aliphatic cyclic skeleton include a cyclohexane ring, an isophorone ring, and a tricyclodecane ring.

Among these, a tricyclodecane ring is particularly preferable as the aliphatic ring included in the constitutional unit having an aliphatic cyclic skeleton.

In a case where the binder polymer includes the constitutional unit having an aliphatic cyclic skeleton, the content of the constitutional unit having an aliphatic cyclic skeleton is preferably 5% by mass to 90% by mass, more preferably 10% by mass to 80% by mass, and still more preferably 20% by mass to 70% by mass with respect to a total mass of the binder polymer.

In addition, from the viewpoint of tackiness and hardness after curing, the binder polymer (particularly, the specific polymer A) preferably has a reactive group.

As the reactive group, a radically polymerizable group is preferable, and an ethylenically unsaturated group is more preferable. In addition, in a case where the binder polymer (particularly, the specific polymer A) has an ethylenically unsaturated group, the binder polymer (particularly, the specific polymer A) preferably includes a constitutional unit having an ethylenically unsaturated group in the side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryl group and more preferably a (meth)acryloxy group.

In a case where the binder polymer includes the constitutional unit having an ethylenically unsaturated group, the content of the constitutional unit having an ethylenically unsaturated group is preferably 5% by mass to 70% by mass, more preferably 10% by mass to 50% by mass, and still more preferably 20% by mass to 40% by mass with respect to a total mass of the binder polymer.

Examples of a method of introducing the reactive group into the specific polymer A include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, or the like.

Preferred examples of the method of introducing the reactive group into the specific polymer A include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain (for example, a compound A and compound B shown below) can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the specific polymer A, the following compounds A and C are preferable, and a compound B is more preferable. The content ratio of each constitutional unit shown below can be appropriately changed according to the purpose. In the compounds A to C, each copolymerization ratio is a mass ratio.

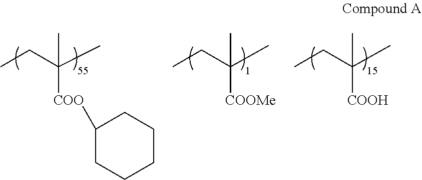

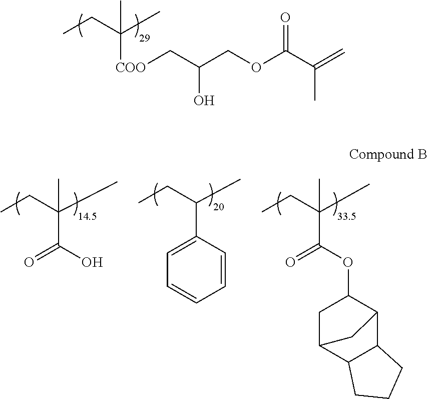

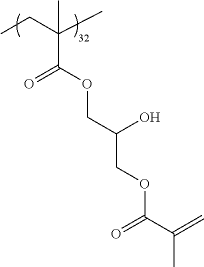

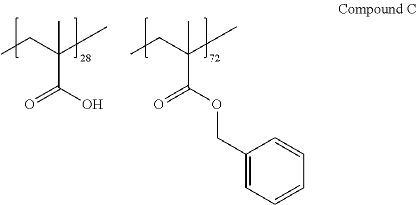

As the specific polymer A, compounds shown below are also preferable. The content ratios (a to d) and the weight-average molecular weight Mw of each of the constitutional units shown below can be appropriately changed according to the purpose.

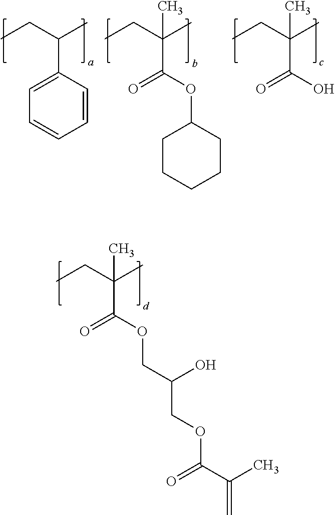

In the above compound, a is preferably 20% by mass to 60% by mass, b is preferably 10% by mass to 50% by mass, c is preferably 5.0% by mass to 25% by mass, and d is preferably 10% by mass to 50% by mass.

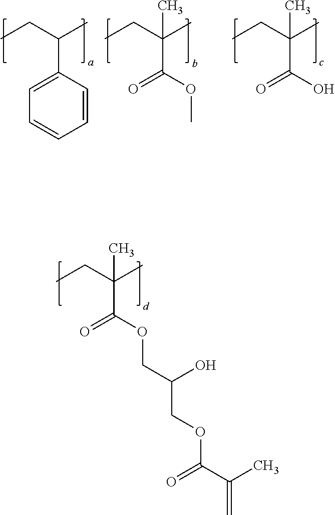

In the above compound, a is preferably 30% by mass to 65% by mass, b is preferably 1.0% by mass to 20% by mass, c is preferably 5.0% by mass to 25% by mass, and d is preferably 10% by mass to 50% by mass.

The weight-average molecular weight (Mw) of the specific polymer A is preferably 10,000 or more, more preferably 10,000 to 100,000, and still more preferably 15,000 to 50,000.

A dispersity (weight-average molecular weight (Mw)/number-average molecular weight (Mn)) of the specific polymer A is preferably 1.0 to 2.0 and more preferably 1.0 to 1.5 from the viewpoint of developability, and preferably 1.8 to 2.8 and more preferably 2.0 to 2.5 from the viewpoint of production suitability.

The acid value of the binder polymer is preferably 60 mgKOH/g to 200 mgKOH/g, more preferably 60 mgKOH/g to 150 mgKOH/g, and still more preferably 60 mgKOH/g to 110 mgKOH/g.

The acid value of the binder polymer is a value measured according to the method described in JIS K0070: 1992.

In a case where the photosensitive layer contains a binder polymer (particularly, specific polymer A) having an acid value of 60 mgKOH/g or more as the binder polymer, a second resin layer which will be described later contains a (meth)acrylic resin having an acid group, in addition to the above-described advantages. Therefore, it is possible to increase interlaminar adhesion between the photosensitive layer and the second resin layer.

The photosensitive layer may contain, as the binder polymer, a polymer (hereinafter, also referred to as a “polymer B”) including a constitutional unit having a carboxylic acid anhydride structure. In a case where the photosensitive layer contains the polymer B, developability and hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5-membered ring to 7-membered ring, more preferably a 5-membered ring or a 6-membered ring, and particularly preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

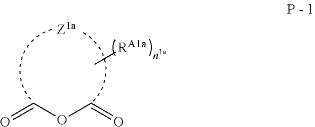

In Formula P-1, R^{A1a} represents a substituent, n^{1a} pieces of R^{A1a}'s may be the same or different, Zia represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and particularly preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and particularly preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated alicyclic carboxylic acid anhydride, particularly preferably a constitutional unit derived from maleic anhydride or itaconic anhydride, and most preferably a constitutional unit derived from maleic acid anhydride.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

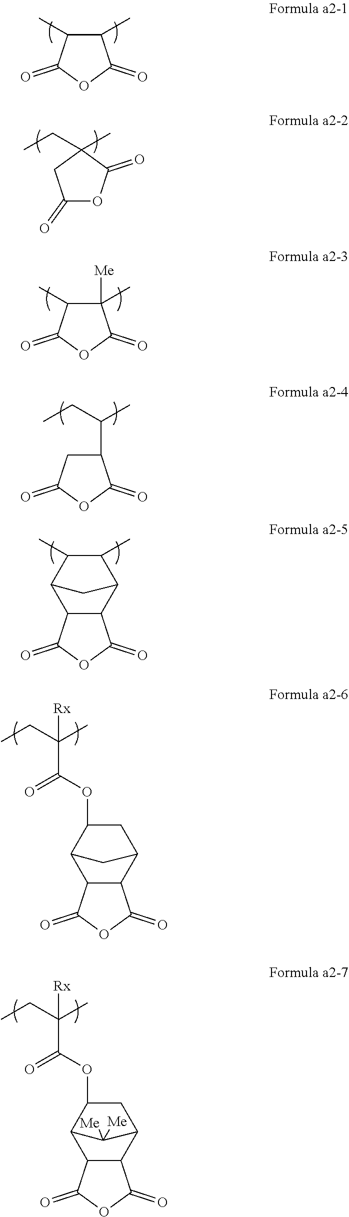

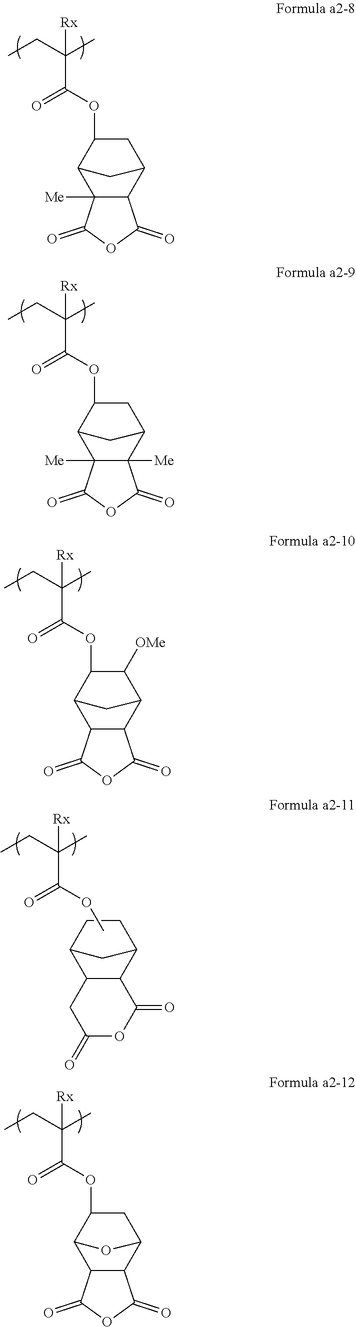

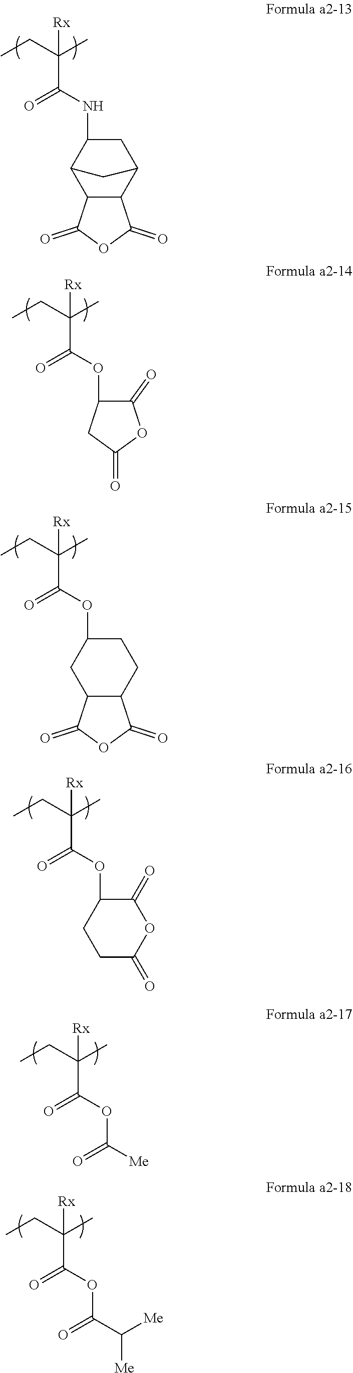

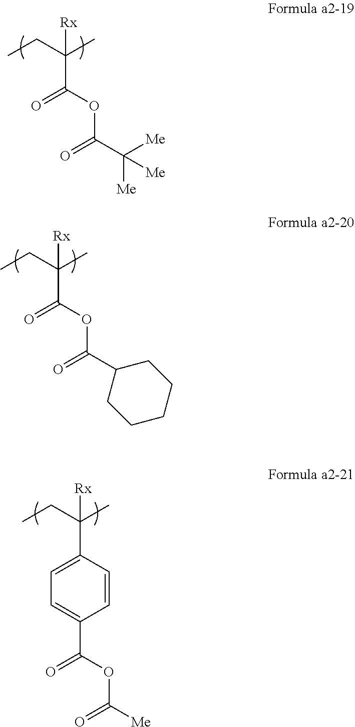

The polymer B may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and particularly preferably 10 mol % to 35 mol % with respect to the total amount of the polymer B.

As the binder polymer, a known binder polymer used for the positive photosensitive layer can be used. For example, a polymer containing a constitutional unit having an acid group protected by an acid-decomposable group is preferably mentioned.

As the polymer containing a constitutional unit having an acid group protected by an acid-decomposable group, known polymers can be used, and examples thereof include those described in JP2019-204070A.

From the viewpoint of the moisture-heat resistance of the metal, a ClogP value of the binder polymer is preferably 2.00 or higher, more preferably 2.20 or higher, and particularly preferably 2.50 or higher.

In addition, from the viewpoint of the moisture-heat resistance of the metal, the ClogP value of the binder polymer is preferably 5.00 or lower, more preferably 4.50 or lower, and particularly preferably 4.00 or lower.

The ClogP value in the present disclosure is calculated using ChemDraw (registered trademark) Professional (ver. 16.0.1.4) manufactured by PerkinElmer Informatics.

Specifically, for example, the calculation of a polymer is performed by converting the polymer into monomers constituting the polymer. For example, in a case of polyacrylic acid, the calculation is performed by acrylic acid, and in a case of a polyacrylic acid-polymethacrylic acid copolymer (a mass ratio of 50:50), ClogP values of acrylic acid and methacrylic acid are calculated, the values are multiplied by the mass ratio (0.5 each in this case), the total value thereof is defined as the ClogP value.

The weight-average molecular weight (Mw) of the binder polymer is not particularly limited, but is preferably more than 3,000, more preferably more than 3,000 and 60,000 or more, and still more preferably 5,000 to 50,000.

From the viewpoint of patterning properties and reliability, a residual monomer of each constitutional unit in the binder polymer is preferably 1,000 ppm by mass or less, more preferably 500 ppm by mass or less, and particularly preferably 100 ppm by mass or less with respect to the binder polymer. The lower limit is preferably 0.1 ppm by mass or more and more preferably 1 ppm by mass or more.

It is preferable that the amount of residual monomer of the monomer in a case of synthesizing the binder polymer by the polymer reaction is also within the above-described range. For example, in a case where glycidyl acrylate is reacted with a side chain with carboxy group to synthesize the alkali-soluble resin, the content of glycidyl acrylate is preferably within the above-described range.

The amount of the residual monomer can be measured by a known method such as liquid chromatography and gas chromatography.

The photosensitive layer may include only one kind of the binder polymer, or may include two or more kinds thereof.

From the viewpoint of hardness of the cured film and handleability of the photosensitive transfer material, for example, the content of the binder polymer in the photosensitive layer is preferably 10% by mass to 90% by mass, more preferably 20% by mass to 80% by mass, and still more preferably 30% by mass to 70% by mass with respect to a total mass of the photosensitive layer.

<<Polymerizable Compound>>

From the viewpoint of photosensitivity and hardness of the obtained resin layer on which a pattern has been formed, the photosensitive layer preferably contains a polymerizable compound.

Examples of the polymerizable compound include an ethylenically unsaturated compound, an epoxy compound, and an oxetane compound. Among these, from the viewpoint of photosensitivity and hardness of a resin layer to be obtained, an ethylenically unsaturated compound is preferable.

The ethylenically unsaturated compound preferably contains a bi- or higher functional ethylenically unsaturated compound.

In the present disclosure, the “bi- or higher functional ethylenically unsaturated compound” means a compound having two or more ethylenically unsaturated groups in one molecule.

As the ethylenically unsaturated group, a (meth)acryloyl group is preferable.

As the ethylenically unsaturated compound, a (meth)acrylate compound is preferable.

From the viewpoint of hardness of the cured film after curing, for example, the ethylenically unsaturated compounds particularly preferably include a bifunctional ethylenically unsaturated compound (preferably, a bifunctional (meth)acrylate compound) and a tri- or higher functional ethylenically unsaturated compound (preferably, a tri- or higher functional (meth)acrylate compound). The upper limit of the number of functional groups of the trifunctional or higher functional ethylenically unsaturated compound is not particularly limited, but can be, for example, 15 or less functional.

The difunctional ethylenically unsaturated compound is not particularly limited and can be appropriately selected from well-known compounds.

Examples of the difunctional ethylenically unsaturated compound include tricyclodecane dimethanol di(meth)acrylate, tricyclodecane dimethanol di(meth)acrylate, 1,9-nonanediol di(meth)acrylate, and 1,6-hexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,10-decanediol diacrylate (product name: NK ESTER A-DOD-N, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from well-known compounds.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), a mixture of dipentaerythritol hexaacrylate and dipentaerythritol pentaacrylate (KAYARAD DPHA76 manufactured by Nippon Kayaku Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 of Daicel-Allnex Ltd., or the like), and ethoxylated glycerin triacrylate (NK ESTER A-GLY-9E manufactured by Shin-Nakamura Chemical Co., Ltd., or the like).

As the ethylenically unsaturated compound, a urethane (meth)acrylate compound (preferably tri- or higher functional urethane (meth)acrylate compound) is also used.

Examples of the tri- or higher functional urethane (meth)acrylate compound include 8UX-015A (manufactured by Taisei Fine Chemical Co., Ltd.), NK ESTER UA-32P (manufactured by Shin-Nakamura Chemical Co., Ltd.), and NK ESTER UA-1100H (manufactured by Shin-Nakamura Chemical Co., Ltd.).

From the viewpoint of improving developability, the ethylenically unsaturated compound preferably includes an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 mgKOH/g to 120 mgKOH/g)], and a penta- to hexa-functional ethylenically unsaturated compound having an acid group [component obtained by introducing a carboxy group to dipentaerythritol penta- and hexa-acrylate (DPHA) skeleton (acid value: 25 mgKOH/g to 70 mgKOH/g)].

The tri- or higher functional Ethylenically unsaturated compound containing the acid group may be used in combination with the difunctional ethylenically unsaturated compound containing the acid group, as necessary.

As the ethylenically unsaturated compound containing an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability and film hardness are further enhanced.

The bi- or higher functional ethylenically unsaturated compound having a carboxy group is not particularly limited and can be appropriately selected from a known compound.

As the bi- or higher functional ethylenically unsaturated compound having a carboxy group, ARONIX (registered trademark) TO-2349 (manufactured by Toagosei Co., Ltd.), ARONIX (registered trademark) M-520 (manufactured by Toagosei Co., Ltd.), ARONIX (registered trademark) M-510 (manufactured by Toagosei Co., Ltd.), or the like can be preferably used.

As the ethylenically unsaturated compound having an acid group, polymerizable compounds having an acid group, which are described in paragraphs 0025 to 0030 of JP2004-239942A, can be preferably used, and the contents described in this publication are incorporated in the present disclosure.

The photosensitive layer may contain one ethylenically unsaturated compound having an acid group alone, or two or more kinds thereof.

From the viewpoint of developability, and pressure-sensitive adhesiveness of an uncured film that has been obtained, the content of the ethylenically unsaturated compound having an acid group is preferably 0.1% by mass to 30% by mass, more preferably 0.5% by mass to 20% by mass, still more preferably 1% by mass to 10% by mass, and particularly preferably 1% by mass to 5% by mass with respect to a total mass of the photosensitive layer.

In addition, as the polymerizable compound included in the photosensitive layer, the following aspects are also preferably mentioned.

From the viewpoint of the film hardness, the curing property, and the moisture-heat resistance of the metal, the polymerizable compound included in the photosensitive layer preferably includes a bifunctional (meth)acrylate compound, a pentafunctional (meth)acrylate compound, and a hexafunctional (meth)acrylate compound.

Furthermore, from the viewpoint of the film hardness, the curing property, and the moisture-heat resistance of the metal, as a specific another aspect, the polymerizable compound included in the photosensitive layer preferably includes an alkanediol di(meth)acrylate compound, a pentafunctional (meth)acrylate compound, and a hexafunctional (meth)acrylate compound, and more preferably includes 1,9-nonanediol di(meth)acrylate or 1,10-decanediol di(meth)acrylate, dipentaerythritol hexa(meth)acrylate, and dipentaerythritol penta(meth)acrylate.

The molecular weight of the polymerizable compound is preferably 200 to 3,000, more preferably 250 to 2,600, still more preferably 280 to 2,200, and particularly preferably 300 to 2,200.

The proportion of the content of the polymerizable compound having a molecular weight of 300 or less in the polymerizable compounds included in the photosensitive layer is preferably 30% by mass or less, more preferably 25% by mass or less, and still more preferably 20% by mass or less with respect to the content of all the polymerizable compounds included in the photosensitive layer.

The photosensitive layer may include only one kind of the polymerizable compound, or may include two or more kinds thereof.

The content of the polymerizable compound is preferably 1% by mass to 70% by mass, more preferably 10% by mass to 70% by mass, still more preferably 20% by mass to 60% by mass, and particularly preferably 20% by mass to 50% by mass with respect to a total mass of the photosensitive layer.

In a case where the photosensitive layer includes a bifunctional ethylenically unsaturated compound and a tri- or higher functional ethylenically unsaturated compound, the content of the bifunctional ethylenically unsaturated compound is preferably 10% by mass to 90% by mass, more preferably 20% by mass to 85% by mass, and still more preferably 30% by mass to 80% by mass with respect to the total content of all the ethylenically unsaturated compounds included in the photosensitive layer.

In this case, the content of the trifunctional ethylenically unsaturated compound is preferably 10% by mass to 90% by mass, more preferably 15% by mass to 80% by mass, and still more preferably 20% by mass to 70% by mass with respect to the total content of all the ethylenically unsaturated compounds included in the photosensitive layer.

In this case, the content of the bi- or higher functional ethylenically unsaturated compound is preferably 40% by mass or more and less than 100% by mass, more preferably 40% by mass to 90% by mass, still more preferably 50% by mass to 80% by mass, and particularly preferably 50% by mass to 70% by mass, with respect to a total content of the difunctional ethylenically unsaturated compound and the tri- or higher functional ethylenically unsaturated compound.

In a case of including the bi- or higher functional polymerizable compound, the photosensitive layer may further include a monofunctional polymerizable compound.

In a case where the photosensitive layer includes the bi- or higher functional polymerizable compound, the bi- or higher functional polymerizable compound is preferably a main component of the polymerizable compound included in the photosensitive layer.

In a case where the photosensitive layer includes the bi- or higher functional polymerizable compound, the content of the bi- or higher functional polymerizable compound is preferably 60% by mass to 100% by mass, more preferably 80% by mass to 100% by mass, and particularly preferably 90% by mass to 100% by mass with respect to the total content of all the polymerizable compounds included in the photosensitive layer.

In a case where the photosensitive layer includes the ethylenically unsaturated compound having an acid group (preferably, bi- or higher functional ethylenically unsaturated compound including a carboxy group or a carboxylic acid anhydride thereof), the content of the ethylenically unsaturated compound having an acid group is preferably 1% by mass to 50% by mass, more preferably 1% by mass to 20% by mass, and still more preferably 1% by mass to 10% by mass with respect to a total mass of the photosensitive layer.

<<Photopolymerization Initiator>>

The photosensitive layer preferably contains a photopolymerization initiator.

The photopolymerization initiator is not particularly limited and a known photopolymerization initiator can be used.

The photopolymerization initiator may be a radical polymerization initiator or a cationic polymerization initiator, but a radical polymerization initiator is preferable.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based polymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-95716A and paragraphs 0064 to 0081 of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(O-acetyloxime) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE (registered trademark) 651, manufactured by BASF SE], an oxime ester-based photopolymerization initiator [product name: Lunar (registered trademark) 6, manufactured by DKSH Management Ltd.], 1-[4-(phenylthio)phenyl]-3-cyclopentylpropan-1,2-dione-2-(O-benzoyloxime) (product name: TR-PBG-305, manufactured by CHANGZHOU TRONLY NEW ELECTRONIC MATERIALS CO., LTD.), 3-cyclohexyl-1-[9-ethyl-6-(2-furanylcarbonyl)-9H-carbazol-3-yl]-1,2-propanedione-2-(O-acetyloxime) (product name: TR-PBG-326, manufactured by CHANGZHOU TRONLY NEW ELECTRONIC MATERIALS CO., LTD.), 3-cyclohexyl-1-(6-(2-(benzoyloxyimino)hexanoyl)-9-ethyl-9H-carbazol-3-yl)-propan-1,2-dione-2-(O-benzoyloxime) (product name: TR-PBG-391, manufactured by CHANGZHOU TRONLY NEW ELECTRONIC MATERIALS CO., LTD.), API-307 (1-(biphenyl-4-yl)-2-methyl-2-morpholinopropan-1-one, manufactured by Shenzhen UV-ChemTech Ltd.), and the like.

The photosensitive layer may include only one kind of the photopolymerization initiator, or may include two or more kinds thereof.

In a case where the photosensitive layer contains two or more photopolymerization initiators, it is preferable to include an oxime-based photopolymerization initiator and at least one kind selected from the group consisting of an α-aminoalkylphenone-based photopolymerization initiator and an α-hydroxyalkylphenone-based polymerization initiator.

The content of the photopolymerization initiator is not particularly limited, but is preferably 0.1% by mass or more, more preferably 0.5% by mass or more, and still more preferably 1.0% by mass or more with respect to a total mass of the photosensitive layer.

In addition, the content of the photopolymerization initiator is preferably 10% by mass or less and more preferably 5% by mass or less with respect to a total mass of the photosensitive layer.

<<Heterocyclic Compound Other than Above Compound A>>

The photosensitive layer may further contain a heterocyclic compound other than the above compound A. The heterocyclic compound contributes to the improvement of adhesiveness to the metal conductive material and corrosion inhibitory property of the metal conductive material.

A heterocyclic ring included in the heterocyclic compound other than the compound A may be either a monocyclic or polycyclic heterocyclic ring.

Examples of a heteroatom included in the heterocyclic compound other than the above compound A include an oxygen atom and the like.

Examples of the heterocyclic ring of the heterocyclic compound other than the compound A include a furan ring, a benzofuran ring, an isobenzofuran ring, a tetrahydrofuran ring, a pyran ring, a benzopyran ring, and the like.

The photosensitive layer may include only one kind of the heterocyclic compound other than the above compound A, or may include two or more kinds thereof.

The content of the heterocyclic compound other than the above compound A is preferably 0.01% by mass to 20% by mass, more preferably 0.1% by mass to 10% by mass, still more preferably 0.3% by mass to 8% by mass, and particularly preferably 0.5% by mass to 5% by mass with respect to a total mass of the photosensitive layer. In a case where the content of the heterocyclic compound other than the above compound A is within the above-described range, the adhesiveness to the metal conductive material and the corrosion inhibitory property of the metal conductive material can be improved.

<Thermal Crosslinking Compound>

From the viewpoint of hardness of a cured film to be obtained and pressure-sensitive adhesiveness of an uncured film to be obtained, it is preferable that the photosensitive layer contains a thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

In the present disclosure, in a case where the photosensitive layer includes only a radically polymerizable compound as the photopolymerization initiator, the above-described epoxy compound and the above-described oxetane compound are treated as the thermal crosslinking compound, and in a case of including a cationic polymerization initiator, the above-described epoxy compound and the above-described oxetane compound are treated as the polymerizable compound.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened.

The blocked isocyanate compound refers to a “compound having a structure in which the isocyanate group of isocyanate is protected (so-called masked) with a blocking agent”.

The dissociation temperature of the blocked isocyanate compound is not particularly limited, but is preferably 100° C. to 160° C. and more preferably 130° C. to 150° C.

The dissociation temperature of blocked isocyanate in the present disclosure means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (such as dimethyl malonate, diethyl malonate, di-n-butyl malonate, and di-2-ethylhexyl malonate)], and an oxime compound (compound having a structure represented by —C(═N—OH)— in a molecule, such as formaldoxime, acetaldoxime, acetoxime, methyl ethyl ketoxime, and cyclohexanoneoxime).

Among these, from the viewpoint of preservation stability, the blocking agent having a dissociation temperature of 100° C. to 160° C. is preferably, for example, at least one selected from oxime compounds.

From the viewpoint of improving brittleness of the film and improving the adhesion to a transferred material, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound preferably has a polymerizable group and more preferably has a radically polymerizable group, from the viewpoint of hardness of the cured film.

The polymerizable group is not particularly limited, and a known polymerizable group can be used.

Examples of the polymerizable group include a (meth)acryloxy group, a (meth)acrylamide group, an ethylenically unsaturated group such as styryl group, and an epoxy group such as a glycidyl group.

Among these, as the polymerizable group, from the viewpoint of surface shape of the surface of a cured film to be obtained, a development speed, and reactivity, an ethylenically unsaturated group is preferable, and a (meth)acryloxy group is more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all of which are manufactured by SHOWA DENKO K.K.), and block-type DURANATE series (for example, DURANATE (registered trademark) TPA-B80E, manufactured by Asahi Kasei Corporation).

The photosensitive layer may include only one kind of the thermal crosslinking compound, or may include two or more kinds thereof.

The content of the thermal crosslinking compound is preferably 1% by mass to 50% by mass and more preferably 5% by mass to 30% by mass with respect to a total mass of the photosensitive layer.

<<Surfactant>>

The photosensitive layer may include a surfactant.

The surfactant is not particularly limited, and a known surfactant can be used.

Examples of the surfactant include surfactants described in paragraph 0017 of JP4502784B and paragraphs 0060 to 0071 of JP2009-237362A.

As the surfactant, a nonionic surfactant, a fluorine-based surfactant or a silicon-based surfactant is preferable.

Examples of a commercially available product of the fluorine-based surfactant include MEGAFACE F-171, F-172, F-173, F-176, F-177, F-141, F-142, F-143, F-144, F-437, F-444, F-475, F-477, F-479, F-482, F-551-A, F-552, F-554, F-555-A, F-556, F-557, F-558, F-559, F-560, F-561, F-565, F-563, F-568, F-575, F-780, EXP, MFS-330, MFS-578, MFS-579, MFS-586, MFS-587, R-41, R-41-LM, R-01, R-40, R-40-LM, RS-43, TF-1956, RS-90, R-94, RS-72-K, DS-21 (all of which are manufactured by DIC Corporation), Fluorad FC430, FC431, FC171 (all of which are manufactured by Sumitomo 3M Limited), Surflon S-382, SC-101, SC-103, SC-104, SC-105, SC-1068, SC-381, SC-383, S-393, KH-40 (all of which are manufactured by AGC Inc.), PolyFox PF636, PF656, PF6320, PF6520, PF7002 (all of which are OMNOVA Solutions Inc.), FTERGENT 710FL, 710FM, 610FM, 601AD, 601ADH2, 602A, 215M, 245F, 251, 212M, 250, 209F, 222F, 208G, 710LA, 710FS, 730LM, 650AC, 681 (all of which are manufactured by NEOS COMPANY LIMITED), and the like.

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series manufactured by DIC Corporation (The Chemical Daily (Feb. 22, 2016)); Nikkei Business Daily (Feb. 23, 2016)) such as MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used.

As the fluorine-based surfactant, a block polymer can also be used. As the fluorine-based surfactant, a fluorine-containing polymer compound can be preferably used, the fluorine-containing polymer compound including: a constitutional repeating unit derived from a (meth)acrylate compound having a fluorine atom; and a constitutional repeating unit derived from a (meth)acrylate compound having 2 or more (preferably 5 or more) alkyleneoxy groups (preferably an ethyleneoxy group and a propyleneoxy group).

As the fluorine-based surfactant, a fluorine-containing polymer having an ethylenically unsaturated bond-containing group at a side chain can also be used. MEGAFACE RS-101, RS-102, RS-718K, RS-72-K (all of which are manufactured by DIC Corporation), and the like can be mentioned.

From the viewpoint of improving environmental suitability, the fluorine-based surfactant is preferably a surfactant derived from an alternative material of a compound containing a linear perfluoroalkyl group having 7 or more carbon atoms, such as perfluorooctanoic acid (PFOA) and perfluorooctanesulfonic acid (PFOS).

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (all of which are manufactured by BASF), TETRONIC 304, 701, 704, 901, 904, and 150R1 (all of which are manufactured by BASF), SOLSPERSE 20000 (all of which are manufactured by Lubrizol Corporation), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include a linear polymer obtained by a siloxane bond and a modified siloxane polymer containing an organic group introduced into a side chain or a terminal.

Specific examples of the surfactants include DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH3OPA, and TORAY SILICONE SH8400 (all of which are manufactured by Dow Corning Toray Co., Ltd.), X-22-4952, X-22-4272, X-22-6266, KF-351A, K354L, KF-355A, KF-945, KF-640, KF-642, KF-643, X-22-6191, X-22-4515, KF-6004, KP-341, KF-6001, KF-6002 (all of which are manufactured by Shin-Etsu Chemical Co., Ltd.), TSF-4440, TSF-4300, TSF-4445, TSF-4460, and TSF-4452 (all of which are manufactured by Momentive Performance Materials Co., Ltd.), and BYK307, BYK323, and BYK330 (all of which are manufactured by BYK Chemie).

The photosensitive layer may include only one kind of the surfactant, or may include two or more kinds thereof.

The content of the surfactant is preferably 0.01% by mass to 3% by mass, more preferably 0.05% by mass to 1% by mass, and still more preferably 0.1% by mass to 0.8% by mass with respect to a total mass of the photosensitive layer.

<<Hydrogen Donating Compound>>

It is preferable that the photosensitive layer includes a hydrogen donating compound.

In the photosensitive layer, the hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-20189B (JP-544-20189B), JP1976-82102A (JP-551-82102A), JP1977-134692A (JP-552-134692A), JP1984-138205A (JP-559-138205A), JP1985-84305A (JP-560-84305A), JP1987-18537A (JP-562-18537A), JP1989-33104A (JP-564-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-S48-42965B) (tributyl tin acetate and the like), a hydrogen donor described in JP1980-34414B (JP-S55-34414B), and a sulfur compound described in JP1994-308727A (JP-H06-308727A) (trithiane and the like).

The photosensitive layer may include only one kind of the hydrogen donating compound, or may include two or more kinds thereof.

For example, from the viewpoint of improving a curing rate by balancing the polymerization growth rate and chain transfer, the content of the hydrogen donating compound is preferably 0.01% by mass to 10% by mass, more preferably 0.03% by mass to 5% by mass, and still more preferably 0.05% by mass to 3% by mass with respect to a total mass of the photosensitive layer.

<<Photo-Acid Generator>>

It is preferable that the photosensitive layer includes a photo-acid generator.

The photo-acid generator used in the present disclosure is a compound capable of generating an acid by irradiation with actinic rays such as ultraviolet rays, far ultraviolet rays, X-rays, and electron beams.

The photo-acid generator is preferably a compound that is sensitive to actinic rays having a wavelength of 300 nm or more, preferably 300 nm to 450 nm and that generates an acid, but a chemical structure thereof is not limited. A photo-acid generator which is not directly sensitive to actinic rays having a wavelength of 300 nm or more can also be preferably used in combination with a sensitizer as long as it is a compound which is sensitive to actinic rays having a wavelength of 300 nm or more and generates an acid by being used in combination with the sensitizer.

The photo-acid generator used in the present disclosure is preferably a photo-acid generator which generates an acid with a pKa of 4 or less, more preferably a photo-acid generator which generates an acid with a pKa of 3 or less, and particularly preferably a photo-acid generator which generates an acid with a pKa of 2 or less. The lower limit value of the pKa is not particularly limited, but is preferably −10.0 or more.

Examples of the photo-acid generator include an ionic photo-acid generator and a nonionic photo-acid generator.

Examples of the ionic photo-acid generator include onium salt compounds such as diaryliodonium salts and triarylsulfonium salts, and quaternary ammonium salts. Among these, onium salt compounds are preferable, and triarylsulfonium salts and diaryliodonium salts are particularly preferable.

As the ionic photo-acid generator, ionic photo-acid generators described in paragraphs 0114 to 0133 of JP2014-85643A can also be preferably used.

Examples of the nonionic photo-acid generator include trichloromethyl-s-triazines, a diazomethane compound, an imide sulfonate compound, and an oxime sulfonate compound. Among these, from the viewpoint of sensitivity, resolution, and adhesiveness, the photo-acid generator is preferably an oxime sulfonate compound. Specific examples of the trichloromethyl-s-triazines, the diazomethane compound, and the imide sulfonate compound include compounds described in paragraphs 0083 to 0088 of JP2011-221494A.

As the oxime sulfonate compound, those described in paragraphs 0084 to 0088 of WO2018/179640A can be suitably used.

The photosensitive layer may contain one kind of the photo-acid generator alone, or may contain two or more kinds thereof.

From the viewpoint of sensitivity and resolution, the content of the photo-acid generator in the photosensitive layer is preferably 0.1% by mass to 10% by mass and more preferably 0.5% by mass to 5% by mass with respect to a total mass of the photosensitive layer.

<<Other Components>>

The photosensitive layer may include components (so-called other components) other than the components described above.

Examples of the other components include particles (for example, metal oxide particles) and a colorant.

In addition, examples of the other components include a thermal polymerization inhibitor described in paragraph 0018 of JP4502784B and other additives described in paragraphs 0058 to 0071 of JP2000-310706A.

In addition, examples of other additives include known additives such as plasticizers, sensitizers, alkoxysilane compounds, basic compounds, ultraviolet absorbers, and rust inhibitors.

Examples of the plasticizers, sensitizers, and alkoxysilane compounds include those described in paragraphs 0097 to 0119 of WO2018/179640A.

—Particles—

The photosensitive layer may include particles (for example, metal oxide particles; the same applies hereinafter) for the purpose of adjusting refractive index, light-transmitting property, and the like.

The metal of the metal oxide particles also includes semimetal such as B, Si, Ge, As, Sb, or Te.

From the viewpoint of transparency of the cured film, for example, the average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive layer includes particles, the photosensitive layer may include only one kind of particles having different metal types, sizes, and the like, or may include two or more kinds thereof.

It is preferable that the photosensitive layer does not include particles, or the content of the particles is more than 0% by mass to 35% by mass or less with respect to a total mass of the photosensitive layer; it is more preferable that the photosensitive layer does not include particles, or the content of the particles is more than 0% by mass to 10% by mass or less with respect to a total mass of the photosensitive layer; it is still more preferable that the photosensitive layer does not include particles, or the content of the particles is more than 0% by mass to 5% by mass or less with respect to a total mass of the photosensitive layer; it is even more preferable that the photosensitive layer does not include particles, or the content of the particles is more than 0% by mass to 1% by mass or less with respect to a total mass of the photosensitive layer; and it is particularly preferable that the photosensitive layer does not include particles.

—Colorant—

The photosensitive layer may include a trace amount of a colorant (pigment, dye, and the like), but for example, from the viewpoint of transparency, it is preferable that the photosensitive layer does not substantially include the colorant.

The content of the colorant is preferably less than 1% by mass and more preferably less than 0.1% by mass with respect to a total mass of the photosensitive layer.

<<Content of Chloride Ions>>

From the viewpoint of the moisture-heat resistance of the metal, a content of chloride ions included in the above-described photosensitive layer is preferably 50 ppm or less, more preferably 20 ppm or less, still more preferably 10 ppm or less, particularly preferably 5 ppm or less, and most preferably 1 ppm or less with respect to a total mass of the photosensitive layer.

In the present disclosure, the content of chloride ions included in the above-described photosensitive layer or in a resin layer described later is measured by the following method.

The photosensitive layer or the resin layer described later is collected as a sample of approximately 100 mg, and approximately 100 mg of the collected sample is dissolved in 5 mL of propylene glycol monomethyl ether acetate. 5 mL of ultrapure water is added thereto, and the mixture is stirred for 2 hours. The mixture is left to stand for 12 hours or more, 1 mL of the aqueous layer is collected, and 9 mL of ultrapure water is added thereto to prepare a sample for measurement.

The prepared sample for measurement is subjected to ion chromatograph according to the measuring device and measuring conditions shown below, thereby measuring and calculating the content of chloride ions.
Ion chromatograph device: IC-2010 (manufactured by Tosoh Corporation)
Analytical column: TSKgel SuperIC-Anion HS
Guard column: TSKgel guardcolumn SuperIC-A HS
Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (using a suppressor)

Examples of a method of collecting the above-described photosensitive layer used for measuring the content of chloride ions include a method in which a protective film is peeled off, a photosensitive layer on the photosensitive transfer material is laminated on glass, the temporary support is peeled off to transfer the photosensitive layer, and 100 mg of the photosensitive layer is collected.

In addition, examples of a method of collecting the resin layer described later include a method of scraping 100 mg from the resin layer to be collected.

The thickness of the photosensitive layer is not particularly limited, but from the viewpoint of production suitability, reducing the thickness of the entire photosensitive transfer material, improvement of the transmittance of the photosensitive layer or a film to be obtained, and suppression of yellowing of the photosensitive layer or a film to obtained, the thickness of the photosensitive layer is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

The thickness of each layer such as the photosensitive layer is obtained as an average value of 5 random points measured by cross-sectional observation with a scanning electron microscope (SEM).

The refractive index of the photosensitive layer is not particularly limited, but is preferably 1.47 to 1.56, more preferably 1.50 to 1.53, still more preferably 1.50 to 1.52, and particularly preferably 1.51 to 1.52.

A method of forming the photosensitive layer is not particularly limited, and a known method can be used.

As an example of the method of forming the photosensitive layer, a method of forming the photosensitive layer by applying a photosensitive composition of an aspect including a solvent onto a temporary support and then drying, as necessary is used.

As a coating method, a known method can be used.

Examples of the coating method include a printing method, a spray coating method, a roll coating method, a bar coating method, a curtain coating method, a spin coating method, and a die coating method (that is, a slit coating method).

Among these, a die coating method is preferable as the coating method.

As a drying method, known methods such as natural drying, heating drying, and drying under reduced pressure can be used, and these methods can be applied alone or in combination of plural thereof.

In the present disclosure, the “drying” means removing at least a part of the solvent included in the composition.

It is preferable to use a solvent for forming the photosensitive layer. In a case where the above-described photosensitive composition includes a solvent, the formation of the photosensitive layer by coating tends to be easier.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

As the solvent, a solvent described in paragraphs 0054 and 0055 of US2005/282073A can also be used, and the contents of the present specification are incorporated in the present disclosure.

In addition, as the solvent, an organic solvent (high boiling point solvent) having a boiling point of 180° C. to 250° C. can also be used, as necessary. When a high boiling point solvent is contained, the content thereof is preferably 2% by mass to 20% by mass with respect to the total solvent.

In a case where the above-described photosensitive composition includes a solvent, the photosensitive resin composition may include only one kind of the solvent, or may include two or more kinds thereof.

The solid content of the above-described photosensitive composition is preferably 5% by mass to 80% by mass, more preferably 5% by mass to 40% by mass, and particularly preferably 5% by mass to 30% by mass with respect to a total mass of the photosensitive composition.

For example, from the viewpoint of coatability, the viscosity of the above-described photosensitive composition at 25° C. is preferably 1 mPa·s to 50 mPa·s, more preferably 2 mPa·s to 40 mPa·s, and still more preferably 3 mPa·s to 30 mPa·s.

The viscosity is measured using a viscometer. As the viscometer, for example, a viscometer (product name: VISCOMETER TV-22) manufactured by Toki Sangyo Co., Ltd. can be suitably used. However, the viscometer is not limited thereto.

For example, from the viewpoint of coatability, the surface tension of the above-described photosensitive composition at 25° C. is preferably 5 mN/m to 100 mN/m, more preferably 10 mN/m to 80 mN/m, and still more preferably 15 mN/m to 40 mN/m.

The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited thereto.

It is not necessary that the solvent used in forming the photosensitive layer is completely removed. For example, the content of the solvent in the photosensitive layer is preferably 5% by mass or less, more preferably 1% by mass or less, and particularly preferably 0.5% by mass or less with respect to a total mass of the photosensitive layer. From the viewpoint of imparting developability and the like, the content of the solvent in the photosensitive layer is preferably 0.05% by mass or more.

<<Color of Photosensitive Layer>>

The above-described photosensitive layer is preferably achromatic. In a L*a*b* color system, an a* value of the photosensitive layer is preferably −1.0 to 1.0, and a b* value is preferably −1.0 to 1.0.

<<Refractive Index of Photosensitive Layer>>

A refractive index of the photosensitive layer is preferably 1.41 to 1.59 and more preferably 1.47 to 1.56.

<<Visible Light Transmittance of Photosensitive Layer>>

A visible light transmittance per 1.0 μm film thickness of the photosensitive layer is preferably 80% or more, more preferably 90% or more, and particularly preferably 95% or more.

As the visible light transmittance, it is preferable that an average transmittance at a wavelength of 400 nm to 800 nm, a minimum transmittance at a wavelength of 400 nm to 800 nm, and a transmittance at a wavelength of 400 nm all satisfy the above transmittance.

Preferable values for the transmittance can be, for example, 87%, 92%, 98%, and the like.

The same applies to the transmittance per 1.0 μm film thickness of the cured film of the photosensitive layer.

<<Moisture Permeability of Photosensitive Layer>>

From the viewpoint of device reliability, a moisture permeability of the pattern (the cured film of the photosensitive layer) obtained from the photosensitive layer cured at a film thickness of 40 μm is preferably 500 g/(m²·24 hr) or less, more preferably 300 g/(m²·24 hr) or less, and still more preferably 100 g/(m²·24 hr) or less.

The moisture permeability is measured with a cured film obtained in such a manner that the photosensitive layer is subjected to exposure with an i ray at an exposure amount of 300 mJ/cm², and thereafter, post baking is performed at 145° C. for 30 minutes to cure the photosensitive layer, thereby forming the cured film.

The moisture permeability is measured according to a JIS Z0208 cup method. The above-described moisture permeability is preferably secured under any of test conditions of temperature 40° C./humidity 90%, temperature 65° C./humidity 90%, and temperature 80° C./humidity 95%.

Specific preferable numerical values can include, for example, 80 g/(m²·24 hr), 150 g/(m²·24 hr), 220 g/(m²·24 hr), and the like.

<Dissolution Rate of Photosensitive Layer>

From the viewpoint of suppressing residue during development, a dissolution rate of the photosensitive layer with respect to a 1.0% aqueous solution of sodium carbonate is preferably 0.01 μm/sec or more, more preferably 0.10 μm/sec or more, and still more preferably 0.20 μm/sec or more.

From the viewpoint of an edge shape of the pattern, 5.0 μm/sec or less is preferable, 4.0 μm/sec or less is more preferable, and 3.0 μm/sec or less is still more preferable.

Specific preferable numerical values include, for example, 1.8 μm/sec, 1.0 μm/sec, 0.7 μm/sec, and the like.

The dissolution rate of the photosensitive layer with respect to an aqueous solution of 1.0% by mass sodium carbonate per unit time is measured as follows.

Shower development is performed on the photosensitive layer (film thickness within a range of 1.0 to 10 μm), which is formed on the glass substrate and from which the solvent has been sufficiently removed, at 25° C. by using an aqueous solution of 1.0% sodium carbonate by mass until the photosensitive layer is melted out (where, the shower development is performed up to 2 minutes, at longest). The dissolution rate is obtained by dividing the film thickness of the photosensitive layer by the time required for the photosensitive layer to be melted out. In a case where the photosensitive layer is not melted out in 2 minutes, calculation is performed in the same way based on the amount of change in film thickness up to that point.

The dissolution rate of the cured film (the film thickness being within the range of 1.0 μm to 10 μm) of the photosensitive layer with respect to a 1.0% aqueous solution of sodium carbonate is preferably 3.0 μm/sec or less, more preferably 2.0 μm/sec or less, still more preferably 1.0 μm/sec or less, and particularly preferably 0.2 μm/sec or less. The cured film of the photosensitive layer is a film obtained in such a manner that the photosensitive layer is subjected to exposure with an i ray at an exposure amount of 300 mJ/cm².

Specific preferable numerical values can include, for example, 0.8 μm/sec, 0.2 μm/sec, 0.001 μm/sec, and the like.

The development is performed by using a shower nozzle of 1/4 MINJJX03OPP manufactured by H. IKEUCHI Co., Ltd., and a shower pressure is 0.08 MPa. Under the above conditions, a shower flow rate per unit time is 1,800 mL/min.

<Swelling Ratio of Photosensitive Layer>

From the viewpoint of improving pattern formation, a swelling ratio of the photosensitive layer after the exposure with respect to an aqueous solution of 1.0% sodium carbonate by mass is preferably 100% or less, more preferably 50% or less, and still more preferably 30% or less.

The swelling ratio of the photosensitive layer after the exposure with respect to an aqueous solution of 1.0% sodium carbonate by mass is measured as follows.

The photosensitive layer (the film thickness being within the range of 1.0 to 10 μm), which is formed on the glass substrate and from which the solvent has been sufficiently removed, is exposed to 500 mj/cm² (i ray measurement) with an ultra-high pressure mercury lamp. Each glass substrate is immersed in an aqueous solution of 1.0% by mass sodium carbonate at 25° C., and the film thickness is measured after 30 seconds. Then, a rate at which a film thickness after immersion increases with respect to the film thickness before immersion is calculated.

Specific preferable numerical values include, for example, 4%, 13%, 25%, and the like.

<Foreign Substance in Photosensitive Layer>

From the viewpoint of pattern formation, the number of foreign substances each of which has a diameter of 1.0 μm or more in the photosensitive layer is preferably 10 pieces/mm² or less, and more preferably 5 pieces/mm² or less.

The number of foreign substances is measured as follows.

Any 5 regions (1 mm×1 mm) on a surface of the photosensitive layer are visually observed from the normal direction of the surface of the photosensitive layer with an optical microscope, the number of foreign substances each of which has a diameter of 1.0 μm or more in each region is measured, and the results are arithmetically averaged and calculated as the number of foreign substances.

Specific preferable numerical values include, for example, 0 pieces/mm², 1 piece/mm², 4 pieces/mm², 8 pieces/mm², and the like.

<Haze of Dissolved Substance in Photosensitive Layer>

From the viewpoint of restraining the generation of agglomerates during the development, a haze of a solution obtained in such a manner that a photosensitive layer of 1.0 cm³ is dissolved in 1.0 liter of an aqueous solution of 1.0% by mass sodium carbonate at 30° C. is preferably 60% or less, more preferably 30% or less, still more preferably 10% or less, and particularly preferably 1% or less.

The haze is measured as follows.

First, an aqueous solution of 1.0% by mass sodium carbonate is prepared, and a liquid temperature is adjusted to 30° C. A photosensitive layer of 1.0 cm³ is placed in 1.0 L of an aqueous solution of sodium carbonate. The mixture is stirred at 30° C. for 4 hours while being careful not to mix air bubbles. After stirring, a haze of a solution in which the photosensitive layer is dissolved is measured. The haze is measured using a haze meter (product name “NDH4000”, manufactured by Nippon Denshoku Kogyo Co., Ltd.), a liquid measuring unit, and a liquid measuring cell having an optical path length of 20 mm.

Specific preferable numerical values include, for example, 0.4%, 1.0%, 9%, 24%, and the like.

<Second Resin Layer>

The photosensitive transfer material according to the embodiment of the present disclosure may further have a second resin layer between the temporary support and the photosensitive layer.

Examples of the second resin layer include a thermoplastic resin layer which will be described later, and an interlayer.

In addition, as the second resin layer the photosensitive transfer material according to the embodiment of the present disclosure may have a thermoplastic resin layer or an interlayer between the temporary support and the photosensitive layer, or may have both a thermoplastic resin layer and an interlayer between the temporary support and the photosensitive layer.

—Thermoplastic Resin Layer—

The photosensitive transfer material according to the present disclosure may further include a thermoplastic resin layer between a temporary support and a photosensitive layer.

In a case where the photosensitive transfer material further includes a thermoplastic resin layer, air bubbles due to lamination are hardly generated in a case where the photosensitive transfer material is transferred to a substrate to form a film. In a case where this film is used in an image display device, image unevenness is hardly generated and excellent display properties are obtained.

The thermoplastic resin layer preferably has alkali solubility.

The thermoplastic resin layer functions as a cushion material which absorbs ruggedness of the surface of the substrate at the time of transfer.

The ruggedness of the surface of the substrate includes an image, an electrode, a wiring, and the like which are formed in advance.

The thermoplastic resin layer preferably has properties capable of being deformed in accordance with ruggedness.

The thermoplastic resin layer preferably includes an organic polymer substance described in JP1993-72724A (JP-H05-72724A), and more preferably includes an organic polymer substance having a softening point approximately 80° C. or lower by a Vicat method (specifically, polymer softening point measurement method using an American Society for Testing and Materials ASTM D1235).

The thickness of the thermoplastic resin layer is preferably 3 μm to 30 μm, more preferably 4 μm to 25 μm, and still more preferably 5 μm to 20 μm.

In a case where the thickness of the thermoplastic resin layer is 3 μm or more, followability with respect to the ruggedness of the surface of the substrate is improved, and the ruggedness of the surface of the substrate can be effectively absorbed.

In a case where the thickness of the thermoplastic resin layer is 30 μm or less, since the production suitability is more improved, for example, burden of the drying (so-called drying for removing the solvent) in a case of applying and forming the thermoplastic resin layer on the temporary support is further reduced, and the development time of the thermoplastic resin layer after the transfer is further shortened.

The thickness of the thermoplastic resin layer is obtained as an average value of 5 random points measured by cross-sectional observation with a scanning electron microscope (SEM).

The thermoplastic resin layer can be formed by applying and, as necessary, drying a composition for forming a thermoplastic resin layer including a solvent and a thermoplastic organic polymer on the temporary support.

Specific examples of coating and drying methods in the forming method of the thermoplastic resin layer are the same as the specific examples of coating and drying in the forming method of the photosensitive layer, respectively.

The solvent is not particularly limited as long as the solvent dissolves the polymer component forming the thermoplastic resin layer.

Examples of the solvent include organic solvents (for example, methyl ethyl ketone, cyclohexanone, propylene glycol monomethyl ether acetate, n-propanol, and 2-propanol).

The viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive layer measured at 100° C.

—Interlayer—

The photosensitive transfer material according to the present disclosure may further include an interlayer between a temporary support and a photosensitive layer.

In a case where the photosensitive transfer material according to the embodiment of the present disclosure has the thermoplastic resin layer, the interlayer is preferably disposed between the thermoplastic resin layer and the photosensitive layer.

Examples of a component included in the interlayer include at least one polymer selected from the group consisting of polyvinyl alcohol, polyvinylpyrrolidone, and cellulose.

In addition, as the interlayer, a component disclosed in JP1993-072724A (JP-H5-072724A) as a “separation layer” can also be used.

In a case of producing the photosensitive transfer material of an aspect having the thermoplastic resin layer, the interlayer, and the photosensitive layer on the temporary support in this order, for example, the interlayer can be formed by applying and, as necessary, drying a composition for forming an interlayer including a solvent which does not dissolve the thermoplastic resin layer, and the above-described polymer as the component of the interlayer.

Specifically, first, the composition for forming a thermoplastic resin layer is applied and dried on the temporary support to form the thermoplastic resin layer. Next, the composition for forming an interlayer is applied on the formed thermoplastic resin layer and dried as necessary to form the interlayer. Next, a photosensitive resin composition (so-called a composition for forming a photosensitive layer) including an organic solvent is applied on the formed interlayer and dried to form the photosensitive layer. The organic solvent included in the composition for forming a photosensitive layer is preferably an organic solvent which does not dissolve the interlayer.

Specific examples of coating and drying methods in the forming method of the interlayer are the same as the specific examples of coating and drying in the forming method of the photosensitive layer, respectively.

<Refractive Index Adjusting Layer>

The photosensitive transfer material according to the embodiment of the present disclosure may further have a refractive index adjusting layer between the photosensitive layer and the protective film.

The refractive index adjusting layer is not limited, and a known refractive index adjusting layer can be applied. Examples of a material contained in the refractive index adjusting layer include a binder and particles.

The binder is not limited, and a known binder can be applied. Examples of the binder include the above-described binder polymer.

The particles are not limited, and known particles can be applied. Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index adjusting layer preferably contains a metal oxidation inhibitor. In a case where the refractive index adjusting layer contains a metal oxidation inhibitor, oxidation of metal in contact with the refractive index adjusting layer can be suppressed.

Preferred examples of the metal oxidation inhibitor include a compound having an aromatic ring including a nitrogen atom in the molecule. Specific examples of the metal oxidation inhibitor include imidazole, benzimidazole, tetrazole, mercaptothiadiazole, and benzotriazole.

The refractive index of the refractive index adjusting layer is preferably 1.50 or more, more preferably 1.55 or more, and particularly preferably 1.60 or more.

In addition, the upper limit of the refractive index of the refractive index adjusting layer is not particularly limited, but is preferably 2.10 or less and more preferably 1.85 or less.

The thickness of the refractive index adjusting layer is preferably 500 nm or less, more preferably 110 nm or less, and particularly preferably 100 nm or less.

In addition, the thickness of the refractive index adjusting layer is preferably 20 nm or more and more preferably 50 nm or more.

The thickness of the refractive index adjusting layer is obtained as an average value of 5 random points measured by cross-sectional observation with a scanning electron microscope (SEM).

A method of forming the refractive index adjusting layer is not limited, and a known method can be applied. Examples of the method of forming the refractive index adjusting layer include a method using a composition for a refractive index adjusting layer. For example, the composition for a refractive index adjusting layer is applied on an object to be coated, and the composition is dried as necessary to form a refractive index adjusting layer.

Examples of a method of producing the composition for a refractive index adjusting layer include a method of mixing the above-described components and a solvent. The mixing method is not limited, and a known method can be applied.

The solvent is not limited, and a known solvent can be applied. Examples of the solvent include water, and organic solvents described in the above section of “a method of forming the photosensitive layer”.

As the coating method and drying method, the coating method and drying method described in the above section of “method of forming the photosensitive layer” can be applied, respectively.

<Antistatic Layer>

The photosensitive transfer material according to the embodiment of the present disclosure may further include an antistatic layer between the photosensitive layer and the protective film or between the photosensitive layer and the temporary support. Since the photosensitive transfer material according to the embodiment of the present disclosure has an antistatic layer, it is possible to suppress generation of static electricity in a case of peeling off the film or the like disposed on the antistatic layer, and also to suppress generation of static electricity due to rubbing against equipment or other films. As a result, for example, it is possible to suppress the occurrence of defects in electronic devices.

The antistatic layer is preferably disposed between the temporary support and the photosensitive layer from the viewpoint of suppressing the generation of static electricity.

The antistatic layer is a layer having antistatic properties and contains at least an antistatic agent. The antistatic agent is not limited, and a known antistatic agent can be used.

The antistatic layer preferably contains, as the antistatic agent, at least one compound selected from the group consisting of an ionic liquid, an ionic conductive polymer, an ionic conductive filler, and a conductive polymer (also, referred to as a “conductive polymer”).

The ionic liquid is preferably an ionic liquid composed of a fluoroorganic anion and an onium cation.

Examples of the ionic conductive polymer include an ionic conductive polymer obtained by polymerizing or copolymerizing a monomer having a quaternary ammonium base. As a counter ion of the quaternary ammonium base, non-halogen ions are preferable. Examples of the non-halogen ion include sulfonate anions and carboxylate anions.

Examples of the ionic conductive filler include tin oxide, antimony oxide, indium oxide, cadmium oxide, titanium oxide, zinc oxide, indium, tin, antimony, gold, silver, copper, aluminum, nickel, chromium, titanium, iron, cobalt, copper iodide, indium oxide/tin oxide (ITO), and antimony oxide/tin oxide (ATO).

Examples of the conductive polymer include polythiophene, polyaniline, polypyrrole, polyethyleneimine, and arylamine-based polymers. Specific examples of the conductive polymer include (3,4-ethylenedioxythiophene)-poly(styrene sulfonic acid).

Among the above examples, the antistatic agent is preferably polythiophene. As the polythiophene, a polymer compound including poly(3,4-ethylenedioxythiophene) (PEDOT) is preferable, and a conductive polymer consisting of poly(3,4-ethylenedioxythiophene) and polystyrene sulfonic acid (hereinafter, abbreviated as “PEDOT/PSS”) is particularly preferable.

The antistatic layer may contain only one kind of antistatic agent, or may contain two or more kinds of antistatic agents.

From the viewpoint of antistatic properties, the content of the antistatic agent is preferably 0.1% by mass to 100% by mass with respect to a total mass of a layer including the antistatic layer. In a case where the antistatic agent is a solvent-dispersed antistatic agent, the content of the antistatic agent is more preferably 1% by mass to 10% by mass and particularly preferably 3% by mass to 10% by mass with respect to a total mass of the antistatic layer. In a case where the antistatic agent is not a solvent-dispersed antistatic agent, the content of the antistatic agent is more preferably 60% by mass to 100% by mass and particularly preferably 70% by mass to 100% by mass with respect to a total mass of the antistatic layer.

The antistatic layer may further contain a component other than the antistatic agent as necessary. Examples pf components other than the antistatic agents include, for example, a binder polymer (such as polyvinylpyrrolidone, polyvinyl alcohol, or an acrylic resin), a curable component (such as a polymerizable compound or a photopolymerization initiator), and a surfactant.

The average thickness of the antistatic layer is preferably 1 μm or less, more preferably 0.6 μm or less, still more preferably 0.4 μm or less, and particularly preferably 0.2 μm or less. In a case where the average thickness of the antistatic layer is 1 μm or less, haze can be reduced. The lower limit of the thickness of the antistatic layer is not limited. From the viewpoint of production suitability, the average thickness of the antistatic layer is preferably 0.01 μm or more. The average thickness of the antistatic layer is the arithmetic mean of thicknesses of the five points measured by cross-sectional observation with a scanning electron microscope (SEM).

Examples of the method of forming the antistatic layer include a method using a composition for an antistatic layer. For example, a method of applying a composition for an antistatic layer on an object to be coated (for example, the temporary support or the photosensitive layer) can be mentioned. Examples of the coating method include a printing method, a spray coating method, a roll coating method, a bar coating method, a curtain coating method, a spin coating method, and a die coating method (that is, a slit coating method). Among the above, a die coating method is preferable as the coating method.

In the method of forming an antistatic layer, the photosensitive composition applied on the object to be coated may be dried, as necessary. Examples of the drying method include natural drying, heating drying, and drying under reduced pressure.

<<Impurities and the Like>>

It is preferable that the amount of impurities contained in each of the photosensitive layer, the second resin layer, the refractive index adjusting layer, and the antistatic layer is small.

Specific Examples of the impurities include sodium, potassium, magnesium, calcium, iron, manganese, copper, aluminum, titanium, chromium, cobalt, nickel, zinc, tin, and ions of these.

The content of impurities in each layer is preferably 80 ppm or less, more preferably 10 ppm or less, and still more preferably 2 ppm or less on a mass basis. The lower limit is not particularly limited, but the content of impurities in each layer may be 1 ppb or more or 0.1 ppm or more on a mass basis.

Examples of a method of keeping the impurities in the above-described range include selecting a raw material having a low content of impurities as a raw material for each layer, preventing the impurities from being mixed in a case of forming each layer, and washing and removing the impurities. By such a method, the amount of impurities can be kept within the above-described range.

The impurities can be quantified by a known method such as inductively coupled plasma (ICP) emission spectroscopy, atomic absorption spectroscopy, and ion chromatography.

It is preferable that the content of compounds such as benzene, formaldehyde, trichloroethylene, 1,3-butadiene, carbon tetrachloride, chloroform, N,N-dimethylformamide, N,N-dimethylacetamide, and hexane is low in each layer. The content of these compounds in each layer is preferably 100 ppm or less, more preferably 20 ppm or less, and still more preferably 4 ppm or less on a mass basis. The lower limit thereof may be 10 ppb or more or 100 ppb or more on a mass basis. The content of these compounds can be suppressed in the same manner as in the above-described metal as impurities. In addition, the compounds can be quantified by a known measurement method.

From the viewpoint of improving reliability and laminating property, the content of water in each layer is preferably 0.01% by mass to 1.0% by mass and more preferably 0.05% by mass to 0.5% by mass.

<Protective Film>

The photosensitive transfer material according to the embodiment of the present disclosure may further comprise a protective film on an opposite side of the photosensitive layer to the temporary support-provided side.

The above-described protective film is preferably an outermost layer on an opposite surface to the temporary support-provided side in the photosensitive transfer material according to the embodiment of the present disclosure.

Examples of the protective film include a polyethylene terephthalate film, a polypropylene film, a polystyrene film, and a polycarbonate film.

As the protective film, for example, films described in paragraphs 0083 to 0087 and 0093 of JP2006-259138A may be used.

The thickness of the protective film is preferably 1 μm to 100 μm, more preferably 5 μm to 50 μm, still more preferably 5 μm to 40 μm, and particularly preferably 15 μm to 30 μm. The thickness of the protective film is preferably 1 μm or more in terms of excellent mechanical hardness and is preferably 100 μm or less in terms of relatively low cost.

The protective film is also available as ALPHAN (registered trademark) FG-201 manufactured by Oji F-Tex Co., Ltd., ALPHAN (registered trademark) E-201F manufactured by Oji F-Tex Co., Ltd., Cerapeel (registered trademark) 25WZ manufactured by TORAY ADVANCED FILM CO., LTD., or LUMIRROR (registered trademark) 16QS62 (16KS40) manufactured by Toray Industries, Inc.

In order to make it easier to peel off the protective film from the photosensitive layer or the refractive index adjusting layer, it is preferable that the adhesive force between the protective film and the photosensitive layer or the refractive index adjusting layer is smaller than the adhesive force between the temporary support and the photosensitive layer.

The protective film preferably has 5 pieces/m² or less of the number of fisheyes with a diameter of 80 μm or more in the protective film. The “fisheye” means that, in a case where a material is hot-melted, kneaded, extruded, biaxially stretched, cast or the like to produce a film, foreign substances, undissolved substances, oxidatively deteriorated substances, and the like of the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the photosensitive layer or a metal such as a conductive layer.

In the protective film, from the viewpoint of imparting take-up property, the arithmetic average roughness Ra on a surface opposite to a surface in contact with the photosensitive layer or the refractive index adjusting layer is preferably 0.01 μm or more, more preferably 0.02 μm or more, and still more preferably 0.03 μm or more. On the other hand, the arithmetic average roughness Ra is preferably less than 0.50 μm, more preferably 0.40 μm or less, and still more preferably 0.30 μm or less.

In the protective film, from the viewpoint of suppressing defects during transfer, the surface roughness Ra on the surface in contact with the photosensitive layer or the refractive index adjusting layer is preferably 0.01 μm or more, more preferably 0.02 μm or more, and still more preferably 0.03 μm or more. On the other hand, the arithmetic average roughness Ra is preferably less than 0.50 μm, more preferably 0.40 μm or less, and still more preferably 0.30 μm or less.

—Specific Example of Photosensitive Transfer Material—

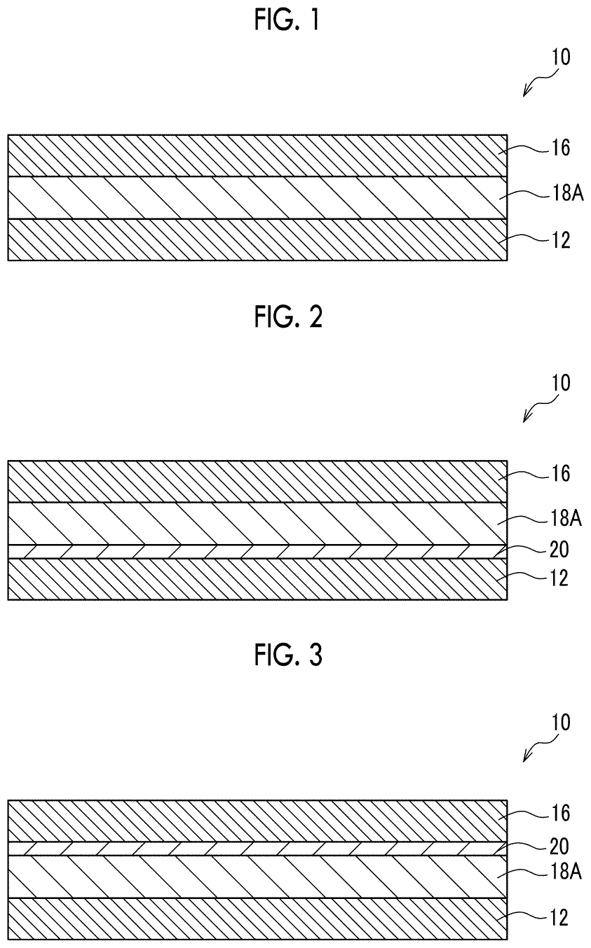

FIG. 1 is a schematic cross-sectional view showing a photosensitive transfer material 10 which is a specific example of the photosensitive transfer material according to the embodiment of the present disclosure. As shown in FIG. 1, the photosensitive transfer material 10 has a laminated structure of temporary support 12/photosensitive layer 18A/protective film 16 (that is, laminated structure in which a temporary support 12, a photosensitive layer 18A, and a protective film 16 are arranged in this order).

FIG. 2 is a schematic cross-sectional view showing a photosensitive transfer material 10 that is another specific example of the photosensitive transfer material according to the embodiment of the present disclosure. As shown in FIG. 2, the photosensitive transfer material 10 has a laminated structure of temporary support 12/antistatic layer 20/photosensitive layer 18A/protective film 16 (that is, laminated structure in which a temporary support 12, an antistatic layer 20, a photosensitive layer 18A, and a protective film 16 are arranged in this order).

Furthermore, FIG. 3 is a schematic cross-sectional view showing a photosensitive transfer material 10 that is the other specific example of the photosensitive transfer material according to the embodiment of the present disclosure. As shown in FIG. 3, the photosensitive transfer material 10 has a laminated structure of temporary support 12/photosensitive layer 18A/antistatic layer 20/protective film 16 (that is, laminated structure in which a temporary support 12, a photosensitive layer 18A, an antistatic layer 20, and a protective film 16 are arranged in this order).

However, the photosensitive transfer material according to the present disclosure is not limited to the photosensitive transfer material 10, and the protective film 16 may be omitted, for example.

A producing method of the photosensitive transfer material 10 is not particularly limited.

The method of producing the photosensitive transfer material 10 includes, for example, a step of forming the photosensitive layer 18A on the temporary support 12 and a step of forming the protective film 16 on the photosensitive layer 18A in this order.

The method of producing the photosensitive transfer material 10 may include a step of volatilizing ammonia disclosed in a paragraph 0056 of WO2016/009980A, between the step of forming the photosensitive layer 18A and the step of forming the protective film 16.

(Method of Producing Patterned Metal Conductive Material)

It is sufficient that the method of producing a patterned metal conductive material according to the embodiment of the present disclosure is a method using the photosensitive transfer material according to the embodiment of the present disclosure. However, it is preferable that the method of producing a patterned metal conductive material according to the embodiment of the present disclosure includes, in the following order, a step of transferring at least the above-described photosensitive layer in the photosensitive transfer material according to the embodiment of the present disclosure to a substrate having a metal conductive material on a surface (also referred to as a “photosensitive layer forming step”); a step of performing a pattern exposure of the above-described photosensitive layer (also referred to as a “pattern exposure step”); and a step of developing the above-described photosensitive layer to form a pattern (also referred to as a “development step”).

Hereinafter, each step in the producing method of a patterned metal conductive material according to the embodiment of the present disclosure will be described.

<Photosensitive Layer Forming Step>

The photosensitive layer forming step is a step of transferring at least the above-described photosensitive layer of the photosensitive transfer material according to the embodiment of the present disclosure to a substrate having a metal conductive material on a surface.

In the photosensitive layer forming step, the photosensitive layer is formed on the surface by laminating the photosensitive transfer material according to the embodiment of the present disclosure on the surface of the substrate which has a metal conductive material on a surface, on a side on which the metal conductive material is disposed, and transferring the photosensitive layer of the photosensitive transfer material according to the embodiment of the present disclosure on the surface.

The laminating (so-called transfer of the photosensitive layer) can be performed using a known laminator such as a vacuum laminator or an auto-cut laminator.

Examples of the substrate used in the method of producing a patterned metal conductive material according to the embodiment of the present disclosure include substrates formed of various materials including a metal conductive material on a surface, for example, a resin substrate, a glass substrate, a metal substrate, a silicon substrate, and the like, and a known structure such as an electrode may be further provided on a surface of the substrate and inside the substrate.

Among these, a glass substrate or a resin substrate is preferable as the above-described substrate.

In addition, the substrate is preferably a transparent substrate and more preferably a transparent resin substrate. The transparency in the present disclosure means that the transmittance of all visible light is 85% or more, preferably 90% or more, and more preferably 95% or more.

A refractive index of the substrate is preferably 1.50 to 1.52.

As the glass substrate, tempered glass such as GORILLA GLASS (registered trademark) manufactured by Corning Incorporated can be used. The thickness of the glass substrate is preferably 0.01 mm or more and 1.1 mm or less, and more preferably 0.1 mm or more and 0.7 mm or less.

As the resin substrate, at least one of a substrate with no optical strains or a substrate having high transparency is preferably used, and examples thereof include a substrate formed of a resin such as polyethylene terephthalate (PET), polyethylene naphthalate (PEN), polycarbonate (PC), triacetyl cellulose (TAC), polyimide (PI), polybenzoxazole (PBO), and cycloolefin polymer (COP). From the viewpoint of strength and flexibility, the thickness of the resin substrate is preferably 1.0 μm or more and 100 μm or less, and more preferably 5.0 μm or more and 50 μm or less.

As a material of the transparent substrate, a material disclosed in JP2010-086684A, JP2010-152809A, and JP2010-257492A is preferably used.

Examples of the metal in the metal conductive material include Al, Zn, Cu, Fe, Ni, Cr, Mo, Ag, Au, and the like. Among these, Au, Ag, or Cu is preferably contained, Au or Ag is more preferably contained, and Ag is particularly preferable.

As the metal conductive material, known materials can be used, metal fibers are preferable, silver fibers are more preferable, and silver nanowires are particularly preferable. In a case of adopting the above aspect, the deterioration is more likely to occur under moist heat conditions, so that the effect in the present disclosure can be further exerted.

As the laminating condition, a general condition can be applied.

The laminating temperature is preferably 80° C. to 150° C., more preferably 90° C. to 150° C., and still more preferably 100° C. to 150° C.

In a case of using a laminator including a rubber roller, the laminating temperature indicates a temperature of the rubber roller.

A temperature of the substrate in a case of laminating is not particularly limited.

The temperature of the substrate in a case of laminating is preferably 10° C. to 150° C., more preferably 20° C. to 150° C., and still more preferably 30° C. to 150° C.

In a case of using a resin substrate as the substrate, the temperature of the substrate in a case of laminating is preferably 10° C. to 80° C., more preferably 20° C. to 60° C., and still more preferably 30° C. to 50° C.

In addition, the linear pressure in a case of laminating is preferably 0.5 N/cm to 20 N/cm, more preferably 1 N/cm to 10 N/cm, and still more preferably 1 N/cm to 5 N/cm.

In addition, the transportation speed (laminating speed) in a case of laminating is preferably 0.5 m/min to 5 m/min and more preferably 1.5 m/min to 3 m/min.

In a case of using the photosensitive transfer material having a laminated structure of protective film/photosensitive layer/interlayer/thermoplastic resin layer/temporary support, first, the protective film is peeled off from the photosensitive transfer material to expose the photosensitive layer, the photosensitive transfer material and the substrate are attached to each other so that the exposed photosensitive layer and the surface of the substrate on the side on which the metal conductive material is disposed are in contact with each other, and heating and pressurizing are performed. By such an operation, the photosensitive layer of the photosensitive transfer material is transferred onto the surface of the substrate on the side on which the metal conductive material is disposed, and a film having a laminated structure of temporary support/thermoplastic resin layer/interlayer/photosensitive layer/metal conductive material/substrate is formed. In this laminated structure, the portion of the “metal conductive material/substrate” is the substrate having a metal conductive material on the surface.

Thereafter, the temporary support is peeled off from the laminate having the laminated structure, as necessary. However, the pattern exposure which will be described later can be also performed, by leaving the temporary support.

As an example of the method of transferring the photosensitive layer of the photosensitive transfer material on the substrate and performing pattern exposure and development, a description disclosed in paragraphs 0035 to 0051 of JP2006-023696A can also be referred to.

<Pattern Exposure Step>

The pattern exposure step is a step of performing a pattern exposure of the above-described photosensitive layer after the above-described photosensitive layer forming step.

The “pattern exposure” refers to exposure of the aspect of performing the exposure in a patterned shape, that is, the aspect in which an exposed portion and an unexposed portion are present.

For example, in a case where the photosensitive layer is a negative type, the exposed portion of the photosensitive layer on the substrate in the pattern exposure is cured and finally becomes the cured film. Meanwhile, the unexposed portion of the photosensitive layer on the substrate in the pattern exposure is not cured, and is dissolved and removed with a developer in the subsequent development step. With the unexposed portion, the opening portion of the cured film can be formed after the development step.

The pattern exposure may be an exposure through a mask or may be a digital exposure using a laser or the like.

As a light source of the pattern exposure, a light source can be appropriately selected, as long as it can emit light at a wavelength range (for example, 365 nm or 405 nm) at which the photosensitive layer can be cured.

Examples of the light source include various lasers, a light emitting diode (LED), an ultra-high pressure mercury lamp, a high pressure mercury lamp, and a metal halide lamp.

The exposure amount is preferably 5 mJ/cm² to 200 mJ/cm² and more preferably 10 mJ/cm² to 200 mJ/cm².

In a case where the photosensitive layer is formed on the substrate using the photosensitive transfer material, the pattern exposure may be performed after peeling the temporary support, or the temporary support may be peeled off after performing the pattern exposure before peeling off the temporary support.

In addition, in the exposure step, the heat treatment (so-called post exposure bake (PEB)) may be performed with respect to the photosensitive layer after the pattern exposure and before the development.

<Development Step>

The development step is a step of developing the above-described photosensitive layer after the above-described pattern exposure step (that is, by dissolving the unexposed portion in the pattern exposure in a developer) to form a pattern.

A developer used in the development is not particularly limited, and a well-known developer such as a developer disclosed in JP1993-72724A (JP-HOS-72724A) can be used.

As the developer, an alkali aqueous solution is preferably used.

Examples of an alkali compound which can be included in the alkali aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutyl ammonium hydroxide, and choline (2-hydroxyethyltrimethyl ammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to a total mass of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent is preferably 0.1% by mass to 30% by mass.

The developer may include a known surfactant.

The concentration of the surfactant is preferably 0.01% by mass to 10% by mass.

The liquid temperature of the developer is preferably 20° C. to 40° C.

Examples of the development method include methods such as puddle development, shower development, shower and spin development, and dip development.

In a case of the shower development, an uncured portion of the photosensitive layer is removed by the developer being sprayed to the photosensitive layer after the pattern exposure as a shower.

In a case of using the photosensitive transfer material film including the photosensitive layer and at least one of the thermoplastic resin layer or the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance, or the thermoplastic resin layer and the interlayer may be removed while the uncured portion is removed.

In addition, after the development, the development residue is preferably removed by spraying a washing agent with a shower and rubbing with a brush or the like.

The liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In a case where the photosensitive layer includes a carboxy group-containing (meth)acrylic resin, at least a part of the carboxy group-containing (meth)acrylic resin can be changed to carboxylic acid anhydride by the post baking. In a case of being changed in this way, developability and hardness of the cured film are excellent.

The development step may include a stage of performing the development, and a stage of exposing the cured film obtained by the development (hereinafter, also referred to as “post exposure”).

In a case where the development step includes both a stage of performing the post exposure and a stage of performing the post baking, it is preferable to perform the post baking after the post exposure.

With regard to the pattern exposure and the development, for example, a description described in paragraphs 0035 to 0051 of JP2006-23696A can be referred to.

The producing method of a patterned metal conductive material according to the embodiment of the present disclosure may include a step (so-called other steps) other than the steps described above.

Examples of the other step include a known step (for example, washing step) which may be provided in a normal photolithography step.

(Film)

A film according to the embodiment of the present disclosure includes a metal, and a resin layer that contains a compound A containing at least one group selected from the group consisting of a metal reducing group and a metal coordinating group.

In the film according to the embodiment of the present disclosure, the metal may be contained in the resin layer, may be contained in a layer other than the resin layer, or may be contained as a layer consisting of a metal.

In a case where the photosensitive transfer material according to the embodiment of the present disclosure is used to form the film according to the embodiment of the present disclosure, a film formed in such a manner that the photosensitive layer is transferred onto a layer consisting of a metal or a layer containing a metal, a film formed in such a manner that the photosensitive layer is transferred onto a layer consisting of a metal or a layer containing a metal and cured, a film formed in such a manner that the photosensitive layer is transferred onto a layer consisting of a metal or a layer containing a metal, exposed to form a pattern, and cured, a film formed in such a manner that a photosensitive composition is applied onto a layer consisting of a metal or a layer containing a metal, dried to form a photosensitive layer, exposed to form a pattern, and cured, and the like can be used.

As a result of intensive research conducted by the present inventor, it has been found that the film having excellent moisture-heat resistance of a metal to be used can be provided by adopting the above-described configuration.

The action mechanism of the excellent effects obtained by employing the above-described configuration is not clear, but is presumed as follows:

in a case where the above-described resin layer contains the above-described metal, since the above-described resin layer contains the above-described metal and the above-described compound A, the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed;

in a case where a layer consisting of the above-described metal separately from the above-described resin layer, since the above-described resin layer contains the above-described compound A, and the compound A moves in the photosensitive layer to adhere to the metal or to exist in the vicinity thereof, the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed;

in a case of providing a layer containing the above-described metal separately from the above-described resin layer, since the above-described resin layer contains the above-described compound A, the compound A is diffused in the transferred layer containing the metal, and the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed.

The metal is not particularly limited, and examples thereof preferably include a metal conductive material. As the metal conductive material, a known metal conductive material can be used.

Examples of the metal include Al, Zn, Cu, Fe, Ni, Cr, Mo, Ag, Au, and the like. Among these, Au, Ag, or Cu is preferably contained, Au or Ag is more preferably contained, and Ag is particularly preferable.

In addition, as the metal, metal fibers are preferable, silver fibers are more preferable, and silver nanowires are particularly preferable. In a case of adopting the above aspect, the deterioration is more likely to occur under moist heat conditions, so that the effect in the present disclosure can be further exerted.

The shape of the metal is not particularly limited, and may be provided as a layer on one entire surface of the above-described substrate, or may have a desired patterned shape. Examples thereof include a mesh-shaped transparent electrode shape, and a wire shape such as a lead wire (so-called lead-out wire) disposed on a frame portion of the touch panel.

Among these, the metal preferably contains metal fibers, and is particularly preferably a layer containing metal fibers (metal fiber layer). In addition, a layer containing the above-described metal fibers preferably has a desired patterned shape.

Examples of the shape of the metal fibers include a cylindrical shape, a rectangular parallelepiped shape, and a columnar shape having a polygonal cross-section. The metal fibers preferably have at least one shape of a cylindrical shape or a columnar shape having a polygonal cross-section in applications where high transparency is required.

The cross-sectional shape of the silver nanowires can be observed using, for example, a transmission electron microscope (TEM).

The diameter (so-called minor axis length) of the metal fibers is not particularly limited, but from the viewpoint of transparency, for example, is preferably 50 nm or less, more preferably 35 nm or less, and still more preferably 20 nm or less.

From the viewpoint of oxidation resistance and durability, the lower limit of the diameter of the metal fibers is preferably, for example, 5 nm or more.

The length (so-called major axis length) of the metal fibers is not particularly limited, but from the viewpoint of conductivity, for example, is preferably 5 μm or more, more preferably 10 μm or more, and still more preferably 30 μm or more.

From the viewpoint of suppressing formation of aggregates in the producing process, the upper limit of the length of the metal fibers is preferably, for example, 1 mm or less.

The diameter and length of the metal fibers can be measured using, for example, a transmission electron microscope (TEM) or an optical microscope.

Specifically, the diameter and length of 300 randomly selected silver nanowires are measured from the metal fibers magnified and observed using a transmission electron microscope (TEM) or an optical microscope. Values obtained by arithmetically averaging the measured values are defined as the diameter and length of the silver nanowires.

The content of the metal fibers in the metal fiber layer is not particularly limited, but from the viewpoint of transparency and conductivity, is preferably 1% by mass to 99% by mass and more preferably 10% by mass to 95% by mass with respect to a total mass of the metal fiber layer.

The metal fiber layer may include a binder (also referred to as a “matrix”), as necessary.

The binder is a solid material in which the metal fibers are dispersed or embedded.

Examples of the binder include polymer materials and inorganic materials.

As the binder, a material having light-transmitting property is preferable.

Examples of the polymer material include (meth)acrylic resins [for example, poly(methyl methacrylate)], polyesters [for example, polyethylene terephthalate (PET)], polycarbonates, polyimides, polyamides, polyolefins (for example, polypropylene), polynorbornenes, cellulose compounds, polyvinyl alcohol (PVA), and polyvinylpyrrolidone.

Examples of the cellulose compound include hydroxypropylmethyl cellulose (HPMC), hydroxyethyl cellulose (HEC), methyl cellulose (MC), hydroxypropyl cellulose (HPC), and carboxymethyl cellulose (CMC).

In addition, the polymer material may be a conductive polymer material.

Examples of the conductive polymer material include polyaniline and polythiophene.

Examples of the inorganic material include silica, mullite, and alumina.

In addition, as the binder, those described in paragraphs 0051 and 0052 of JP2014-212117A can also be used.

In a case where the metal fiber layer includes a binder, the metal fiber layer may include only one kind of the binder, or may include two or more kinds thereof.

In a case where the silver nanowire layer includes a binder, the content of the binder in the silver nanowire layer is preferably 1% by mass to 99% by mass and more preferably 5% by mass to 80% by mass with respect to a total mass of the silver nanowire layer.

The thickness of the metal fiber layer is not particularly limited, but from the viewpoint of transparency and conductivity, is preferably 1 nm to 400 nm and more preferably 10 nm to 200 nm. Within the above-described range, low resistance electrode can be formed relatively easily.

The thickness of the silver nanowire layer is measured by the following method.

In a cross-sectional observation image of the silver nanowire layer in a thickness direction, the arithmetic average value of the thickness of the silver nanowire layer measured at five randomly selected points is obtained, and the obtained value is defined as the thickness of the metal fiber layer. The cross-sectional observation image of the silver nanowire layer in the thickness direction can be obtained by using a scanning electron microscope (SEM).

In addition, the width of the metal fiber layer can also be measured in the same manner as the measuring method of the thickness of the silver nanowire layer.

The above-described resin layer is preferably a layer obtained by curing the photosensitive layer in the photosensitive transfer material according to the embodiment of the present disclosure.

In addition, the shape of the above-described resin layer is not particularly limited, and may have a desired patterned shape.

Furthermore, the above-described resin layer may have an opening portion.

The opening portion can be formed by dissolving an unexposed portion of the photosensitive layer with a developer.

The above-described resin layer preferably includes a cured resin obtained by curing a curable component (the polymerizable compound, the photopolymerization initiator, the thermal crosslinking compound, and the like) in the above-described photosensitive layer by a reaction such as polymerization.

In addition, the preferred aspect of components other than the curable component in the above-described resin layer is the same as the preferred aspect in the above-described photosensitive layer, and the preferred content of these components in the above-described resin layer is also the same as in the preferred aspect in the above-described photosensitive layer.

In addition, the preferred thickness of the above-described resin layer is the same as the preferred thickness of the above-described photosensitive layer.

The compound A in the resin layer of the film has the same meaning as the compound A in the photosensitive layer of the photosensitive transfer material according to the embodiment in the present disclosure, and the preferred aspect is also the same.

The content of the compound A in the above-described resin layer is preferably 0.01% by mass to 10% by mass, more preferably 0.05% by mass to 10% by mass, still more preferably 0.1% by mass to 5% by mass, and particularly preferably 0.1% by mass to 2% by mass with respect to a total mass of the above-described resin layer. By setting the content of the compound A within the above-described range, the moisture-heat resistance of the metal can be improved while maintaining the strength of the film.

The resin contained in the above-described resin layer is not particularly limited, and a known resin can be used.

Specific examples of the resin include an acrylic resin, a styrene resin, an epoxy resin, an amide resin, an amide epoxy resin, an alkyd resin, a phenol resin, an ester resin, a urethane resin, an epoxy acrylate resin obtained by the reaction of an epoxy resin and (meth)acrylic acid, an acid-modified epoxy acrylate resin obtained by the reaction of an epoxy acrylate resin and acid anhydride, and the like. These resins may be used alone or two or more kinds thereof may be used in combination.

Among these, a binder polymer used for the above-described photosensitive layer is suitably mentioned.

The above-described resin layer is preferably a layer obtained by the photosensitive layer being cured, and more preferably a layer formed by the photosensitive layer with any patterned shape being cured.

The thickness of the above-described resin layer is not particularly limited and can be appropriately selected as desired, but for example, the thickness is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

From the viewpoint of the moisture-heat resistance of the metal, a content of chloride ions included in the above-described resin layer is preferably 50 ppm or less, more preferably 20 ppm or less, still more preferably 10 ppm or less, particularly preferably 5 ppm or less, and most preferably 1 ppm or less with respect to a total mass of the resin layer.

The above-described resin layer may contain a component (other component) in addition to the metal, the compound A, and the resin.

As another component, a known additive can be used. Examples of another component suitably include components contained in the above-described photosensitive layer.

The resin layer is preferably achromatic. Specifically, in CIE1976 (L*, a*, b*) color space, the total reflection (incidence angle: 8°, light source: D-65 (visual field: 2°)) preferably has a resin layer L* value of 10 to 90, preferably has a resin layer a* value of −1.0 to 1.0, and preferably has a resin layer b* value of −1.0 to 1.0.

From the viewpoint of a rust inhibition property, a moisture permeability of the resin layer at a film thickness of 40 μm is preferably 500 g/(m²·24 hr) or less, more preferably 300 g/(m²·24 hr) or less, and still more preferably 100 g/(m²·24 hr) or less.

(Capacitive Input Device)

The capacitive input device according to the present disclosure includes the film according to the embodiment of the present disclosure and is preferably manufactured by using the photosensitive transfer material according to the embodiment of the present disclosure.

In addition, the above-described capacitive input device is preferably a touch panel. That is, the touch panel according to the embodiment of the present disclosure preferably includes the film according to the embodiment of the present disclosure.

In addition, the capacitive input device according to the present disclosure is preferably a laminate in which a substrate, an electrode that is the above-described metal, and the above-described resin layer are laminated in this order. In this case, the above-described electrode and the above-described resin layer correspond to the film according to the embodiment of the present disclosure.

The substrate is not particularly limited, but a glass substrate or a resin substrate is preferable. Examples of the glass substrate or the resin substrate include those described above in the method of producing a patterned metal conductive material according to the embodiment of the present disclosure.

In addition, the above-described substrate is preferably a transparent substrate and more preferably a transparent resin substrate.

A refractive index of the above-described substrate is preferably 1.41 to 1.59 and more preferably 1.50 to 1.52.

The preferred aspect of the electrode as the above-described metal in the capacitive input device according to the present disclosure is the same as the preferred aspect of the above-described metal in the film according to the embodiment of the present disclosure.

The above-described electrode may be a transparent electrode pattern or a lead wire. The above-described electrode is preferably an electrode pattern and more preferably a transparent electrode pattern.

As the transparent electrode pattern, a layer containing metal fibers or a metal mesh layer is preferable, a layer containing metal fibers is more preferable, and the silver nanowire layer described above is particularly preferable.

As a material of the lead wire, metal is preferable. Examples of the metal which is the material of the lead wire include gold, silver, copper, molybdenum, aluminum, titanium, chromium, zinc, and manganese, and alloy formed of two or more kinds of these metal elements. As the material of the lead wire, copper, molybdenum, aluminum, or titanium is preferable, copper is particularly preferable.

The preferred aspect of the above-described resin layer in the capacitive input device according to the present disclosure is the same as the preferred aspect of the above-described resin layer in the film according to the embodiment of the present disclosure.

In addition, the above-described resin layer in the capacitive input device according to the present disclosure may have a desired pattern shape.

The capacitive input device according to the present disclosure, preferably the touch panel according to the embodiment of the present disclosure, may include a refractive index adjusting layer.

The preferred aspect of the refractive index adjusting layer is the same as the preferred aspect of the refractive index adjusting layer which can be included in the photosensitive transfer material.

The refractive index adjusting layer may be formed by applying and drying a composition for forming the refractive index adjusting layer, or may be formed by transferring the refractive index adjusting layer of the photosensitive transfer material having the refractive index adjusting layer.

The aspect in which the touch panel includes the refractive index adjusting layer has an advantage in which the metal conductive material and the like are hardly visible (that is, wire visibility is prevented).

It is preferable that the capacitive input device according to the present disclosure includes the substrate, the transparent electrode pattern that is the above-described metal, the above-described resin layer disposed adjacent to the transparent electrode pattern, and the refractive index adjusting layer disposed adjacent to the above-described resin layer, and a refractive index of the resin layer is higher than a refractive index of the refractive index adjusting layer. The refractive index of the above-described resin layer is preferably 1.6 or more.

In a case of adopting the above-described configuration, a covering property of the transparent electrode pattern is improved.

As the wire for a touch panel, for example, the lead wire (lead-out wire) disposed on the frame portion of the touch panel is used. As a material of the wire for a touch panel, metal is preferable. Examples of a metal which is the material of the wire for a touch panel include gold, silver, copper, molybdenum, aluminum, titanium, chromium, zinc, manganese, and alloy formed of two or more kinds of these metal elements. Among these, as the metal which is the material of the wire for a touch panel, copper, molybdenum, aluminum, or titanium is preferable, and from the viewpoint of low electric resistance, copper is more preferable. On the other hand, since copper is easily oxidized and discolored, an antioxidant treatment may be applied to form a protective film (metal conductive material protective film).

With regard to the structure of the touch panel, a structure of a capacitive input device described in JP2014-10814A and JP2014-108541A may be referred to.

Preferred aspects of the laminate, pattern exposure, and development include the preferred aspect described above in the method of producing a patterned metal conductive material.

The touch panel according to the embodiment of the present disclosure may include a UV absorbing layer having absorption at a wavelength range of 300 nm to 400 nm in the layer structure thereof. In a case where the UV absorbing layer is provided, it is desirable that the UV absorbing layer is disposed on the visual side of the photosensitive layer. The UV absorbing layer can protect the photosensitive layer from sunlight and suppress the excitation and decomposition of the compound A.

In the UV absorbing layer, the sum of absorbances at a wavelength range of 300 nm to 400 nm is preferably 10 or more and 500 or less, more preferably 150 or more and 500 or less, and still more preferably 300 or more and 500 or less. By setting the sum of the absorbances within the above range, decomposition of the compound A can be suppressed while maintaining the transparency.

As the UV absorbing layer, an OCA to which a polarizing element and a UV absorber are added, a protective film, soda glass, or the like can be used.

—Specific Example of Touch Panel—

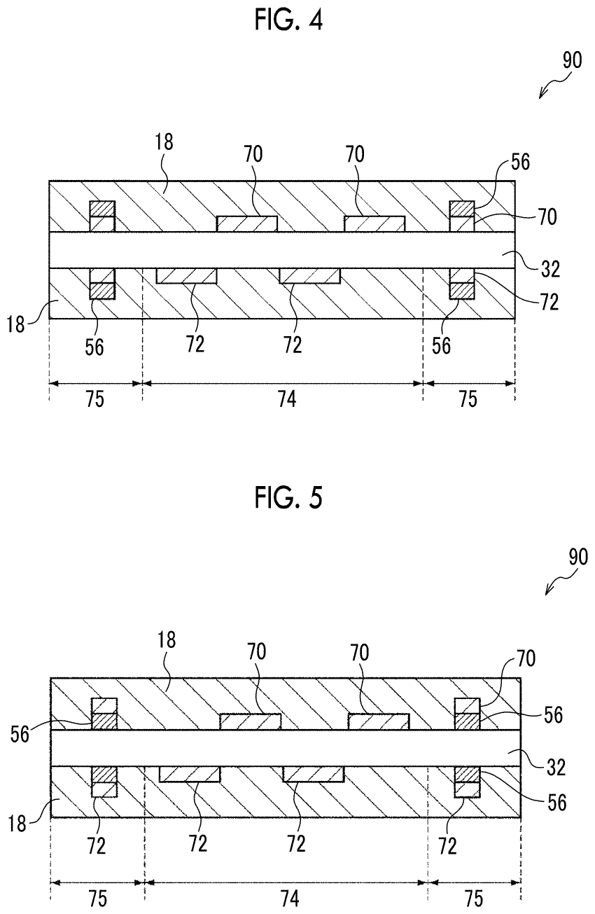

FIG. 4 is a schematic cross-sectional view of a touch panel 90 which is a first specific example of the touch panel according to the embodiment of the present disclosure.

As shown in FIG. 4, the touch panel 90 has an image display region 74 and an image non-display region 75 (that is, frame portion).

In addition, the touch panel 90 includes the electrode for a touch panel on both surfaces of the substrate 32. Specifically, the touch panel 90 includes a first metal conductive material 70 on one surface of the substrate 32 and includes a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire.

In the touch panel 90, a metal conductive material protective film 18 is formed on one surface of the substrate 32 so as to cover the first transparent electrode pattern 70 and the lead wire 56, and the metal conductive material protective film 18 is formed on the other surface of the substrate 32 so as to cover the second metal conductive material 72 and the lead wire 56.

The refractive index adjusting layer may be formed on one surface of the substrate 32.

In addition, FIG. 5 is a schematic cross-sectional view of the touch panel 90 which is the second specific example of the touch panel according to the embodiment of the present disclosure.

As shown in FIG. 5, the touch panel 90 has the image display region 74 and the image non-display region 75 (that is, frame portion).

In addition, the touch panel 90 includes the electrode for a touch panel on both surfaces of the substrate 32. Specifically, the touch panel 90 includes a first metal conductive material 70 on one surface of the substrate 32 and includes a second metal conductive material 72 on the other surface thereof.

In the touch panel 90, a lead wire 56 is connected to the first metal conductive material 70 and the second metal conductive material 72, respectively. The lead wire 56 is, for example, a copper wire or a silver wire. In addition, the lead wire 56 is formed inside surrounded by the metal conductive material protective film 18, and the first metal conductive material 70 or the second metal conductive material 72.

In the touch panel 90, a metal conductive material protective film 18 is formed on one surface of the substrate 32 so as to cover the first transparent electrode pattern 70 and the lead wire 56, and the metal conductive material protective film 18 is formed on the other surface of the substrate 32 so as to cover the second metal conductive material 72 and the lead wire 56.

The refractive index adjusting layer may be formed on one surface of the substrate 32.

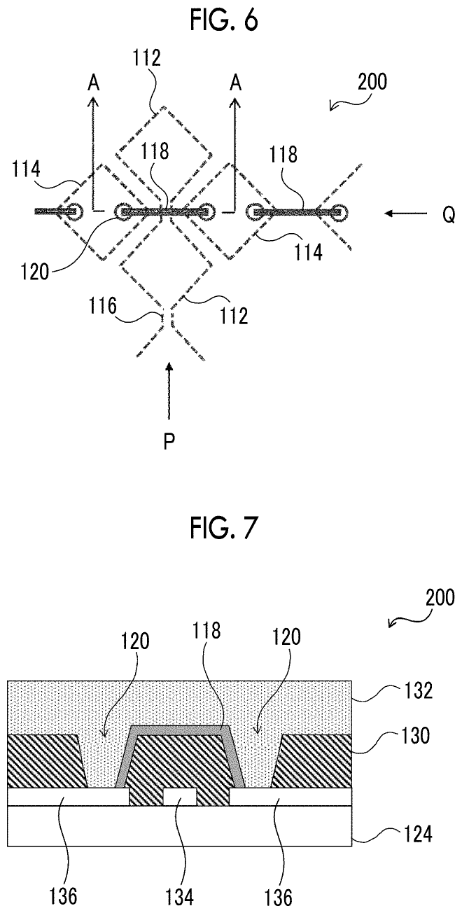

Still another embodiment of the touch sensor of the present disclosure will be described with reference to FIGS. 6 and 7.

FIG. 6 is a schematic plane view showing still another specific example of the touch panel according to the embodiment of the present disclosure, and FIG. 7 is a cross-sectional view taken along line A-A of FIG. 6.

FIGS. 6 and 7 show a transparent laminate 200 including a transparent electrode pattern (including a first island-shaped electrode portion, a first wiring portion 116, a second island-shaped electrode portion, and a bridge wiring 118), a protective layer 130, and an overcoat layer 132 on a transparent film substrate 124, in this order.

It is preferable that the protective layer 130 and the overcoat layer 132 are layers formed of the film according to the present disclosure or formed by the film according to the present disclosure being cured.

As shown in FIGS. 6 and 7, through-holes 120 for connecting a second island-shaped electrode portion 114 and the bridge wiring (a second wiring portion) 118 to make a bridge between two adjacent second island-shaped electrode portions 114 and to electrically connect the second island-shaped electrode portions 114 to each other are formed on the protective layer 130 positioned on the second island-shaped electrode portion 114 in the transparent electrode pattern on the transparent film substrate 124.

The touch sensor 200 has a first electrode pattern 134 and a second electrode pattern 136 extending in a direction of an arrow P or a direction of an arrow Q, which intersect with each other, on the transparent substrate 124, respectively.

FIGS. 6 and 7 show only a part of the touch sensor, but on the transparent substrate, the first electrode pattern 134 is arranged in one direction (first direction) over a wide range of the transparent substrate, and furthermore, the second electrode pattern 136 is arranged in a direction (second direction) different from the first direction over a wide range of the transparent substrate.

In FIG. 6, in the first electrode pattern 134, a plurality of square electrode portions (first island-shaped electrode portions) 112 are arranged in an island shape at equal intervals along the direction of the arrow P on the transparent substrate 124, and the first island-shaped electrode portions 112 adjacent to each other are connected through the first wiring portion 116 in a row. As a result, a long electrode is formed in one direction on a surface of the transparent substrate.

The first wiring portion is preferably formed of the same material as the first island-shaped electrode portion.

In FIG. 6, in the second electrode pattern 136, square electrode portions (second island-shaped electrode portions) 114 substantially similar to the first island-shaped electrode portions are arranged in an island shape at equal intervals along the direction of the arrow Q, which is substantially orthogonal to the direction of the arrow P, on the transparent substrate 124, and the second island-shaped electrode portions 114 adjacent to each other are connected through the second wiring portion 118 (bridge wiring) in a row.

As a result, a long electrode is formed in one direction different from the first electrode pattern on the surface of the transparent substrate.

As shown in FIGS. 6 and 7, the first electrode pattern 134 and the second electrode pattern 136 are provided with a bridge structure in which one of the intersecting electrodes jumps over the other at an intersecting portion so as not to conduct with each other.

In the touch sensor shown in FIG. 7, the protective layer 130 is arranged and installed to cover the first electrode pattern 134 and the second electrode pattern 136.

(Laminate)

A laminate according to an embodiment of the present disclosure includes a substrate having a metal conductive material on a surface and a resin layer containing a compound A containing at least one group selected from the group consisting of a metal reducing group and a metal coordinating group, and preferably includes the substrate having a metal conductive material on a surface, the resin layer containing the compound A containing at least one group selected from the group consisting of a metal reducing group and a metal coordinating group, and a UV absorbing layer in which an integrated absorbance for each 1 nm in a wavelength range of 300 nm to 400 nm is 10 or more, in this order.

Preferred aspects of the substrate, the UV absorbing layer, and the like in the laminate according to the embodiment of the present disclosure are the same as the preferred aspect of the substrate, the UV absorbing layer, and the like described above.

The resin layer in the laminate according to the embodiment of the present disclosure is the above-described photosensitive layer or a layer formed by the above-described photosensitive layer on which a pattern is formed and cured as necessary, and is preferably a layer formed by the photosensitive layer being cured in a patterned manner.

A preferred aspect of the resin layer in the laminate according to the embodiment of the present disclosure is the same as the above-described photosensitive layer or a layer cured in a patterned manner.

Other elements in the laminate according to the embodiment of the present disclosure can also be provided with reference to the above-described touch panel and the like.

(Method of Suppressing Deterioration)

A method of suppressing deterioration according to an embodiment of the present disclosure is a method of suppressing deterioration of a metal in a film including the metal and a resin layer, and the resin layer contains a compound A containing at least one group selected from the group consisting of a metal reducing group and a metal coordinating group.

As the film including the metal and the resin layer in the method of suppressing deterioration according to the embodiment of the present disclosure, the film according to the embodiment of the present disclosure is suitably mentioned.

In the film in the method of suppressing deterioration according to the embodiment of the present disclosure, the metal may be contained in the resin layer, may be contained in a layer other than the resin layer, or may be contained as a layer consisting of a metal.

In a case where the photosensitive transfer material according to the embodiment of the present disclosure is used to form the above-described film, a film formed in such a manner that the photosensitive layer is transferred onto a layer consisting of a metal or a layer containing a metal, a film formed in such a manner that the photosensitive layer is transferred onto a layer consisting of a metal or a layer containing a metal and cured, a film formed in such a manner that the photosensitive layer is transferred onto a layer consisting of a metal or a layer containing a metal, exposed to form a pattern, and cured, and the like can be used.

As a result of intensive research conducted by the present inventor, it has been found that the method of suppressing deterioration with excellent moisture-heat resistance of a metal to be used can be provided by adopting the above-described configuration.

The action mechanism of the excellent effects obtained by employing the above-described configuration is not clear, but is presumed as follows:

in a case where the above-described resin layer contains the above-described metal, since the above-described resin layer contains the above-described metal and the above-described compound A, the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed;

in a case where a layer consisting of the above-described metal separately from the above-described resin layer, since the above-described resin layer contains the above-described compound A, and the compound A moves in the photosensitive layer to adhere to the metal or to exist in the vicinity thereof, the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed;

in a case of providing a layer containing the above-described metal separately from the above-described resin layer, since the above-described resin layer contains the above-described compound A, the compound A is diffused in the transferred layer containing the metal, and the metal reducing group in the compound A reduces a metal that is oxidized and ionized due to moisture and oxygen oxidation over time or suppresses the oxidation and ionization itself of the metal, or the metal coordinating group in the compound A is coordinated to the metal, so that a surface of the metal is coated with the compound A, and oxidation and ionization of the metal due to moisture and oxygen oxidation over time and access of harmful substances such as halogen to the metal is suppressed, thereby deterioration of the metal being suppressed.

The compound A in the resin layer of the film has the same meaning as the compound A in the photosensitive layer of the photosensitive transfer material according to the embodiment in the present disclosure, and the preferred aspect is also the same.

The content of the compound A in the above-described resin layer is preferably 0.01% by mass or less to 10% by mass, more preferably 0.05% by mass to 10% by mass, still more preferably 0.1% by mass to 5% by mass, and particularly preferably 0.1% by mass to 2% by mass with respect to a total mass of the above-described resin layer. By setting the content of the compound A within the above-described range, the moisture-heat resistance of the metal can be improved while maintaining the strength of the film.

In the method of suppressing deterioration according to the embodiment of the present disclosure, the metal may be contained in the resin layer, may be contained in a layer other than the resin layer, or may be a layer consisting of a metal.

In the method of suppressing deterioration according to the embodiment of the present disclosure, it is preferable to use the photosensitive transfer material according to the embodiment of the present disclosure.

In a case where the photosensitive transfer material according to the embodiment of the present disclosure is used to form the above-described film, a film formed in such a manner that the photosensitive layer is transferred onto a layer consisting of a metal or a layer containing a metal, a film formed in such a manner that the photosensitive layer is transferred onto a layer consisting of a metal or a layer containing a metal and cured, a film formed in such a manner that the photosensitive layer is transferred onto a layer consisting of a metal or a layer containing a metal, exposed to form a pattern, and cured, and the like can be used.

The metal in the method of suppressing deterioration according to the embodiment of the present disclosure has the same meaning as the metal in the film in the present disclosure, and the preferred aspect is also the same.

The resin contained in the above-described resin layer is not particularly limited, and a known resin can be used.

Specific examples of the resin include those described above as the resin contained in the resin layer of the film according to the embodiment of the present disclosure.

Among these, a binder polymer used for the above-described photosensitive layer is suitably mentioned.

The above-described resin layer is preferably the above-described photosensitive layer or a layer obtained by the above-described photosensitive layer being cured, and more preferably the above-described photosensitive layer or a layer formed by the photosensitive layer with any pattern shape being cured.

The thickness of the above-described resin layer is not particularly limited and can be appropriately selected as desired, but for example, the thickness is preferably 0.01 μm or more and 20 μm or less, more preferably 0.02 μm or more and 15 μm or less, still more preferably 0.05 μm or more and 10 μm or less, and particularly preferably 1 μm or more and 10 μm or less.

From the viewpoint of the moisture-heat resistance of the metal, a content of chloride ions included in the above-described resin layer is preferably 50 ppm or less, more preferably 20 ppm or less, still more preferably 10 ppm or less, particularly preferably 5 ppm or less, and most preferably 1 ppm or less with respect to a total mass of the resin layer.

The above-described resin layer may contain a component (other component) in addition to the metal, the compound A, and the resin.

As another component, a known additive can be used. Examples of another component suitably include components contained in the above-described photosensitive layer.

The method of suppressing deterioration according to the embodiment of the present disclosure may include a step of transferring at least the above-described photosensitive layer in the photosensitive transfer material according to the embodiment of the present disclosure to a substrate having a metal conductive material on a surface, a step of performing a pattern exposure on the above-described photosensitive layer, and a step of developing the above-described photosensitive layer to form a pattern, in this order.

Each step described above is the same as each step in the method of producing a patterned metal conductive material according to the embodiment of the present disclosure.

In the method of suppressing deterioration according to the embodiment of the present disclosure, in a case where the film is a film including the resin layer on a layer consisting of a metal or a layer containing a metal, the step of removing the resin layer may be provided after the compound A adheres to a surface of the above-described layer consisting of a metal or after the compound A is diffused into the above-described layer containing a metal.

The method of suppressing deterioration according to the embodiment of the present disclosure may include a step (so-called another step) in addition to the steps described above.

Examples of another step include another step in the method of producing a patterned metal conductive material according to the embodiment of the present disclosure, and another known step.

### EXAMPLES

Hereinafter, the present disclosure will be described in more detail with reference to Examples.

The material, the amount used, the ratio, the process contents, the process procedure, and the like shown in the following examples can be appropriately changed, within a range not departing from a gist of the present disclosure. Accordingly, the range of the present disclosure is not limited to specific examples shown below.

[Preparation of Composition for Forming Photosensitive Layer]

According to the description in Tables 1 to 5 below, compositions A-1 to A-49 for forming a photosensitive layer, and A′-1 and A′-2 were prepared. The numerical values in individual component columns in Tables 1 to 5 represent the mass ratio.

Details of the abbreviations shown in Tables 1 to 5 are shown below.

<Binder Polymer>

Compound P-1: Styrene/methacrylic acid/dicyclopentadienyl methacrylate/methacrylic acid-glycidyl methacrylate adduct=41/24/15/20 (molar ratio), weight-average molecular weight: 19,000, ClogP value=2.52

Compound P-2: Random copolymerized substance of benzyl methacrylate/methacrylic acid=72/28 (molar ratio), weight-average molecular weight: 37,000, ClogP value=2.52

Compound P-3: Polymer having the structure shown below, weight-average molecular weight: 27,000, ClogP value=2.17

Compound P-5: Random copolymerized substance of benzyl methacrylate/methacrylic acid=70/30 (molar ratio), weight-average molecular weight: 30,000, ClogP value=2.49

Compound P-6: Random copolymerized substance of benzyl methacrylate/methacrylic acid=70/30 (molar ratio), weight-average molecular weight: 56,000, ClogP value=2.49

Compound P-7: Random copolymerized substance of benzyl methacrylate/methacrylic acid=70/30 (molar ratio), weight-average molecular weight: 12,000, ClogP value=2.49

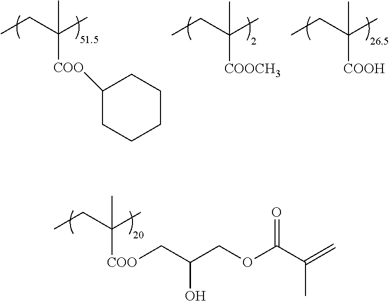

Compound P-4: Polymer having the structure shown below, weight-average molecular weight 18,000, ClogP value=2.26

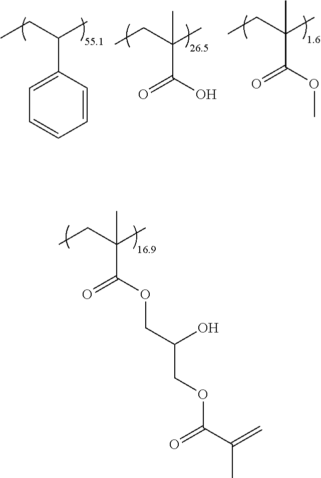

The compound P-3 was prepared through a polymerization step and an additional step shown below.

—Polymerization Step—

60 g of propylene glycol monomethyl ether acetate (manufactured by SANWA KAGAKU SANGYO Co., Ltd, PGMEA) and 240 g of propylene glycol monomethyl ether (manufactured by SANWA KAGAKU SANGYO Co., Ltd, trade name PGM) were introduced into a 2000 mL flask. The obtained liquid was stirred at a stirring speed of 250 rpm (round per minute; the same applies hereinafter) and the temperature thereof was raised to 90° C. As a preparation of a dropwise addition liquid (1), 107.1 g of methacrylic acid (manufactured by Mitsubishi Rayon Co., Ltd., trade name Acryester M), 5.46 g of methyl methacrylate (manufactured by Mitsubishi Gas Chemical Company Inc., trade name MMA), and 231.42 g of cyclohexyl methacrylate (manufactured by Mitsubishi Gas Chemical Company, Inc., trade name CHMA) were mixed and diluted with 60 g of PGMEA to obtain the dropwise addition liquid (1).

As a preparation of a dropwise addition liquid (2), 9.637 g of dimethyl 2,2′-azobis(2-methylpropionate) (manufactured by FUJIFILM Wako Pure Chemical Corporation, trade name V-601) was dissolved with 136.56 g of PGMEA to obtain the dropwise addition liquid (2).

The dropwise addition liquid (1) and the dropwise addition liquid (2) were simultaneously added dropwise to the above-described 2000 mL flask (specifically, a 2000 mL flask containing a liquid heated to 90° C.) over 3 hours.

Next, a container in which the dropwise addition liquid (1) was charged was washed with 12 g of PGMEA, and the washing liquid was added dropwise to the 2000 mL flask. Next, a container in which the dropwise addition liquid (2) was charged was washed with 6 g of PGMEA, and the washing liquid was added dropwise to the 2000 mL flask. During these dropwise additions, the reaction solution in the 2000 mL flask was kept at 90° C. and stirred at a stirring speed of 250 rpm. Furthermore, as a post-reaction, the mixture was stirred at 90° C. for 1 hour.

2.401 g of V-601 was added to the reaction solution after the post-reaction as the first additional addition of an initiator. Furthermore, a container in which V-601 was charged was washed with 6 g of PGMEA, and the washing liquid was introduced into the reaction solution. Thereafter, stirring was carried out for 1 hour at 90° C.

Next, 2.401 g of V-601 was added to the reaction solution as the second additional addition of the initiator. Furthermore, a container in which V-601 was charged was washed with 6 g of PGMEA, and the washing liquid was introduced into the reaction solution. Next, the solution was stirred at 90° C. for 1 hour.

Next, 2.401 g of V-601 was added to the reaction solution as the third additional addition of the initiator. Furthermore, a container in which V-601 was charged was washed with 6 g of PGMEA, and the washing liquid was introduced into the reaction solution. Next, the solution was stirred at 90° C. for 3 hours.

—Additional Step—

After the stirring was performed at 90° C. for 3 hours, 178.66 g of PGMEA was introduced into the reaction solution. Next, 2.7 g of tetraethylammonium acetate (manufactured by FUJIFILM Wako Pure Chemical Corporation) and 0.8 g of hydroquinone monomethyl ether (manufactured by FUJIFILM Wako Pure Chemical Corporation) were added to the reaction solution. Furthermore, each container was washed with 6 g of PGMEA, and the washing liquid was introduced into the reaction solution. Thereafter, the temperature of the reaction solution was raised to 100° C.

Next, 76.03 g of glycidyl methacrylate (manufactured by NOF Corporation, trade name Blemmer GH) was added dropwise to the reaction solution for 1 hour. A container in which Blemmer GH was charged was washed with 6 g of PGMEA, and the washing liquid was introduced into the reaction solution. Then, as an additional reaction, the mixture was stirred at 100° C. for 6 hours.

Next, the reaction solution was cooled and filtered through a mesh filter (100 mesh) for removing dust to obtain 1158 g of a solution of the compound P-3. The obtained solution of the compound P-3 was dried, a solvent was evaporated and redissolved with PGEMA to obtain a solution of the compound P-3 having a concentration of solid contents of 27.0% by mass. A weight-average molecular weight of the obtained compound P-3 was 27,000, the number-average molecular weight was 15,000, and an acid value was 95 mgKOH/g.

The compound P-4 was prepared by steps shown below.

113.5 g of propylene glycol monomethyl ether was charged into a flask and heated to 90° C. under a nitrogen stream. A solution in which 172 g of styrene, 4.7 g of methyl methacrylate, and 112.1 g of methacrylic acid had been dissolved in 30 g of propylene glycol monomethyl ether and a solution in which 27.6 g of a polymerization initiator V-601 (manufactured by FUJIFILM Wako Pure Chemical Corporation) had been dissolved in 57.7 g of propylene glycol monomethyl ether were simultaneously added dropwise to this liquid, over 3 hours. After the dropwise addition, 2.5 g of V-601 was added three times every hour. Thereafter, the reaction was continued for another 3 hours. Thereafter, the reaction solution was diluted with 160.7 g of propylene glycol monomethyl ether acetate and 233.3 g of propylene glycol monomethyl ether. The reaction solution was heated to 100° C. under an air stream, and 1.8 g of tetraethylammonium bromide and 0.86 g of p-methoxyphenol were added thereto. 71.9 g of glycidyl methacrylate (Blemmer GH manufactured by NOF Corporation.) was added dropwise thereto over 20 minutes. The mixture was reacted at 100° C. for 7 hours to obtain a solution of a compound P-4. The obtained solution of the compound P-4 was dried, a solvent was evaporated, and the solution was redissolved with PGEMA to obtain a solution of the compound P-4 having a concentration of solid contents of 27.0% by mass. The weight-average molecular weight in terms of standard polystyrene in GPC was 18,000, the dispersity was 2.3, and the acid value of the polymer was 124 mgKOH/g. The amount of residual monomer measured by gas chromatography was less than 0.1% by mass with respect to the solid content of the polymer in any of the monomers.

TABLE 1

| Composition for forming photosensitive layer | | A-1 | A-2 | A-3 | A-4 | A-5 | A-6 | A-7 | A-8 | A-9 | A10 |
|---|---|---|---|---|---|---|---|---|---|---|---|
| Radical polymerizable | 1,9-nonanediol diacrylate (A-NOD-N, | 2.77 | 2.74 | 2.71 | 2.66 | 2.60 | 2.49 | 2.71 | 2.71 | 2.71 | 2.71 |
| compound | manufactured by Shin-Nakamura Chemical Co., Ltd.) | | | | | | | | | | |
| | Dipentaerythritol hexaacrylate | 3.69 | 3.66 | 3.62 | 3.54 | 3.47 | 3.32 | 3.62 | 3.62 | 3.62 | 3.62 |
| | (KAYARAD DPHA, manufactured by Nippon | | | | | | | | | | |
| | Kayaku Co., Ltd.) of 75% by mass PGMEA solution | | | | | | | | | | |
| | Trimethylolpropane triacrylate (A-TMPT, | — | — | — | — | — | — | — | — | — | — |
| | manufactured by Shin-Nakamura Chemical Co., Ltd.) | | | | | | | | | | |
| | Ditrimethylolpropane tetraacrylate | — | — | — | — | — | — | — | — | — | — |
| | (AD-TMP, manufactured by Shin-Nakamura | | | | | | | | | | |
| | Chemical Co., Ltd.) | | | | | | | | | | |
| | Tricyclodecane dimethanol diacrylate | — | — | — | — | — | — | — | — | — | — |
| | (A-DCP, manufactured by Shin-Nakamura | | | | | | | | | | |
| | Chemical Co., Ltd.) | | | | | | | | | | |
| | Adamantyl diacrylate (ADDA, manufactured | — | — | — | — | — | — | — | — | — | — |
| | by Mitsubishi Gas Chemical Company Inc.) | | | | | | | | | | |
| Binder polymer | 27% by mass PGMEA solution of P-1 | 34.19 | 33.85 | 33.51 | 32.82 | 32.13 | 30.76 | 33.51 | 33.51 | 33.51 | 33.51 |
| | 27% by mass PGMEA solution of P-2 | — | — | — | — | — | — | — | — | — | — |
| | 27% by mass PGMEA solution of P-3 | — | — | — | — | — | — | — | — | — | — |
| Photopolymerization | [8-[5-(2,4,6-trimethylphenyl)-11-(2-ethylhexyl)-11H- | 0.18 | 0.18 | 0.18 | 0.17 | 0.17 | 0.16 | 0.18 | 0.18 | 0.18 | 0.18 |
| initiator | benzo[a]carbazoyl][2-(2,2,3,3-tetrafluoropropoxy)phenyl] | | | | | | | | | | |
| | methanone-(O-acetyloxime) | | | | | | | | | | |
| | (IRGACURE OXE-03, manufactured by BASF SE) | | | | | | | | | | |
| | 1-[9-ethyl-6-(2-methylbenzoyl)-9H- | — | — | — | — | — | — | — | — | — | — |
| | carbazol-3-yl]ethanone-1-(O-acetyloxime) | | | | | | | | | | |
| | (IRGACURE OXE-02, manufactured by BASF SE) | | | | | | | | | | |
| | 2-(dimethylamino)-2-[(4-methylphenyl)methyl]-1-[4-(4- | — | — | — | — | — | — | — | — | — | — |
| | morpholinyl)phenyl]-1-butanone | | | | | | | | | | |
| | (IRGACURE 379EG, manufactured by BASF SE) | | | | | | | | | | |
| | 1,2-octanedione-1-[4-(phenylthio)phenyl]- | — | — | — | — | — | — | — | — | — | — |
| | 2-(O-benzoyloxime) (IRGACURE OXE-01, | | | | | | | | | | |
| | manufactured by BASF SE) | | | | | | | | | | |
| | 2-hydroxy-4′-(2-hydroxyethoxy)-2-methylpropiophenone | — | — | — | — | — | — | — | — | — | — |
| | (IRGACURE 2959, manufactured by BASF SE) | | | | | | | | | | |
| Hydrogen donating | N-phenylglycine (Manufactured by Tokyo | — | — | — | — | — | — | — | — | — | — |
| compound | Chemical Industry Co., Ltd.) | | | | | | | | | | |
| | Naphthoquinone (Manufactured by Tokyo | — | — | — | — | — | — | — | — | — | — |
| | Chemical Industry Co., Ltd.) | | | | | | | | | | |
| | 2,4-diphenyl-4-methyl-1-pentene | — | — | — | — | — | — | — | — | — | — |
| | (Manufactured by Tokyo Chemical Industry Co., Ltd.) | | | | | | | | | | |
| Compound A | 4-methylthio benzaldehyde (Manufactured | 0.0015 | 0.15 | 0.30 | 0.60 | 0.90 | 1.50 | — | — | — | — |
| | by Tokyo Chemical Industry Co., Ltd.), I/O ratio = 0.50 | | | | | | | | | | |
| | Thioanisole (Manufactured by Tokyo | — | — | — | — | — | — | 0.30 | — | — | — |
| | Chemical Industry Co., Ltd.), I/O ratio = 0.19 | | | | | | | | | | |
| | 4-(4-formylphenyl)morpholine | — | — | — | — | — | — | — | 0.30 | — | — |
| | (Manufactured by Tokyo Chemical Industry | | | | | | | | | | |
| | Co., Ltd.), I/O ratio = 0.77 | | | | | | | | | | |
| | 4-ethylbenzaldehyde (Manufactured by | — | — | — | — | — | — | — | — | 0.30 | — |
| | Tokyo Chemical Industry Co., Ltd.), I/O ratio = 0.44 | | | | | | | | | | |
| | 2-aminobenzothiazole (Manufactured by | — | — | — | — | — | — | — | — | — | 0.30 |
| | Tokyo Chemical Industry Co., Ltd.), I/O ratio = 1.03 | | | | | | | | | | |
| Surfactant | MEGAFACE F551A (manufactured by DIC | 0.16 | 0.16 | 0.16 | 0.16 | 0.16 | 0.16 | 0.16 | 0.16 | 0.16 | 0.16 |
| | Corporation) (30% by mass PGMEA solution) | | | | | | | | | | |
| | DOWQIL 8032 additive (manufactured by | — | — | — | — | — | — | — | — | — | — |
| | Dow Corning Toray Co., Ltd.) (30% by mass PGMEA solution) | | | | | | | | | | |
| Solvent | Propylene glycol monomethyl ether acetate (PGMEA) | 33.51 | 33.76 | 34.02 | 34.54 | 35.06 | 36.10 | 34.02 | 34.02 | 34.02 | 34.02 |
| | Methyl ethyl ketone (MEK) | 25.50 | 25.50 | 25.50 | 25.50 | 25.50 | 25.50 | 25.50 | 25.50 | 25.50 | 25.50 |

TABLE 2

| Composition for forming photosensitive layer | | A-11 | A-12 | A-13 | A-14 | A-15 | A-16 | A-17 | A-18 | A-19 | A-20 |
|---|---|---|---|---|---|---|---|---|---|---|---|
| Radical | 1,9-nonanediol diacrylate | 2.71 | — | — | — | 1.68 | 3.60 | 2.71 | 2.71 | 2.71 | — |
| polymerizable | (A-NOD-N, MANUFACTURED BY SHIN-NAKAMURA CHEMICAL CO., LTD.) | | | | | | | | | | |
| compound | Dipentaerythritol hexaacrylate | 3.62 | 6.33 | — | — | 2.24 | 4.81 | 3.62 | 3.62 | 3.62 | — |
| | (KAYARAD DPHA, manufactured by Nippon Kayaku Co., Ltd.) of 75% | | | | | | | | | | |
| | by mass PGMEA solution | | | | | | | | | | |
| | Trimethylolpropane triacrylate | — | — | — | — | — | — | — | — | — | — |
| | (A-TMPT, manufactured by Shin-Nakamura Chemical Co., Ltd.) | | | | | | | | | | |
| | Ditrimethylolpropane tetraacrylate | — | — | — | — | — | — | — | — | — | — |
| | (AD-TMP, manufactured by Shin-Nakamura Chemical Co., Ltd.) | | | | | | | | | | |
| | Tricyclodecane dimethanol diacrylate | — | — | 6.33 | — | — | — | — | — | — | 6.33 |
| | (A-DCP, manufactured by Shin-Nakamura Chemical Co., Ltd.) | | | | | | | | | | |
| | Adamantyl diacrylate | — | — | — | 6.33 | — | — | — | — | — | — |
| | (ADDA, manufactured by Mitsubishi Gas Chemical Company Inc.) | | | | | | | | | | |
| Binder polymer | 27% by mass PGMEA solution of P-1 | — | 33.51 | 33.5 | 33.51 | 41.43 | 26.70 | 33.51 | 33.51 | 33.51 | — |
| | 27% by mass PGMEA solution of P-2 | 33.51 | — | — | — | — | — | — | — | — | 33.51 |
| | 27% by mass PGMEA solution of P-3 | — | — | — | — | — | — | — | — | — | — |
| Photopolymerization | [8-[5-(2,4,6-trimethylphenyl)-11-(2-ethylhexyl)-11H-benzo[a]carbazoyl][2-(2,2,3,3- | 0.18 | 0.18 | 0.18 | 0.18 | 0.11 | 0.24 | — | — | 0.09 | — |
| initiator | tetrafluoropropoxy)phenyl]methanone-(O-acetyloxime) (IRGACURE OXE-03, | | | | | | | | | | |
| | manufactured by BASF SE) | | | | | | | | | | |
| | 1-[9-ethyl-6-(2-methylbenzoy1)-9H-carbazol-3-yl]ethanone-1-(O-acetyloxime) | — | — | — | — | — | — | 0.18 | — | — | — |
| | (IRGACURE OXE-02, manufactured by BASF SE) | | | | | | | | | | |
| | 2-(dimethylamino)-2-[(4-methylphenyl)methyl]-1-[4-(4-morpholinyl)pheny1]-1- | — | — | — | — | — | — | — | 0.18 | 0.09 | — |
| | butanone (IRGACURE 379EG, manufactured by BASF SE) | | | | | | | | | | |
| | 1,2-octanedione-1-[(4-(phenylthio)pheny1]-2-(O-benzoyloxime) | — | — | — | — | — | — | — | — | — | 0.18 |
| | (IRGACURE OXE-01, manufactured by BASF SE) | | | | | | | | | | |
| | 2-hydroxy-4′-(2-hydroxyethoxy)-2-methylpropiophenone | — | — | — | — | — | — | — | — | — | — |
| | (IRGACURE 2959, manufactured by BASF SE) | | | | | | | | | | |
| Hydrogen donating | N-phenylglycine (Manufactured by Tokyo Chemical Industry Co., Ltd.) | — | — | — | — | — | — | — | — | — | — |
| compound | Naphthoquinone (Manufactured by Tokyo Chemical Industry Co., Ltd.) | — | — | — | — | — | — | — | — | — | — |
| | 2,4-diphenyl-4-methyl-1-pentene (Manufactured by Tokyo Chemical Industry Co., Ltd.) | — | — | — | — | — | — | — | — | — | — |
| Compound A | 4-methylthio benzaldehyde | 0.30 | 0.30 | 0.30 | 0.30 | 0.30 | 0.30 | 0.30 | 0.30 | 0.30 | 0.30 |
| | (Manufactured by Tokyo Chemical Industry Co., Ltd.), I/O ratio = 0.50 | | | | | | | | | | |
| | Thioanisole | — | — | — | — | — | — | — | — | — | — |
| | (Manufactured by Tokyo Chemical Industry Co., Ltd.), I/O ratio = 0.19 | | | | | | | | | | |
| | 4-(4-formylphenyl)morpholine | — | — | — | — | — | — | — | — | — | — |
| | (Manufactured by Tokyo Chemical Industry Co., Ltd.), I/O ratio = 0.77 | | | | | | | | | | |
| | 4-ethylbenzaldehyde | — | — | — | — | — | — | — | — | — | — |
| | (Manufactured by Tokyo Chemical Industry Co., Ltd.), I/O ratio = 0.44 | | | | | | | | | | |
| | 2-aminobenzothiazole | — | — | — | — | — | — | — | — | — | — |
| | (Manufactured by Tokyo Chemical Industry Co., Ltd.), I/O ratio = 1.03 | | | | | | | | | | |
| Surfactant | MEGAFACE F551A (manufactured by DIC Corporation) | 0.16 | 0.16 | 0.16 | 0.16 | 0.16 | 0.16 | 0.16 | 0.16 | 0.16 | — |
| | (30% by mass PGMEA solution) | | | | | | | | | | |
| | DOWQIL 8032 additive (manufactured by Dow Coming Toray Co., Ltd.) | — | — | — | — | — | — | — | — | — | 0.16 |
| | (30% by mass PGMEA solution) | | | | | | | | | | |
| Solvent | Propylene glycol monomethyl ether acetate | 34.02 | 34.02 | 34.02 | 34.02 | 28.58 | 38.70 | 34.02 | 34.02 | 34.02 | 34.02 |
| | (PGMEA) | | | | | | | | | | |
| | Methyl ethyl ketone | 25.50 | 25.50 | 25.50 | 25.50 | 25.50 | 25.50 | 25.50 | 25.50 | 25.50 | 25.50 |
| | (MEK) | | | | | | | | | | |

TABLE 3

| Composition for form ng photosensitive layer | | A-21 | A-22 | A-23 | A-24 | A-25 | A-26 | A-27 | A-28 | A-29 | A-30 |
|---|---|---|---|---|---|---|---|---|---|---|---|
| Radical | 1,9-nonanediol diacrylate | 2.71 | 2.70 | 2.69 | 2.63 | 2.58 | 2.44 | 2.63 | 2.63 | 2.63 | 2.63 |
| polymerizable | (A-NOD-N, MANUFACTURED BY SHIN-NAKAMURA CHEMICAL CO., LTD.) | | | | | | | | | | |
| compound | Dipentaerythritol hexaacrylate | 3.61 | 3.60 | 3.58 | 3.51 | 3.43 | 3.25 | 3.51 | 3.51 | 3.51 | 3.51 |
| | (KAYARAD DPHA, manufactured by Nippon Kayaku Co., Ltd.) of 75% by mass | | | | | | | | | | |
| | PGMEA solution | | | | | | | | | | |
| | Trimethylolpropane triacrylate | — | — | — | — | — | — | — | — | — | — |
| | (A-TMPT, manufactured by Shin-Nakamura Chemical Co., Ltd.) | | | | | | | | | | |
| | Ditrimethylolpropane tetraacrylate | — | — | — | — | — | — | — | — | — | — |
| | (AD-TMP, manufactured by Shin-Nakamura Chemical Co., Ltd.) | | | | | | | | | | |
| | Tricyclodecane dimethanol diacrylate | — | — | — | — | — | — | — | — | — | — |
| | (A-DCP, manufactured by Shin-Nakamura Chemical Co., Ltd.) | | | | | | | | | | |
| | Adamantyl diacrylate | — | — | — | — | — | — | — | — | — | — |
| | (ADDA, manufactured by Mitsubishi Gas Chemical Company Inc.) | | | | | | | | | | |
| Binder polymer | 27% by mass PGMEA solution of P-1 | — | — | — | — | — | — | — | — | — | — |
| | 27% by mass PGMEA solution of P-2 | 33.47 | 33.33 | 33.16 | 32.48 | 31.79 | 30.08 | 32.48 | 32.48 | 32.48 | 32.48 |
| | 27% by mass PGMEA solution of P-3 | — | — | — | — | — | — | — | — | — | — |
| | [8-[5-(2,4,6-trimethylpheny1)-11-(2-ethylhexyl)-11H-benzo[a]carbazoyl][2-(2,2,3,3- | 0.18 | 0.18 | 0.18 | 0.17 | 0.17 | 0.16 | 0.03 | 0.03 | — | — |
| | tetrafluoropropoxy)phenyl]methanone-(O-acetyloxime) (IRGACURE OXE-03, | | | | | | | | | | |
| | manufactured by BASF SE) | | | | | | | | | | |
| | 1-[9-ethyl-6-(2-methylbenzoy1)-9H-carbazol-3-yl]ethanone-1-(O-acetyloxime) | — | — | — | — | — | — | — | — | — | — |
| | (IRGACURE OXE-02, manufactured by BASF SE) | | | | | | | | | | |
| Photopolymerization | 2-(dimethylamino)-2-[(4-methylphenyl)methyl]-1-[4-(4-morpholinyl)pheny1]-1- | — | — | — | — | — | — | 0.14 | — | 0.17 | — |
| initiator | butanone (IRGACURE 379EG, manufactured by BASF SE) | | | | | | | | | | |
| | 1,2-octanedione-1[4-(phenylthio)pheny1]-2-(O-benzoyloxime) | — | — | — | — | — | — | — | — | — | — |
| | (IRGACURE OXE-01, manufactured by BASF SE) | | | | | | | | | | |
| | 2-hydroxy-4′-(2-hydroxyethoxy)-2-methylpropiophenone | — | — | — | — | — | — | — | 0.14 | — | 0.17 |
| | (IRGACURE 2959, manufactured by BASF SE) | | | | | | | | | | |
| Hydrogen donating | N-phenylglycine (Manufactured by Tokyo Chemical Industry Co., Ltd.) | 0.015 | 0.075 | 0.15 | 0.45 | 0.75 | 1.50 | 0.45 | 0.45 | 0.45 | 0.45 |
| compound | Naphthoquinone (Manufactured by Tokyo Chemical Industry Co., Ltd.) | — | — | — | — | — | — | — | — | — | — |
| | 2,4-diphenyl-4-methyl-1-pentene (Manufactured by Tokyo Chemical Industry Co., Ltd.) | — | — | — | — | — | — | — | — | — | — |
| Compound A | 4-methylthio benzaldehyde | 0.30 | 0.30 | 0.30 | 030 | 0.30 | 0.30 | 0.30 | 030 | 030 | 0.30 |
| | (Manufactured by Tokyo Chemical Industry Co., Ltd.), I/O ratio = 0.50 | | | | | | | | | | |
| | Thioanisole | — | — | — | — | — | — | — | — | — | — |
| | (Manufactured by Tokyo Chemical Industry Co., Ltd.), I/O ratio = 0.19 | | | | | | | | | | |
| | 4-(4-formylphenyl)morpho line | — | — | — | — | — | — | — | — | — | — |
| | (Manufactured by Tokyo Chemical Industry Co., Ltd.), I/O ratio = 0.77 | | | | | | | | | | |
| | 4-ethylbenzaldehyde | — | — | — | — | — | — | — | — | — | — |
| | (Manufactured by Tokyo Chemical Industry Co., Ltd.), I/O ratio = 0.44 | | | | | | | | | | |
| | 2-aminobenzothiazole | — | — | — | — | — | — | — | — | — | — |
| | (Manufactured by Tokyo Chemical Industry Co., Ltd.), I/O ratio = 1.03 | | | | | | | | | | |
| Surfactant | MEGAFACE F551A (manufactured by DIC Coiporation) | 0.16 | 0.16 | 0.16 | 0.16 | 0.16 | 0.16 | 0.16 | 0.16 | 0.16 | 0.16 |
| | (30% by mass PGMEA solution) | | | | | | | | | | |
| | DOWQIL 8032 additive (manufactured by Dow Corning Toray Co., Ltd.) | — | — | — | — | — | — | — | — | — | — |
| | (30% by mass PGMEA solution) | | | | | | | | | | |
| Solvent | Propylene glycol monomethyl ether acetate | 34.05 | 34.15 | 34.28 | 34.80 | 35.32 | 36.62 | 34.80 | 34.80 | 34.80 | 34.80 |
| | (PGMEA) | | | | | | | | | | |
| | Methyl ethyl ketone | 25.50 | 25.50 | 25.50 | 25.50 | 25.50 | 25.50 | 25.50 | 25.50 | 25.50 | 25.50 |
| | (MEK) | | | | | | | | | | |

TABLE 4

| Composition for forming photosensitive layer | | A-31 | A-32 | A-33 | A-34 | A-35 | A-36 | A-37 | A-38 | A-39 | A-40 |
|---|---|---|---|---|---|---|---|---|---|---|---|
| Radical | 1,9-nonanediol diacrylate | 5.26 | — | — | — | — | — | 2.10 | 2.10 | 2.63 | 2.63 |
| polymerizable | (A-NOD-N, MANUFACTURED BY SHIN-NAKAMURA CHEMICAL CO., LTD.) | | | | | | | | | | |
| compound | Dipentaerythritolhexaacrylate | — | 7.01 | — | — | — | — | 1.41 | 1.41 | 3.51 | 3.51 |
| | (KAYARAD DPHA, manufactured by Nippon Kayaku Co., Ltd.) of 75% by | | | | | | | | | | |
| | mass PGMEA solution | | | | | | | | | | |
| | Trimethylolpropane triacrylate | — | — | 5.26 | — | — | — | 2.10 | — | — | — |
| | (A-TMPT, manufactured by Shin-Nakamura Chemical Co., Ltd.) | | | | | | | | | | |
| | Ditrimethylolpropane tetraacrylate | — | — | — | 5.26 | — | — | — | 2.10 | — | — |
| | (AD-TMP, manufactured by Shin-Nakamura Chemical Co., Ltd.) | | | | | | | | | | |
| | Tricyclodecane dimethanol diacrylate | — | — | — | — | 5.26 | — | — | — | — | — |
| | (A-DCP, manufactured by Shin-Nakamura Chemical Co., Ltd.) | | | | | | | | | | |
| | Adamantyl diacrylate | — | — | — | — | — | 5.26 | — | — | — | — |
| | (ADDA, manufactured by Mitsubishi Gas Chemical Company Inc.) | | | | | | | | | | |
| Binder polymer | 27% by mass PGMEA solution of P-1 | — | — | — | — | — | — | — | — | 32.48 | — |
| | 27% by mass PGMEA solution of P-2 | 32.48 | 32.48 | 32.48 | 32.48 | 32.48 | 32.48 | 32.48 | 32.48 | — | — |
| | 27% by mass PGMEA solution of P-3 | — | — | — | — | — | — | — | — | — | 32.48 |
| | [8-[5-(2,4,6-trimethylpheny1)-11-(2-ethy lhexy 1)-11H-b enzo [a]carb azoy 1][2- | 0.17 | 0.17 | 0.17 | 0.17 | 0.17 | 0.17 | 0.17 | 0.17 | 0.17 | 0.17 |
| | (2,2,3,3-tetrafluo ropropoxy)phenyl]methanone-(O-acetyloxime) (IRGACURE | | | | | | | | | | |
| | OXE-03, manufactured by BASF SE) | | | | | | | | | | |
| | 1-[9-ethyl-6-(2-methylbenzoy1)-9H-carbazol-3-yl]ethanone-1-(O-acetyloxime) | — | — | — | — | — | — | — | — | — | — |
| | (IRGACURE OXE-02, manufactured by BASF SE) | | | | | | | | | | |
| Photopolymerization | 2-(dimethylamino)-2-[(4-methylphenyl)methyl]-144-(4-morpholinyl)pheny1]-1-butanone | — | — | — | — | — | — | — | — | — | — |
| initiator | (IRGACURE 379EG, manufactured by BASF SE) | | | | | | | | | | |
| | 1,2-octanedione-1[4-(phenylthio)pheny1]-2-(O-benzoyloxime) | — | — | — | — | — | — | — | — | — | — |
| | (IRGACURE OXE-01, manufactured by BASF SE) | | | | | | | | | | |
| | 2-hydroxy-4′-(2-hydroxyethoxy)-2-methylpropiophenone | — | — | — | — | — | — | — | — | — | — |
| | (IRGACURE 2959, manufactured by BASF SE) | | | | | | | | | | |
| | N-phenylglycine (Manufactured by Tokyo Chemical Industry Co., Ltd.) | 0.45 | 0.45 | 0.45 | 0.45 | 0.45 | 0.45 | 0.45 | 0.45 | 0.45 | 0.45 |
| Hydrogen donating | Naphthoquinone (Manufactured by Tokyo Chemical Industry Co., Ltd.) | — | — | — | — | — | — | — | — | — | — |
| compound | 2,4-diphenyl-4-methyl-1-pentene (Manufactured by Tokyo Chemical Industry Co., Ltd.) | — | — | — | — | — | — | — | — | — | — |
| Compound A | 4-methylthio benzaldehyde | 030 | 030 | 030 | 0.30 | 030 | 0.30 | 0.30 | 0.30 | 0.30 | 0.30 |
| | (Manufactured by Tokyo Chemical Industry Co., Ltd.), I/O ratio = 0.50 | | | | | | | | | | |
| | Thioanisole | — | — | — | — | — | — | — | — | — | — |
| | (Manufactured by Tokyo Chemical Industry Co., Ltd.), I/O ratio = 0.19 | | | | | | | | | | |
| | 4-(4-formylphenyl)morpholine | — | — | — | — | — | — | — | — | — | — |
| | (Manufactured by Tokyo Chemical Industry Co., Ltd.), I/O ratio = 0.77 | | | | | | | | | | |
| | 4-ethylbenzaldehyde | — | — | — | — | — | — | — | — | — | — |
| | (Manufactured by Tokyo Chemical Industry Co., Ltd.), I/O ratio = 0.44 | | | | | | | | | | |
| | 2-aminobenzothiazole | — | — | — | — | — | — | — | — | — | — |
| | (Manufactured by Tokyo Chemical Industry Co., Ltd.), I/O ratio = 1.03 | | | | | | | | | | |
| Surfactant | MEGAFACE F55 lA (manufactured by DIC Corporation) | 0.16 | 0.16 | 0.16 | 0.16 | 0.16 | 0.16 | 0.16 | 0.16 | 0.16 | 0.16 |
| | (30% by mass PGMEA solution) | | | | | | | | | | |
| | DOWQIL 8032 additive (manufactured by Dow Coming Toray Co., Ltd.) | — | — | — | — | — | — | — | — | — | — |
| | (30% by mass PGMEA solution) | | | | | | | | | | |
| Solvent | Propylene glycol monomethyl ether acetate | 35.68 | 33.93 | 35.68 | 35.68 | 35.68 | 35.68 | 35.33 | 35.33 | 34.80 | 34.80 |
| | (PGMEA) | | | | | | | | | | |
| | Methyl ethyl ketone | 25.50 | 25.50 | 25.50 | 25.50 | 25.50 | 25.50 | 25.50 | 25.50 | 25.50 | 25.50 |
| | (MEK) | | | | | | | | | | |

TABLE 5

| Composition for forming photosensitive layer | | A-41 | A-42 | A-43 | A-44 | A-45 | A-46 | A-47 | A-48 | A-49 | A′-1 | A′-2 |
|---|---|---|---|---|---|---|---|---|---|---|---|---|
| Radical | 1,9-nonanediol diacrylate | 2.63 | 2.63 | 1.63 | 3.49 | 2.66 | 2.58 | 2.63 | 130 | 1.30 | 2.77 | 3.68 |
| polymerizable | (A-NOD-N, MANUFACTURED BY SHIN-NAKAMURA | | | | | | | | | | | |
| compound | CHEMICAL CO., LTD.) | | | | | | | | | | | |
| | Dipentaerythritol hexaacrylate | 3.51 | 3.51 | 2.17 | 4.66 | 3.54 | 3.43 | 3.51 | 0.87 | 0.87 | 3.69 | 4.90 |
| | (KAYARAD DPHA, manufactured by Nippon Kayaku Co., Ltd.) of 75% | | | | | | | | | | | |
| | by mass PGMEA solution | | | | | | | | | | | |
| | Trimethylolpropane triacrylate | — | — | — | — | — | — | — | 1.30 | 1.30 | — | — |
| | (A-TMPT, manufactured by Shin-Nakamura Chemical Co., Ltd.) | | | | | | | | | | | |
| | Ditrimethylolpropane tetraacrylate | — | — | — | — | — | — | — | — | — | — | — |
| | (AD-TMP manufactured by Shin-Nakamura Chemical Co Ltd.) | | | | | | | | | | | |
| | Tricyclodecane dimethanol diacrylate | — | — | — | — | — | — | — | — | — | — | — |
| | (A-DCP, manufactured by Shin-Nakamura Chemical Co., Ltd.) | | | | | | | | | | | |
| | Adamantyl diacrylate | — | — | — | — | — | — | — | — | — | — | — |
| | (ADDA, manufactured by Mitsubishi Gas Chemical Company Inc.) | | | | | | | | | | | |
| Binder polymer | 27% by mass PGMEA solution of P-1 | — | — | — | — | — | — | — | — | — | 34.19 | — |
| | 27% by mass PGMEA solution of P-2 | 32.48 | 32.48 | 40.16 | 25.88 | 32.82 | 31.79 | 32.48 | 40.16 | 40.16 | — | 27.24 |
| | 27% by mass PGMEA solution of P-3 | — | — | — | — | — | — | — | — | — | — | — |
| Photopolymerization | [8-[5-(2,4,6-trimethylpheny1)-11-(2-ethylhexyl)-11H-benzo[a]carbazoyl][2- | 0.17 | 0.17 | 0.11 | 0.23 | 0.17 | 0.17 | 0.17 | 0.11 | — | 0.18 | — |
| initiator | (2,2,3,3-tetrafluoropropoxy)phenyl]methanone-(O-acetyloxime) | | | | | | | | | | | |
| | (IRGACURE OXE-03, manufactured by BASF SE) | | | | | | | | | | | |
| | 1-[9-ethyl-6-(2-methylbenzoy1)-9H-carbazol-3-yl]ethanone-1-(O-acetyloxime) | — | — | — | — | — | — | — | — | — | — | 0.18 |
| | (IRGACURE OXE-02, manufactured by BASF SE) | | | | | | | | | | | |
| | 2-(dimethylamino)-2-[(4-methylphenyl)methyl]-1-[4-(4-morpholinyl)pheny1]- | — | — | — | — | — | — | — | — | — | — | 0.06 |
| | 1-butanone (IRGACURE 379EG, manufactured by BASF SE) | | | | | | | | | | | |
| | 1,2-octanedione-1[4-(phenylthio)pheny1]-2-(O-benzoyloxime) | — | — | — | — | — | — | — | — | — | — | — |
| | (IRGACURE OXE-01, manufactured by BASF SE) | | | | | | | | | | | |
| | 2-hydroxy-4′-(2-hydroxyethoxy)-2-methylpropiophenone | — | — | — | — | — | — | — | — | 0.11 | — | — |
| | (IRGACURE 2959, manufactured by BASF SE) | | | | | | | | | | | |
| | N-phenylglycine (Manufactured by Tokyo Chemical Industry Co., Ltd.) | — | — | 0.45 | 0.45 | 0.45 | 0.45 | 0.45 | 0.45 | 0.45 | — | — |
| Hydrogen donating | Naphthoquinone (Manufactured by Tokyo Chemical Industry Co., Ltd.) | 0.45 | — | — | — | — | — | — | — | — | — | — |
| compound | 2,4-diphenyl-4-methyl-1-pentene (Manufactured by Tokyo Chemical | — | 0.45 | — | — | — | — | — | — | — | — | — |
| | Industry Co., Ltd.) | | | | | | | | | | | |
| Compound A | 4-methylthio benzaldehyde | 0.30 | 0.30 | 0.30 | 0.30 | 0.15 | 0.60 | — | 0.30 | 0.30 | — | — |
| | (Manufactured by Tokyo Chemical Industry Co., Ltd.), I/O ratio = 0.50 | | | | | | | | | | | |
| | Thioanisole | — | — | — | — | — | — | 0.30 | — | — | — | — |
| | (Manufactured by Tokyo Chemical Industry Co., Ltd.), I/O ratio = 0.19 | | | | | | | | | | | |
| | 4-(4-formylphenyl)morpholine | — | — | — | — | — | — | — | — | — | — | — |
| | (Manufactured by Tokyo Chemical Industry Co., Ltd.), I/O ratio = 0.77 | | | | | | | | | | | |
| | 4-ethylbenzaldehyde | — | — | — | — | — | — | — | — | — | — | — |
| | (Manufactured by Tokyo Chemical Industry Co., Ltd.), I/O ratio = 0.44 | | | | | | | | | | | |
| | 2-aminobenzothiazole | — | — | — | — | — | — | — | — | — | — | — |
| | (Manufactured by Tokyo Chemical Industry Co., Ltd.), I/O ratio = 1.03 | | | | | | | | | | | |
| Surfactant | MEGAFACE F551A (manufactured by DIC Corporation) | 0.16 | 0.16 | 0.16 | 0.16 | 0.16 | 0.16 | 0.16 | 0.16 | 0.16 | 0.16 | 0.16 |
| | (30% by mass PGMEA solution) | | | | | | | | | | | |
| | DOWQIL 8032 additive (manufactured by Dow Coming Toray Co., Ltd.) | — | — | — | — | — | — | — | — | — | — | — |
| | (30% by mass PGMEA solution) | | | | | | | | | | | |
| Solvent | Propylene glycol monomethyl ether acetate | 34.80 | 34.80 | 29.53 | 39.33 | 34.54 | 35.32 | 34.80 | 29.85 | 29.85 | 33.50 | 38.27 |
| | (PGMEA) | | | | | | | | | | | |
| | Methyl ethyl ketone | 25.50 | 25.50 | 25.50 | 25.50 | 25.50 | 25.50 | 25.50 | 25.50 | 25.50 | 25.50 | 25.50 |
| | (MEK) | | | | | | | | | | | |

### Examples 1 to 22, and 24 to 54, and Comparative Examples 1 and 2

A LUMIRROR 16KS40 temporary support (thickness of 16 μm, manufactured by Toray Industries, Inc., a polyethylene terephthalate film) was coated with each composition for forming a photosensitive layer described in Tables 6 to 8 by using a slit-shaped nozzle, and the solvent was then volatilized in a drying zone at 120° C. to form a photosensitive layer. The coating amount of each composition for forming a photosensitive layer was adjusted to be each thickness of a photosensitive layer shown in Tables 6 to 8. Next, each of photosensitive transfer materials in Examples 1 to 22 and 24 to 54, and Comparative Examples 1 and 2 was produced in such a manner that a protective film (LUMIRROR 16KS40, thickness of 16 μm, manufactured by Toray Industries, Inc., polyethylene terephthalate film) was laminated on the above-described photosensitive layer with a laminating machine at 50° C. and a pressure of 0.5 MPa. Each of the above-described photosensitive transfer materials has a temporary support, a photosensitive layer, and a protective film in this order.

[Preparation of Coating Liquid for Forming Silver Nanowire Layer]

<Preparation of Additive Solution A>

0.51 g of silver nitrate powder was dissolved in 50 mL of pure water. 1 mol/L of aqueous ammonia was added to the obtained solution until the liquid became transparent. Thereafter, pure water was added to the obtained solution so that the total amount of the solution became 100 mL to prepare an additive solution A.

<Preparation of Additive Solution G>

0.5 g of glucose powder was dissolved in 140 mL of pure water to prepare an additive solution G.

<Preparation of Additive Solution H>

0.5 g of hexadecyl-trimethylammonium bromide (HTAB) powder was dissolved in 27.5 mL of pure water to prepare an additive solution H.

<Preparation of Coating Liquid for Forming Silver Nanowire Layer>

After putting pure water (410 mL) into a three-neck flask, the additive solution H (82.5 mL) and the additive solution G (206 mL) were added thereto with a funnel while stirring at 20° C. The additive solution A (206 mL) was added to the obtained solution at a flow rate of 2.0 mL/min and a stirring rotation speed of 800 rpm (revolutions per minutes; the same applies hereinafter). After 10 minutes, 82.5 mL of the additive solution H was added to the obtained solution. Thereafter, the obtained solution was heated to an internal temperature of 75° C. at 3° C./min. Thereafter, the stirring rotation speed was reduced to 200 rpm, and the solution was heated for 5 hours. After cooling the obtained solution, the solution was placed in a stainless steel cup, and ultrafiltration was performed using an ultrafiltration device in which an ultrafiltration module SIP1013 (manufactured by Asahi Kasei Corporation, molecular weight cut off: 6,000), a magnet pump, a stainless steel cup was connected with a silicon tube. In a case where the filtrate from the module reached 50 mL, 950 mL of distilled water was added to the stainless steel cup for washing. After repeating the above-described washing 10 times, concentration was performed until the amount of the solution reached 50 mL. The additive solution A, the additive solution G, and the additive solution H were repeatedly produced by the above-described method and used for preparing a coating liquid for forming a silver nanowire layer.

The obtained concentrated solution was diluted with pure water and methanol (volume ratio of pure water and methanol: 60/40) to obtain a coating liquid for forming a silver nanowire layer.

[Production of Transparent Conductive Film]

Next, the coating liquid for forming a silver nanowire layer was applied to a cycloolefin polymer film. The amount of the coating liquid for forming a silver nanowire layer was set so that the wet film thickness was 20 μm. The layer thickness of the silver nanowire layer after drying was 30 nm, and the sheet resistance of the layer including the silver nanowire was 60Ω/□. The sheet resistance was measured using a noncontact eddy current-type resistance measuring instrument EC-80P (manufactured by NAPSON). In addition, the diameter of the silver nanowire was 17 nm, the major axis length thereof was 35 μm.

(Production of Laminate)

Regarding each of the photosensitive transfer materials of Examples 1 to 22 and 24 to 54, and Comparative Examples 1 and 2, the protective film was peeled off, a surface of the photosensitive layer exposed was laminated on the silver nanowire layer side of the transparent conductive film produced above to obtain a laminate having a structure of temporary support/photosensitive layer/silver nanowire layer/cycloolefin polymer film. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each laminate described above was exposed with an exposure amount of 60 mJ/cm² (i ray), without peeling off the temporary support. After the exposure, the laminate left for 1 hour, the temporary support of each laminate described above was peeled off, exposure was then further performed with an exposure amount of 375 mJ/cm² (i ray) to cure the photosensitive layer, thereby producing each laminate.

### Example 23

The silver nanowire layer side of the transparent conductive film produced above was coated with the composition A-3 for a photosensitive layer by using a slit-shaped nozzle, and the solvent was then volatilized in a drying zone at 120° C. to form a photosensitive layer. The coating amount of each composition for forming a photosensitive layer was adjusted to be each thickness of a photosensitive layer shown in Table 3. Using a proximity type exposure machine (manufactured by Hitachi High-Tech Electronic Engineering Corporation) having an ultra-high pressure mercury lamp, the above described laminate was exposed from the photosensitive layer side with an exposure amount of 60 mJ/cm² (i ray). After the exposure, the laminate was further exposed at an exposure amount of 375 mJ/cm² (i ray), and the photosensitive layer was cured to produce a laminate of Example 23.

### Comparative Example 3

The transparent conductive film produced above was used as it was as a laminate of Comparative Example 3.

<Measurement of Content of Chloride Ions>

100 mg of the cured photosensitive layer was scraped off and collected. 100 mg of the collected sample was dissolved in 5 mL of propylene glycol monomethyl ether acetate. 5 mL of ultrapure water was added thereto, and the mixture was stirred for 2 hours. The mixture was left to stand for 12 hours or more, 1 mL of the aqueous layer was collected, and 9 mL of ultrapure water was added thereto to prepare a sample for measurement.

—Measurement of Content of Chloride Ions—

An ion chromatograph was used for the measurement. Measurement conditions such as a measuring device are as described below.
Ion chromatograph device: IC-2010 (manufactured by Tosoh Corporation)
Analytical column: TSKgel SuperIC-Anion HS
Guard column: TSKgel guardcolumn SuperIC-A HS
Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (using a suppressor)

<Evaluation of Moisture-Heat Resistance>

The sheet resistance of the laminate produced above was measured using a noncontact eddy current-type resistance measuring instrument EC-80P (manufactured by NAPSON). That is, a probe of the resistance measuring instrument was pressed against the photosensitive layer side of the laminate produced above to be closely attached, and resistance values were measured at 9 points within a 10 cm square, and an average value thereof was regarded as a measured value.

The produced laminate was tested for 24 hours at a temperature of 85° C. and a humidity of 85% RH using a constant temperature and humidity chamber. Sheet resistance values were measured before and after the wet heat test and evaluated by the following A to D based on a rate of change of the resistance values before and after the test. The rate of change was calculated by subtracting the resistance value before the test from the resistance value after the test and dividing the absolute value of the amount of change in the resistance value by the resistance value before the test.

A: Rate of change was 0% to 5%.

B: Rate of change was more than 5% and 10% or less.

C: Rate of change was more than 10% and 20% or less.

D: Rate of change was more than 20%.

<Evaluation of Patterning Properties of Photosensitive Layer>

Regarding each of the photosensitive transfer materials of Examples 1 to 22 and 24 to 54, the protective film was peeled off, a surface of the photosensitive layer exposed was laminated on the silver nanowire layer side of the transparent conductive film produced above to obtain a laminate having a structure of temporary support/photosensitive layer/silver nanowire layer/cycloolefin polymer film. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each laminate was exposed with an exposure amount of 60 mJ/cm² (i ray) through a mask having a pattern of L/S=100 μm/100 μm, without peeling off the temporary support. After exposure, the temporary support of each laminate described above was peeled off after being left for 1 hour and developed for 45 seconds with a 1% by mass aqueous solution of sodium carbonate (liquid temperature of 30° C.) to develop and remove the photosensitive layer in the unexposed portion. Furthermore, air was blown to remove water. It was confirmed that the pattern of L/S=100 μm/100 μm could be formed in all of Examples 1 to 22 and 24 to 54 after the development.

TABLE 6

| | Photosensitive layer | | | | | | | | |
|---|---|---|---|---|---|---|---|---|---|
| | Compo- | | | | | | | | |
| | sition | | | | | | | | |
| | for | | | | | | | | |
| | forming | Compound A | | | | | Thick- | | |
| | photo- | | | | Metal | | ness | Moisture- | |
| | sensitive | | | Metal reducing | coordinating | I/O | of | heat | Content of chloride |
| | layer | Kind | Ratio | group | group | ratio | layer | resistance | ions |
| Example 1 | A-1 | 4-methylthio benzaldehyde | 0.01% | Aldehyde group | Thioether group | 0.50 | 3 μm | C | Less than 0.5 ppm |
| Example 2 | A-2 | 4-methylthio benzaldehyde | 1.00% | Aldehyde group | Thioether group | 0.50 | 3 μm | B | Less than 0.5 ppm |
| Example 3 | A-3 | 4-methylthio benzaldehyde | 2.00% | Aldehyde group | Thioether group | 0.50 | 3 μm | A | Less than 0.5 ppm |
| Example 4 | A-4 | 4-methylthio benzaldehyde | 4.00% | Aldehyde group | Thioether group | 0.50 | 3 μm | A | Less than 0.5 ppm |
| Example 5 | A-5 | 4-methylthio benzaldehyde | 6.00% | Aldehyde group | Thioether group | 0.50 | 3 μm | B | Less than 0.5 ppm |
| Example 6 | A-6 | 4-methylthio benzaldehyde | 10.00% | Aldehyde group | Thioether group | 0.50 | 3 μm | C | Less than 0.5 ppm |
| Example 7 | A-7 | Thioanisole | 2.00% | — | Thioether group | 0.19 | 3 μm | C | Less than 0.5 ppm |
| Example 8 | A-8 | 4-(4- | 2.00% | Aldehyde group | Morpholino | 0.77 | 3 μm | C | Less than 0.5 ppm |
| | | formylphenyl)morpholine | | | group | | | | |
| Example 9 | A-9 | 4-ethylbenzaldehyde | 2.00% | Aldehyde group | — | 0.44 | 3 μm | C | Less than 0.5 ppm |
| Example 10 | A-10 | 2-aminobenzothiazole | 2.00% | Amino group | Thiazolyl group | 1.03 | 3 μm | C | Less than 0.5 ppm |
| Example 11 | A-11 | 4-methylthio benzaldehyde | 2.00% | Aldehyde group | Thioether group | 0.50 | 3 μm | A | Less than 0.5 ppm |
| Example 12 | A-12 | 4-methylthio benzaldehyde | 2.00% | Aldehyde group | Thioether group | 0.50 | 3 μm | A | Less than 0.5 ppm |
| Example 13 | A-13 | 4-methylthio benzaldehyde | 2.00% | Aldehyde group | Thioether group | 0.50 | 3 μm | A | Less than 0.5 ppm |
| Example 14 | A-14 | 4-methylthio benzaldehyde | 2.00% | Aldehyde group | Thioether group | 0.50 | 3 μm | A | Less than 0.5 ppm |
| Example 15 | A-15 | 4-methylthio benzaldehyde | 2.00% | Aldehyde group | Thioether group | 0.50 | 3 μm | A | Less than 0.5 ppm |
| Example 16 | A-16 | 4-methylthio benzaldehyde | 2.00% | Aldehyde group | Thioether group | 0.50 | 3 μm | A | Less than 0.5 ppm |
| Example 17 | A-17 | 4-methylthio benzaldehyde | 2.00% | Aldehyde group | Thioether group | 0.50 | 3 μm | A | Less than 0.5 ppm |
| Example 18 | A-18 | 4-methylthio benzaldehyde | 2.00% | Aldehyde group | Thioether group | 0.50 | 5 μm | A | Less than 0.5 ppm |
| Example 19 | A-19 | 4-methylthio benzaldehyde | 2.00% | Aldehyde group | Thioether group | 0.50 | 8 μm | A | Less than 0.5 ppm |
| Example 20 | A-20 | 4-methylthio benzaldehyde | 2.00% | Aldehyde group | Thioether group | 0.50 | 3 μm | A | Less than 0.5 ppm |
| Example 21 | A-3 | 4-methylthio benzaldehyde | 2.00% | Aldehyde group | Thioether group | 0.50 | 3 μm | A | Less than 0.5 ppm |
| Example 22 | A-3 | 4-methylthio benzaldehyde | 2.00% | Aldehyde group | Thioether group | 0.50 | 3 μm | A | Less than 0.5 ppm |
| Example 23 | A-3 | 4-methylthio benzaldehyde | 2.00% | Aldehyde group | Thioether group | 0.50 | 3 μm | A | Less than 0.5 ppm |

TABLE 7

| | Photosensitive layer | | | | | | | | |
|---|---|---|---|---|---|---|---|---|---|
| | Compo- | | | | | | | | |
| | sition | | | | | | | | |
| | for | | | | | | | | |
| | forming | Compound A | | | | | Thick- | | |
| | photo- | | | | Metal | | ness | Moisture- | |
| | sensitive | | | Metal reducing | coordinating | I/O | of | heat | Content of chloride |
| | layer | Kind | Ratio | group | group | ratio | layer | resistance | ions |
| Example 24 | A-21 | 4-methylthio benzaldehyde | 2.00% | Aldehyde group | Thioether group | 0.50 | 3 μm | A | Less than 0.5 ppm |
| Example 25 | A-22 | 4-methylthio benzaldehyde | 2.00% | Aldehyde group | Thioether group | 0.50 | 3 μm | A | Less than 0.5 ppm |
| Example 26 | A-23 | 4-methylthio benzaldehyde | 2.00% | Aldehyde group | Thioether group | 0.50 | 3 μm | A | Less than 0.5 ppm |
| Example 27 | A-24 | 4-methylthio benzaldehyde | 2.00% | Aldehyde group | Thioether group | 0.50 | 3 μm | A | Less than 0.5 ppm |
| Example 28 | A-25 | 4-methylthio benzaldehyde | 2.00% | Aldehyde group | Thioether group | 0.50 | 3 μm | A | Less than 0.5 ppm |
| Example 29 | A-26 | 4-methylthio benzaldehyde | 2.00% | Aldehyde group | Thioether group | 0.50 | 3 μm | A | Less than 0.5 ppm |
| Example 30 | A-27 | 4-methylthio benzaldehyde | 2.00% | Aldehyde group | Thioether group | 0.50 | 3 μm | A | Less than 0.5 ppm |
| Example 31 | A-28 | 4-methylthio benzaldehyde | 2.00% | Aldehyde group | Thioether group | 0.50 | 3 μm | A | Less than 0.5 ppm |
| Example 32 | A-29 | 4-methylthio benzaldehyde | 2.00% | Aldehyde group | Thioether group | 0.50 | 3 μm | A | Less than 0.5 ppm |
| Example 33 | A-30 | 4-methylthio benzaldehyde | 2.00% | Aldehyde group | Thioether group | 0.50 | 3 μm | A | Less than 0.5 ppm |
| Example 34 | A-31 | 4-methylthio benzaldehyde | 2.00% | Aldehyde group | Thioether group | 0.50 | 3 μm | A | Less than 0.5 ppm |
| Example 35 | A-32 | 4-methylthio benzaldehyde | 2.00% | Aldehyde group | Thioether group | 0.50 | 3 μm | A | Less than 0.5 ppm |
| Example 36 | A-33 | 4-methylthio benzaldehyde | 2.00% | Aldehyde group | Thioether group | 0.50 | 3 μm | A | Less than 0.5 ppm |
| Example 37 | A-34 | 4-methylthio benzaldehyde | 2.00% | Aldehyde group | Thioether group | 0.50 | 3 μm | A | Less than 0.5 ppm |
| Example 38 | A-35 | 4-methylthio benzaldehyde | 2.00% | Aldehyde group | Thioether group | 0.50 | 3 μm | A | Less than 0.5 ppm |
| Example 39 | A-36 | 4-methylthio benzaldehyde | 2.00% | Aldehyde group | Thioether group | 0.50 | 3 μm | A | Less than 0.5 ppm |
| Example 40 | A-37 | 4-methylthio benzaldehyde | 2.00% | Aldehyde group | Thioether group | 0.50 | 3 μm | A | Less than 0.5 ppm |
| Example 41 | A-38 | 4-methylthio benzaldehyde | 2.00% | Aldehyde group | Thioether group | 0.50 | 3 μm | A | Less than 0.5 ppm |
| Example 42 | A-39 | 4-methylthio benzaldehyde | 2.00% | Aldehyde group | Thioether group | 0.50 | 3 μm | A | Less than 0.5 ppm |
| Example 43 | A-40 | 4-methylthio benzaldehyde | 2.00% | Aldehyde group | Thioether group | 0.50 | 3 μm | A | Less than 0.5 ppm |
| Example 44 | A-41 | 4-methylthio benzaldehyde | 2.00% | Aldehyde group | Thioether group | 0.50 | 3 μm | A | Less than 0.5 ppm |
| Example 45 | A-42 | 4-methylthio benzaldehyde | 2.00% | Aldehyde group | Thioether group | 0.50 | 3 μm | A | Less than 0.5 ppm |
| Example 46 | A-43 | 4-methylthio benzaldehyde | 2.00% | Aldehyde group | Thioether group | 0.50 | 3 μm | A | Less than 0.5 ppm |

TABLE 8

| | Photosensitive layer | | | | | | | | |
|---|---|---|---|---|---|---|---|---|---|
| | Compo- | | | | | | | | |
| | sition | | | | | | | | |
| | for | | | | | | | | |
| | forming | Compound A | | | | | Thick- | | |
| | photo- | | | | Metal | | ness | Moisture- | |
| | sensitive | | | Metal reducing | coordinating | I/O | of | heat | Content of chloride |
| | layer | Kind | Ratio | group | group | ratio | layer | resistance | ions |
| Example 47 | A-44 | 4-methylthio benzaldehyde | 2.00% | Aldehyde group | Thioether group | 0.50 | 3 μm | A | Less than 0.5 ppm |
| Example 48 | A-45 | 4-methylthio benzaldehyde | 1.00% | Aldehyde group | Thioether group | 0.50 | 3 μm | A | Less than 0.5 ppm |
| Example 49 | A-46 | 4-methylthio benzaldehyde | 4.00% | Aldehyde group | Thioether group | 0.50 | 3 μm | A | Less than 0.5 ppm |
| Example 50 | A-47 | Thioanisole | 2.00% | — | Thioether group | 0.19 | 3 μm | B | Less than 0.5 ppm |
| Example 51 | A-48 | 4-methylthio benzaldehyde | 2.00% | Aldehyde group | Thioether group | 0.50 | 3 μm | A | Less than 0.5 ppm |
| Example 52 | A-49 | 4-methylthio benzaldehyde | 2.00% | Aldehyde group | Thioether group | 0.50 | 3 μm | A | Less than 0.5 ppm |
| Example 53 | A-24 | 4-methylthio benzaldehyde | 2.00% | Aldehyde group | Thioether group | 0.50 | 2 μm | B | Less than 0.5 ppm |
| Example 54 | A-24 | 4-methylthio benzaldehyde | 2.00% | Aldehyde group | Thioether group | 0.50 | 1 μm | C | Less than 0.5 ppm |
| Comparative | A′-1 | — | — | — | — | — | 3 μm | D | Less than 0.5 ppm |
| Example 1 | | | | | | | | | |
| Comparative | A′-2 | — | — | — | — | — | 3 μm | D | Less than 0.5 ppm |
| Example 2 | | | | | | | | | |
| Comparative | — | — | — | — | — | — | — | D | — |
| Example 3 | | | | | | | | | |

Each “ratio” (unit: %) of the compound A in Tables 6 to 8 represents the content (unit: % by mass) of the compound A with respect to a total mass of the photosensitive layer.

Since the laminate of Comparative Example 3 did not have a photosensitive layer, the content of the chloride ions was not measured.

### Examples 101 to 104

A transfer film and a laminate were produced in the same manner as in Example 3 except that the temporary support and the protective film in Example 3 were changed as shown in Table 9, and the transfer film and the laminate were evaluated in the same manner as in Example 3. All had the same evaluation results as in Example 3.

TABLE 9

| | Temporary support | Protective film |
|---|---|---|
| Example | Lumirror (registered trademark) 16FB40 | Lumirror (registered trademark) 16FB40 |
| 101 | manufactured by Toray Industries, Inc. | manufactured by Toray Industries, Inc. |
| Example | Lumirror (registered trademark) 16FB40 | ALPHAN (registered trademark) FG-201 |
| 102 | manufactured by Toray Industries, Inc. | manufactured by Oji F-Tex Co., Ltd. |
| Example | Lumirror (registered trademark) 16FB40 | ALPHAN (registered trademark) E-201F |
| 103 | manufactured by Toray Industries, Inc. | manufactured by Oji F-Tex Co., Ltd. |
| Example | Cosmo Shine (registered trademark) A4100 | ALPHAN (registered trademark) FG-201 |
| 104 | (film thickness of 50 μm) | manufactured by Oji F-Tex Co., Ltd. |
| | manufactured by TOYOBO Co., Ltd. | |

[Preparation of Composition for Forming Photosensitive Layer]

Compositions A-201 to A-253 for forming a photosensitive layer were prepared according to the description in Tables 10 to 13 below, respectively. The numerical values in individual component columns in Tables 10 to 13 represent the mass ratio.

TABLE 10

| Composition for forming photosensitive layer | | A-201 | A-202 | A-203 | A-204 | A-205 | A-206 | A-207 | A-208 | A-209 | A-210 | A-211 |
|---|---|---|---|---|---|---|---|---|---|---|---|---|
| Radical | 1,9-nonanediol diacrylate | 6.21 | 6.21 | 6.21 | 6.21 | 6.21 | 6.21 | 6.21 | 6.21 | 6.21 | 6.21 | 6.21 |
| polymerizable | (A-NOD-N, MANUFACTURED BY SHIN-NAKAMURA CHEMICAL | | | | | | | | | | | |
| compound | CO., LTD.) | | | | | | | | | | | |
| | Dipentaelythritol hexaacrylate | — | — | — | — | — | — | — | — | — | — | — |
| | (KAYARAD DPHA, manufactured by Nippon Kayaku Co., Ltd.) of 75% | | | | | | | | | | | |
| | by mass PGMEA solution | | | | | | | | | | | |
| Binder polymer | 27% by mass PGMEA solution of P-1 | — | — | — | — | — | — | — | — | — | — | — |
| | 27% by mass PGMEA solution of P-2 | 28.77 | 28.77 | 28.77 | 28.77 | 28.77 | 28.77 | 28.77 | 28.77 | 28.77 | 28.77 | 28.77 |
| Photopolymerization | 2-(dimethylamino)-2-[(4-methylphenyl)methyl]-1-[4-(4-morpholinyl)phenyl]- | 0.01 | 0.01 | 0.01 | 0.01 | 0.01 | 0.01 | 0.01 | 0.01 | 0.01 | 0.01 | 0.01 |
| initiator | 1-butanone (IRGACURE 379EG, manufactured by BASF SE) | | | | | | | | | | | |
| | 1-(biphenyl-4-y1)-2-methyl-2-molpholinopropan-1-one | 0.32 | 0.32 | 0.32 | 0.32 | 0.32 | 0.32 | 0.32 | 0.32 | 0.32 | 0.32 | 0.32 |
| | (APi-307, manufactured by Shenzhen UV-ChemTech LTD) | | | | | | | | | | | |
| | 1-hydroxy cyclohexyl phenyl ketone | — | — | — | — | — | — | — | — | — | — | — |
| | (IRGACURE 184, MANUFACTURED BASF SE) | | | | | | | | | | | |
| | 2,2-dimethoxy-1,2-diphenylethan-1-one | — | — | — | — | — | — | — | — | — | — | — |
| | (IRGACURE 651, manufactured by BASF SE) | | | | | | | | | | | |
| Compound A | 4-methylthio benzaldehyde | 0.15 | — | — | — | — | — | — | — | — | — | — |
| | (Manufactured by Tokyo Chemical Industry Co., Ltd.), I/O ratio = 0.50 | | | | | | | | | | | |
| | Dimethyl 3,3′-thiodipropionate | — | 0.15 | — | — | — | — | — | — | — | — | — |
| | (Manufactured by Tokyo Chemical Industry Co., Ltd.), I/O ratio = 0.70 | | | | | | | | | | | |
| | Diethyl 3,3′-thiodipropionate | — | — | 0.15 | — | — | — | — | — | — | — | — |
| | (Manufactured by Aldrich), I/O ratio = 0.58 | | | | | | | | | | | |
| | Dipropyl 3,3′-thiodipropionate | — | — | — | 0.15 | — | — | — | — | — | — | — |
| | (Manufactured by Shijiazhuang Sdyano Fine Chemical Co., Ltd.), | | | | | | | | | | | |
| | I/O ratio = 0.50 | | | | | | | | | | | |
| | Dibutyl 3,3′-thiodipropionate | — | — | — | — | 0.15 | — | — | — | — | — | — |
| | (Manufactured by Zhengzhou Acme Chemical Co., Ltd.), I/O ratio = 0.44 | | | | | | | | | | | |
| | Dipentyl 3,3′-thiodipropionate | — | — | — | — | — | 0.15 | — | — | — | — | — |
| | (Manufactured by Shijiazhuang Sdyano Fine Chemical Co., Ltd.), | | | | | | | | | | | |
| | I/O ratio = 0.39 | | | | | | | | | | | |
| | Dihexyl 3,3′-thiodipropionate | — | — | — | — | — | — | 0.15 | — | — | — | — |
| | (Manufactured by Hangzhou Ocean Chemical Co., Ltd.), I/O ratio = 0.35 | | | | | | | | | | | |
| | Bis (2-ethylhexyl) 3,3′-thiodipropionate | | | | | | | | | | | |
| | (Manufactured by Tokyo Chemical Industry Co., Ltd.), I/O ratio = 0.29 | — | — | — | — | — | — | — | 0.15 | — | — | — |
| | Didodecyl 3,3′-thiodipropionate | — | — | — | — | — | — | — | — | 0.15 | — | — |
| | (Manufactured by Tokyo Chemical Industry Co., Ltd.), I/O ratio = 0.22 | | | | | | | | | | | |
| | Dibutyl methylenebis thioglycolate | — | — | — | — | — | — | — | — | — | 0.15 | — |
| | (Manufactured by Tokyo Chemical Industry Co., Ltd.), I/O ratio = 0.47 | | | | | | | | | | | |
| | 4-methylthio acetophenone | — | — | — | — | — | — | — | — | — | — | 0.15 |
| | (Manufactured by Tokyo Chemical Industry Co., Ltd.), I/O ratio = 0.46 | | | | | | | | | | | |
| Surfactant | MEGAFACE F551A (manufactured by DIC Corporation) | 0.16 | 0.16 | 0.16 | 0.16 | 0.16 | 0.16 | 0.16 | 0.16 | 0.16 | 0.16 | 0.16 |
| | (30% by mass PGMEA solution) | | | | | | | | | | | |
| Solvent | Propylene glycol monomethyl ether acetate | 38.74 | 38.74 | 38.74 | 38.74 | 38.74 | 38.74 | 38.74 | 38.74 | 38.74 | 38.74 | 38.74 |
| | (PGMEA) | | | | | | | | | | | |
| | Methyl ethyl ketone | 25.65 | 25.65 | 25.65 | 25.65 | 25.65 | 25.65 | 25.65 | 25.65 | 25.65 | 25.65 | 25.65 |
| | (MEK) | | | | | | | | | | | |

TABLE 11

| Composition for forming photosensitive layer | | A-212 | A-213 | A-214 | A-215 | A-216 | A-217 | A-218 | A-219 | A-220 | A-221 |
|---|---|---|---|---|---|---|---|---|---|---|---|
| Radical | 1,9-nonanediol diacrylate | 6.07 | 6.07 | 6.25 | 6.15 | 6.15 | 1.63 | 6.07 | 6.07 | 6.25 | 6.15 |
| polymerizable | (A-NOD-N, MANUFACTURED BY SHIN-NAKAMURA CHEMICAL | | | | | | | | | | |
| compound | CO., LTD.) | | | | | | | | | | |
| | Dipentaerythritol hexaacrylate | 6.21 | 6.21 | 6.21 | 6.21 | 6.21 | 2.17 | — | — | — | — |
| | (KAYARAD DPHA, manufactured by Nippon Kayaku Co., Ltd.) of 75% | | | | | | | | | | |
| | by mass PGMEA solution | | | | | | | | | | |
| Binder polymer | 27% by mass PGMEA solution of P-1 | — | — | — | — | — | 40.27 | — | — | — | — |
| | 27% by mass PGMEA solution of P-2 | 28.77 | 28.77 | 28.77 | 28.77 | 28.77 | — | 28.12 | 28.12 | 28.91 | 28.48 |
| Photopolymerization | 2-(dimethylamino)-2-[(4-methylphenyl)methyl]-1-[4- | 0.01 | 0.01 | 0.01 | 0.01 | 0.01 | 0.003 | 0.01 | 0.01 | 0.01 | 0.01 |
| initiator | (4-morpholinyl)phenyl]-1-butanone (IRGACURE 379EG, | | | | | | | | | | |
| | manufactured by BASF SE) | | | | | | | | | | |
| | 1-(biphenyl-4-y1)-2-methyl-2-morpholinopropan-1-one | 0.32 | 0.32 | 0.32 | 0.32 | 0.32 | 0.17 | — | — | 0.32 | 0.32 |
| | (APi-307, manufactured by Shenzhen UV-ChemTech LTD) | | | | | | | | | | |
| | 1-hydroxy cyclohexyl phenyl ketone | — | — | — | — | — | — | 0.63 | — | — | — |
| | (IRGACURE 184, MANUFACTURED BASF SE) | | | | | | | | | | |
| | 2,2-dimethoxy-1,2-diphenylethan-1-one | — | — | — | — | — | — | — | 0.63 | — | — |
| | (IRGACURE 651, manufactured by BASF SE) | | | | | | | | | | |
| Compound A | Dimethyl 3,3′-thiodipropionate | — | — | — | — | — | 0.15 | 0.15 | 0.15 | 0.07 | 0.29 |
| | (Manufactured by Tokyo Chemical Industry Co., Ltd.), I/O ratio = 0.70 | | | | | | | | | | |
| | 2-butylthio ethanol | 0.15 | — | — | — | — | — | — | — | — | — |
| | (Manufactured by Tokyo Chemical Industry Co., Ltd.), I/O ratio = 0.76 | | | | | | | | | | |
| | Diethyl 2,2′-Thiodiglycolate | — | 0.15 | — | — | — | — | — | — | — | — |
| | (Manufactured by Tokyo Chemical Industry Co., Ltd.), I/O ratio = 0.70 | | | | | | | | | | |
| | 4-(methylthio)benzyl alcohol | — | — | 0.15 | — | — | — | — | — | — | — |
| | (Manufactured by Tokyo Chemical Industry Co., Ltd.), I/O ratio = 0.68 | | | | | | | | | | |
| | 2-methoxythioanisole | — | — | — | 0.15 | — | — | — | — | — | — |
| | (Manufactured by Tokyo Chemical Industry Co., Ltd.), I/O ratio = 0.28 | | | | | | | | | | |
| | 2-methyl-4-propyl-1,3-oxathiane | — | — | — | — | 0.15 | — | — | — | — | — |
| | (Manufactured by Tokyo Chemical Industry Co., Ltd.), I/O ratio = 0.25 | | | | | | | | | | |
| Surfactant | MEGAFACE F551A (manufactured by DIC Corporation) | 0.16 | 0.16 | 0.16 | 0.16 | 0.16 | 0.16 | 0.16 | 0.16 | 0.16 | 0.16 |
| | (30% by mass PGMEA solution) | | | | | | | | | | |
| Solvent | Propylene glycol monomethyl ether acetate | 38.74 | 38.74 | 38.74 | 38.74 | 38.74 | 29.80 | 39.21 | 39.21 | 38.63 | 38.95 |
| | (PGMEA) | | | | | | | | | | |
| | Methyl ethyl ketone | 25.65 | 25.65 | 25.65 | 25.65 | 25.65 | 25.65 | 25.65 | 25.65 | 25.65 | 25.65 |
| | (MEK) | | | | | | | | | | |

TABLE 12

| Composition for forming photosensitive layer | | A-222 | A-223 | A-224 | A-225 | A-226 | A-227 | A-228 | A-229 | A-230 | A-231 | A-232 | A-233 | A-234 | A-235 | A-236 |
|---|---|---|---|---|---|---|---|---|---|---|---|---|---|---|---|---|
| Radical | 1,9-nonanediol diacrylate | 6.15 | 6.25 | 6.27 | 6.28 | 6.27 | 6.27 | 6.27 | 6.27 | 6.27 | 6.27 | 6.27 | 6.29 | 6.29 | 6.29 | 6.29 |
| polymerizable | (A-NOD-N, MANUFACTURED BY | | | | | | | | | | | | | | | |
| compound | SHIN-NAKAMURA | | | | | | | | | | | | | | | |
| | CHEMICAL CO., LTD.) | | | | | | | | | | | | | | | |
| | Dipentaerythritol hexaacrylate | — | — | — | — | — | — | — | — | — | — | — | — | — | — | — |
| | (KAYARAD DPHA, manufactured | | | | | | | | | | | | | | | |
| | by Nippon Kayaku Co., Ltd.) | | | | | | | | | | | | | | | |
| | of 75% by mass PGMEA solution | | | | | | | | | | | | | | | |
| Binder polymer | 27% by mass PGMEA solution of P-1 | — | — | — | — | — | — | — | — | — | — | — | — | — | — | — |
| | 27% by mass PGMEA solution of P-2 | 28.77 | 28.91 | 29.03 | 29.05 | 29.03 | 29.03 | 29.03 | 29.03 | 29.03 | 29.03 | 29.03 | 29.10 | 29.10 | 29.10 | — |
| | 27% by mass PGMEA solution of P-4 | — | — | — | — | — | — | — | — | — | — | — | — | — | — | 29.10 |
| Photo- | 2-(dimethylamino)-2-[(4- | 0.01 | 0.01 | 0.01 | 0.01 | 0.01 | 0.01 | 0.01 | 0.01 | 0.01 | 0.01 | 0.01 | 0.01 | 0.01 | 0.01 | 0.01 |
| polymerization | methylphenyl)methyl]-1- | | | | | | | | | | | | | | | |
| initiator | [4-(4-morpholinyl)phenyl]-1-butanone | | | | | | | | | | | | | | | |
| | (IRGACURE 379EG, | | | | | | | | | | | | | | | |
| | manufactured by BASF SE) | | | | | | | | | | | | | | | |
| | 1-(biphenyl-4-yl)-2 -methyl-2- | 0.32 | 0.32 | 0.32 | 0.32 | 0.32 | 0.32 | 0.32 | 0.32 | 0.32 | 0.32 | 0.32 | 0.32 | 0.32 | 0.32 | 0.32 |
| | morpholinopropan-1-one | | | | | | | | | | | | | | | |
| | (APi-307, manufactured by Shenzhen | | | | | | | | | | | | | | | |
| | UV-ChemTech LTD) | | | | | | | | | | | | | | | |
| | 1-hydroxy cyclohexyl phenyl ketone | — | — | — | — | — | — | — | — | — | — | — | — | — | — | — |
| | (IRGACURE 184, MANUFACTURED | | | | | | | | | | | | | | | |
| | BASF SE) | | | | | | | | | | | | | | | |
| | 2,2-dimethoxy-1,2-diphenylethan-1-one | — | — | — | — | — | — | — | — | — | — | — | — | — | — | — |
| | (IRGACURE 651, manufactured by BASF SE) | | | | | | | | | | | | | | | |
| Compound A | 4-methoxybenzenethiol | 0.15 | 0.07 | 0.015 | 0.003 | — | — | — | — | — | — | 0.015 | 0.015 | — | — | — |
| | (Manufactured by Tokyo | | | | | | | | | | | | | | | |
| | Chemical Industry Co., Ltd.) | | | | | | | | | | | | | | | |
| | Dodecanethiol | — | — | — | — | 0.015 | — | — | — | — | — | — | — | — | — | — |
| | (Manufactured by Tokyo | | | | | | | | | | | | | | | |
| | Chemical Industry Co., Ltd.) | | | | | | | | | | | | | | | |
| | Tert-dodecyl mercaptan | — | — | — | — | — | 0.015 | — | — | — | — | — | — | — | — | — |
| | (Manufactured by Tokyo | | | | | | | | | | | | | | | |
| | Chemical Industry Co., Ltd.) | | | | | | | | | | | | | | | |
| | Dibutyl disulfide | — | — | — | — | — | — | 0.015 | — | — | — | — | — | — | — | — |
| | (Manufactured by Tokyo | | | | | | | | | | | | | | | |
| | Chemical Industry Co., Ltd.) | | | | | | | | | | | | | | | |
| | Dicyclohexyl disulfide | — | — | — | — | — | — | — | 0.015 | — | — | — | — | — | — | — |
| | (Manufactured by Tokyo | | | | | | | | | | | | | | | |
| | Chemical Industry Co., Ltd.) | | | | | | | | | | | | | | | |
| | 2-isopropylbenzenethiol | — | — | — | — | — | — | — | — | 0.015 | — | — | — | — | — | — |
| | (Manufactured by Tokyo | | | | | | | | | | | | | | | |
| | Chemical Industry Co., Ltd.) | | | | | | | | | | | | | | | |
| | Karenz MT-BD1 (1,4-bis | — | — | — | — | — | — | — | — | — | 0.015 | — | — | — | — | — |
| | (3-mercaptobutyryloxy)butane, | | | | | | | | | | | | | | | |
| | manufactured by SHOWA | | | | | | | | | | | | | | | |
| | DENKO K.K.) | | | | | | | | | | | | | | | |
| | 2-naphthalenethiol | — | — | — | — | — | — | — | — | — | — | — | — | 0.015 | 0.003 | 0.003 |
| | (Manufactured by Tokyo | | | | | | | | | | | | | | | |
| | Chemical Industry Co., Ltd.) | | | | | | | | | | | | | | | |
| Surfactant | MEGAFACE F551A | 0.16 | 0.16 | 0.16 | 0.16 | 0.16 | 0.16 | 0.16 | 0.16 | 0.16 | 0.16 | — | — | — | — | — |
| | (manufactured by DIC Corporation) | | | | | | | | | | | | | | | |
| | (30% by mass PGMEA solution) | | | | | | | | | | | | | | | |
| | MEGAFACE 710FL (manufactured | — | — | — | — | — | — | — | — | — | — | 0.09 | 0.02 | 0.09 | 0.08 | 0.08 |
| | by DIC Corporation) | | | | | | | | | | | | | | | |
| | (50% by mass PGMEA solution) | | | | | | | | | | | | | | | |
| Solvent | Propylene glycol monomethyl | 38.74 | 38.63 | 38.55 | 38.53 | 38.55 | 38.55 | 38.55 | 38.55 | 38.55 | 38.55 | 38.61 | 38.60 | 38.61 | 38.55 | 38.55 |
| | ether acetate | | | | | | | | | | | | | | | |
| | (PGMEA) | | | | | | | | | | | | | | | |
| | Methyl ethyl ketone | 25.65 | 25.65 | 25.65 | 25.65 | 25.65 | 25.65 | 25.65 | 25.65 | 25.65 | 25.65 | 25.65 | 25.65 | 25.65 | 25.65 | 25.65 |
| | (MEK) | | | | | | | | | | | | | | | |

TABLE 13

| Composition for forming photosensitive layer | | A-237 | A-238 | A-239 | A-240 | A-241 | A-242 | A-243 | A-244 | A-245 | A-246 | A-247 | A-248 | A-249 | A-250 | A-251 | A-252 | A-253 |
|---|---|---|---|---|---|---|---|---|---|---|---|---|---|---|---|---|---|---|
| Radical | 1,9-nonanediol diacrylate | 6.27 | 6.25 | 6.27 | 6.28 | 6.22 | 6.28 | 6.28 | 6.22 | 6.22 | 6.22 | 6.28 | 6.28 | 6.28 | 7.05 | 4.07 | 9.54 | 3.14 |
| polymerizable | (A-NOD-N, | | | | | | | | | | | | | | | | | |
| compound | MANUFACTURED BY | | | | | | | | | | | | | | | | | |
| | SHIN-NAKAMURA | | | | | | | | | | | | | | | | | |
| | CHEMICAL CO., LTD.) | | | | | | | | | | | | | | | | | |
| Binder | 27% by mass PGMEA | 29.05 | — | — | — | — | — | — | — | — | — | — | — | — | — | — | — | — |
| polymer | solution of P-3 | | | | | | | | | | | | | | | | | |
| | 27% by mass PGMEA | — | 29.10 | — | — | 28.81 | 29.08 | 29.08 | 28.81 | 28.81 | 28.81 | 29.08 | — | — | 26.11 | 37.72 | 44.15 | 14.55 |
| | solution of P-5 | | | | | | | | | | | | | | | | | |
| | 27% by mass PGMEA | — | — | 29.10 | — | — | — | — | — | — | — | — | 29.08 | — | — | — | — | — |
| | solution of P-6 | | | | | | | | | | | | | | | | | |
| | 27% by mass PGMEA | — | — | — | 29.10 | — | — | — | — | — | — | — | — | 29.08 | — | — | — | — |
| | solution of P-7 | | | | | | | | | | | | | | | | | |
| Photo- | 1-(biphenyl-4-y1)-2- | 0.33 | 0.33 | 0.33 | 0.33 | 0.33 | 0.33 | 0.33 | 0.33 | 0.33 | 0.33 | 0.33 | 0.33 | 0.33 | 0.37 | 0.21 | 0.50 | 0.17 |
| polymerization | methyl-2- | | | | | | | | | | | | | | | | | |
| initiator | morpholinopropan-1- | | | | | | | | | | | | | | | | | |
| | one (APi-307, | | | | | | | | | | | | | | | | | |
| | manufactured by | | | | | | | | | | | | | | | | | |
| | Shenzhen | | | | | | | | | | | | | | | | | |
| | UV-ChemTech LTD) | | | | | | | | | | | | | | | | | |
| Compound A | 2-naphthalenethiol | 0.003 | 0.003 | 0.003 | 0.003 | 0.15 | — | — | — | — | — | — | — | — | 0.004 | 0.004 | 0.007 | 0.002 |
| | (Manufactured by | | | | | | | | | | | | | | | | | |
| | Tokyo Chemical | | | | | | | | | | | | | | | | | |
| | Industry Co Ltd.) | | | | | | | | | | | | | | | | | |
| | 4-methoxybenzenethiol | — | — | — | — | — | 0.015 | — | — | — | — | — | — | — | — | — | — | — |
| | (Manufactured by | | | | | | | | | | | | | | | | | |
| | Tokyo Chemical | | | | | | | | | | | | | | | | | |
| | Industry Co., Ltd.) | | | | | | | | | | | | | | | | | |
| | Biphenyl-4-thiol | — | — | — | — | — | — | 0.015 | — | — | — | — | — | — | — | — | — | — |
| | (Manufactured by Aldrich) | | | | | | | | | | | | | | | | | |
| | 4-methylthio benzaldehyde | — | — | — | — | — | — | — | 0.15 | — | — | — | — | — | — | — | — | — |
| | (Manufactured by | | | | | | | | | | | | | | | | | |
| | Tokyo Chemical | | | | | | | | | | | | | | | | | |
| | Industry Co., Ltd.) | | | | | | | | | | | | | | | | | |
| | 4-methylthio acetophenone | — | — | — | — | — | — | — | — | 0.15 | — | — | — | — | — | — | — | — |
| | (Manufactured by | | | | | | | | | | | | | | | | | |
| | Tokyo Chemical | | | | | | | | | | | | | | | | | |
| | Industry Co., Ltd.) | | | | | | | | | | | | | | | | | |
| | 4-acetyl diphenyl sulfide | — | — | — | — | — | — | — | — | — | 0.15 | — | — | — | — | — | — | — |
| | (Manufactured by | | | | | | | | | | | | | | | | | |
| | Tokyo Chemical | | | | | | | | | | | | | | | | | |
| | Industry Co., Ltd.) | | | | | | | | | | | | | | | | | |
| | 9-mercapto fluorene | — | — | — | — | — | — | — | — | — | — | 0.015 | 0.015 | 0.015 | — | — | — | — |
| | (Manufactured by Aldrich) | | | | | | | | | | | | | | | | | |
| Surfactant | MEGAFACE 710FL | 0.05 | 0.05 | 0.05 | 0.05 | 0.05 | 0.05 | 0.05 | 0.05 | 0.05 | 0.05 | 0.05 | 0.05 | 0.05 | 0.05 | 0.05 | 0.07 | 0.02 |
| | (manufactured | | | | | | | | | | | | | | | | | |
| | by DIC Corporation) | | | | | | | | | | | | | | | | | |
| | (50% by mass | | | | | | | | | | | | | | | | | |
| | PGMEA solution) | | | | | | | | | | | | | | | | | |
| Solvent | Propylene glycol | 38.62 | 38.62 | 38.62 | 38.62 | 38.79 | 38.60 | 38.60 | 38.79 | 38.79 | 38.79 | 38.60 | 38.60 | 38.60 | 40.76 | 32.29 | 22.34 | 54.29 |
| | monomethyl ether | | | | | | | | | | | | | | | | | |
| | acetate (PGMEA) | | | | | | | | | | | | | | | | | |
| | Methyl ethyl ketone | 25.65 | 25.65 | 25.65 | 25.65 | 25.65 | 25.65 | 25.65 | 25.65 | 25.65 | 25.65 | 25.65 | 25.65 | 25.65 | 25.65 | 25.65 | 23.40 | 27.83 |
| | (MEK) | | | | | | | | | | | | | | | | | |

### Examples 201 to 253

A LUMIRROR 16KS40 temporary support (thickness of 16 μm, manufactured by Toray Industries, Inc., a polyethylene terephthalate film) was coated with each composition for forming a photosensitive layer described in Tables 14 to 16 by using a slit-shaped nozzle, and the solvent was then volatilized in a drying zone at 120° C. to form a photosensitive layer. The coating amount of each composition for forming a photosensitive layer was adjusted to be each thickness of a photosensitive layer shown in Tables 14 and 16. Next, a protective film (LUMIRROR 16KS40, thickness of 16 μm, manufactured by Toray Industries, Inc., polyethylene terephthalate film) was laminated on the above-described photosensitive layer with a laminating machine at 50° C. and a pressure of 0.5 MPa to produce photosensitive transfer materials of Examples 201 to 253. Each of the above-described photosensitive transfer materials has a temporary support, a photosensitive layer, and a protective film in this order.

Moisture-heat resistance was evaluated in the same manner as described above. Results thereof are as shown in Tables 14 to 16.

In the same manner as described above, the patterning properties of the photosensitive layer was evaluated. It was confirmed that the pattern of L/S=100 μm/100 μm could be formed in the photosensitive transfer materials of Examples 201 to 253.

<Evaluation of Xe Durability>

[Production of Transparent Conductive Film with Coating Layer]

Ferrocene (manufactured by Tokyo Chemical Industry Co., Ltd.) was added to HC5619 (transparent UV curable composition, manufactured by Addison Clear Wave Coatings Inc., solid content of 40% by mass) so that a ratio of ferrocene in the solid content is 0.1% by mass, and was then diluted with a solvent of isopropanol/diacetone alcohol=50/50 so that the solid content was 2% by mass, to produce a coating liquid A. The silver nanowire layer side of the transparent conductive film produced above was coated with the coating liquid A produced above by using a spin coater, and the solvent is volatilized in a drying zone at 120° C. to form a coating layer, thereby obtaining a laminate having a structure of coating layer/silver nanowire layer/cycloolefin polymer film. The coating amount was adjusted so that a thickness of the coating layer was 30 nm.

Regarding each of the photosensitive transfer materials of Examples 201 to 253, the protective film was peeled off, a surface of the photosensitive layer exposed was laminated on the coating layer side of the transparent conductive film with a coating layer produced above to obtain a laminate having a structure of temporary support/photosensitive layer/coating layer/silver nanowire layer/cycloolefin polymer film. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each laminate described above was exposed with an exposure amount of 60 mJ/cm² (i ray), without peeling off the temporary support. After the exposure, the laminate left for 1 hour, the temporary support of each laminate described above was peeled off, exposure was then further performed with an exposure amount of 375 mJ/cm² (i ray) to cure the photosensitive layer. The cured photosensitive layer side and gorilla glass (manufactured by Corning Precision Materials Co., Ltd.) with a thickness of 700 μm were bonded through an acrylic pressure sensitive adhesive (8146-2, manufactured by 3M), and each laminate having a structure of gorilla glass/pressure sensitive adhesive/photosensitive layer/coating layer/silver nanowire layer/cycloolefin polymer film was obtained. The sheet resistance of the laminate produced above was measured using a noncontact eddy current-type resistance measuring instrument EC-80P (manufactured by NAPSON). That is, a probe of the resistance measuring instrument was pressed against the cycloolefin polymer film side of the laminate produced above to be closely attached, and resistance values were measured at 9 points within a 10 cm square, and an average value thereof was regarded as a measured value.

The produced laminate was placed on a black acrylic plate, and the gorilla glass side was irradiated with light for 24 hours at an illuminance of 0.8 W/m² under an environment of a temperature of 35° C. and a humidity of 55% RH, by using xenon weather meter (XL75, light source: xenon long life arc lamp 7.5 kW) manufactured by Suga Test Instruments Co., Ltd.). Sheet resistance values were measured before and after performing the irradiation with the xenon lamp and evaluated by the following A to C based on a rate of change of the resistance values before and after the test. The rate of change was calculated by subtracting the resistance value before the test from the resistance value after the test and dividing the absolute value of the amount of change in the resistance value by the resistance value before the test.

A: Rate of change was 0% to 5%.

B: Rate of change was more than 5% and 10% or less.

C: Rate of change was more than 10% and 20% or less.

<Integration of Absorbance at Wavelength Range of 250 nm to 400 nm>

Regarding the photosensitive transfer material of Example 201, the protective film was peeled off, and thereafter, a surface of the exposed photosensitive layer was laminated on gorilla glass (manufactured by Corning Inc.) with a thickness of 700 μm, and the temporary support was peeled off to obtain each laminate having a structure of photosensitive layer/gorilla glass. In the laminating conditions, a roll temperature was set as 110° C., a linear pressure was set as 0.6 MPa, and a linear velocity (laminating speed) was set as 2.0 m/min. For each laminate described above, an absorption spectrum of 250 nm to 400 nm was measured with a spectrophotometer UV1800 (manufactured by Shimadzu Corporation, absorbance mode, measurement pitch: 1 nm).

A photosensitive transfer material was similarly formed by using a composition for forming a photosensitive layer prepared in the same manner as in A-201 to measure the absorption spectrum in the same manner (absorption spectrum of blank), except that the compound A is not added to the composition A-201 for forming a photosensitive layer of Example 201 as a blank.

The sum of the absorbances of a difference spectrum at individual wavelengths in the wavelength range of 250 nm to 400 nm obtained by subtracting a blank absorption spectrum from the absorption spectrum of Example 201 was calculated. This value was used as an integrated absorbance value of Example 201 in the wavelength range of 250 nm to 400 nm.

In Examples 202 to 253, integrated absorbance values at the wavelength range of 250 nm to 400 nm were also measured in the same manner as above.

TABLE 14

| | Photosensitive layer | | | | |
|---|---|---|---|---|---|
| | Composition for | Compound A | | | |
| | forming | | | Metal | |
| | photo-sensitive | | | coordinating | I/O |
| | layer | Kind | Ratio | group | ratio |
| Example 201 | A-201 | 4-methylthio benzaldehyde | 1.00% | Thioether group | 0.50 |
| Example 202 | A-202 | Dimethyl 3,3′-thiodipropionate | 1.00% | Thioether group | 0.70 |
| Example 203 | A-203 | Diethyl 3,3′-thiodipropionate | 1.00% | Thioether group | 0.58 |
| Example 204 | A-204 | Dipropyl 3,3′-thiodipropionate | 1.00% | Thioether group | 0.50 |
| Example 205 | A-205 | Dibutyl 3,3′-thiodipropionate | 1.00% | Thioether group | 0.44 |
| Example 206 | A-206 | Dipentyl 3,3′-thiodipropionate | 1.00% | Thioether group | 0.39 |
| Example 207 | A-207 | Dihexyl 3,3′-thiodipropionate | 1.00% | Thioether group | 0.35 |
| Example 208 | A-208 | Bis(2-ethylhexyl) | 1.00% | Thioether group | 0.29 |
| | | 3,3′-thiodipropionate | | | |
| Example 209 | A-209 | Didodecyl 3,3′-thiodipropionate | 1.00% | Thioether group | 0.22 |
| Example 210 | A-210 | Dibutyl methylenebis | 1.00% | Thioether group | 0.47 |
| | | thioglycolate | | | |
| Example 211 | A-211 | 4-methylthio acetophenone | 1.00% | Thioether group | 0.46 |
| Example 212 | A-212 | 2-butylthio ethanol | 1.00% | Thioether group | 0.76 |
| Example 213 | A-213 | Diethyl 2,2′-Thiodiglycolate | 1.00% | Thioether group | 0.70 |
| Example 214 | A-214 | 4-(methylthio)benzyl alcohol | 1.00% | Thioether group | 0.68 |
| Example 215 | A-215 | 2-methoxythioanisole | 1.00% | Thioether group | 0.28 |
| Example 216 | A-216 | 2-methyl-4-propyl-1,3-oxathiane | 1.00% | Thioether group | 0.25 |
| Example 217 | A-217 | Dimethyl 3,3′-thiodipropionate | 1.00% | Thioether group | 0.70 |
| Example 218 | A-218 | Dimethyl 3,3′-thiodipropionate | 1.00% | Thioether group | 0.70 |
| Example 219 | A-219 | Dimethyl 3,3′-thiodipropionate | 1.00% | Thioether group | 0.70 |
| Example 220 | A-220 | Dimethyl 3,3′-thiodipropionate | 0.50% | Thioether group | 0.70 |
| Example 221 | A-221 | Dimethyl 3,3′-thiodipropionate | 2.00% | Thioether group | 0.70 |

| | Photosensitive layer | | | | |
|---|---|---|---|---|---|
| | Compound A | | | | |
| | Integrated absorbance | | | | |
| | value at wavelength | Thickness | Moisture-heat | Xe | Content of |
| | range of 250 to 400 nm | of layer | resistance | durability | chloride ions |
| Example 201 | 5.4 | 5 μm | A | B | Less than 0.5 ppm |
| Example 202 | 0.3 | 5 μm | A | A | Less than 0.5 ppm |
| Example 203 | 0.3 | 5 μm | A | A | Less than 0.5 ppm |
| Example 204 | 0.3 | 5 μm | A | A | Less than 0.5 ppm |
| Example 205 | 0.3 | 5 μm | A | A | Less than 0.5 ppm |
| Example 206 | 0.4 | 5 μm | A | A | Less than 0.5 ppm |
| Example 207 | 0.4 | 5 μm | A | A | Less than 0.5 ppm |
| Example 208 | 0.3 | 5 μm | B | A | Less than 0.5 ppm |
| Example 209 | 0.5 | 5 μm | C | A | Less than 0.5 ppm |
| Example 210 | 0.5 | 5 μm | A | A | Less than 0.5 ppm |
| Example 211 | 21.1 | 5 μm | A | C | Less than 0.5 ppm |
| Example 212 | 0.2 | 5 μm | A | A | Less than 0.5 ppm |
| Example 213 | 0.5 | 5 μm | A | A | Less than 0.5 ppm |
| Example 214 | 3.2 | 5 μm | A | A | Less than 0.5 ppm |
| Example 215 | 2.3 | 5 μm | B | A | Less than 0.5 ppm |
| Example 216 | 0.2 | 5 μm | B | A | Less than 0.5 ppm |
| Example 217 | 0.3 | 5 μm | A | A | Less than 0.5 ppm |
| Example 218 | 0.3 | 5 μm | A | A | Less than 0.5 ppm |
| Example 219 | 0.3 | 5 μm | A | A | Less than 0.5 ppm |
| Example 220 | 0.2 | 8 μm | A | A | Less than 0.5 ppm |
| Example 221 | 0.4 | 3 μm | A | A | Less than 0.5 ppm |

TABLE 15

| | Photosensitive layer | | | | |
|---|---|---|---|---|---|
| | Composition for | | | | |
| | forming | Compound A | | | |
| | photosensitive | | | Metal coordinating | |
| | layer | Kind | Ratio | group | I/O ratio |
| Example 222 | A-222 | 4-methoxybenzenethiol | 1.00% | Mercapto group | 0.31 |
| Example 223 | A-223 | 4-methoxybenzenethiol | 0.50% | Mercapto group | 0.31 |
| Example 224 | A-224 | 4-methoxybenzenethiol | 0.10% | Mercapto group | 0.31 |
| Example 225 | A-225 | 4-methoxybenzenethiol | 0.02% | Mercapto group | 0.31 |
| Example 226 | A-226 | Dodecanethiol | 0.10% | Mercapto group | 0.07 |
| Example 227 | A-227 | Teit-dodecyl mercaptan | 0.10% | Mercapto group | 0.07 |
| Example 228 | A-228 | Dibutyl disulfide | 0.10% | Disulfide group | 0.17 |
| Example 229 | A-229 | Dicyclohexyl disulfide | 0.10% | Disulfide group | 0.19 |
| Example 230 | A-230 | 2-isopropylbenzenethiol | 0.10% | Mercapto group | 0.17 |
| Example 231 | A-231 | Karenz MT-BD I | 0.10% | Mercapto group | 0.50 |
| Example 232 | A-232 | 4-methoxybenzenethiol | 0.10% | Mercapto group | 0.31 |
| Example 233 | A-233 | 4-methoxybenzenethiol | 0.10% | Mercapto group | 0.31 |
| Example 234 | A-234 | 2-naphthalenethiol | 0.10% | Mercapto group | 0.33 |
| Example 235 | A-235 | 2-naphthalenethiol | 0.02% | Mercapto group | 0.33 |
| Example 236 | A-236 | 2-naphthalenethiol | 0.02% | Mercapto group | 0.33 |
| | Photosensitive layer | | | | |
| | Compound A | | | | |
| | Integrated absorbance | | | | |
| | value at wavelength range | Thickness | Moisture-heat | Xe | Content of |
| | of 250 to 400 nm | of layer | resistance | durability | chloride ions |
| Example 222 | 10.2 | 5 μm | C | C | Less than 0.5 ppm |
| Example 223 | 4.7 | 5 μm | B | B | Less than 0.5 ppm |
| Example 224 | 1.3 | 5 μm | A | A | Less than 0.5 ppm |
| Example 225 | 0.4 | 5 μm | B | A | Less than 0.5 ppm |
| Example 226 | 0.3 | 5 μm | A | A | Less than 0.5 ppm |
| Example 227 | 0.3 | 5 μm | A | A | Less than 0.5 ppm |
| Example 228 | 0.3 | 5 μm | A | A | Less than 0.5 ppm |
| Example 229 | 0.3 | 5 μm | A | A | Less than 0.5 ppm |
| Example 230 | 1.7 | 5 μm | A | A | Less than 0.5 ppm |
| Example 231 | 0.3 | 5 μm | A | A | Less than 0.5 ppm |
| Example 232 | 1.3 | 5 μm | A | A | Less than 0.5 ppm |
| Example 233 | 1.3 | 5 μm | A | A | Less than 0.5 ppm |
| Example 234 | 2.5 | 5 μm | A | A | Less than 0.5 ppm |
| Example 235 | 0.3 | 5 μm | A | A | Less than 0.5 ppm |
| Example 236 | 0.3 | 5 μm | A | A | Less than 0.5 ppm |

TABLE 16

| | Photosensitive layer | | | | |
|---|---|---|---|---|---|
| | Composition for | | | | |
| | forming | Compound A | | | |
| | photosensitive | | | Metal coordinating | |
| | layer | Kind | Ratio | group | I/O ratio |
| Example 237 | A-237 | 2-naphthalenethiol | 0.02% | Mercapto group | 0.33 |
| Example 238 | A-238 | 2-naphthalenethiol | 0.02% | Mercapto group | 0.33 |
| Example 239 | A-239 | 2-naphthalenethiol | 0.02% | Mercapto group | 0.33 |
| Example 240 | A-240 | 2-naphthalenethiol | 0.02% | Mercapto group | 0.33 |
| Example 241 | A-241 | 2-naphthalenethiol | 1.00% | Mercapto group | 0.33 |
| Example 242 | A-242 | 4-methoxybenzenethiol | 0.10% | Mercapto group | 0.31 |
| Example 243 | A-243 | Biphenyl-4-thiol | 0.10% | Mercapto group | 0.18 |
| Example 244 | A-244 | 4-methylthio benzaldehyde | 1.00% | Thioether group | 0.50 |
| Example 245 | A-245 | 4-methylthio acetophenone | 1.00% | Thioether group | 0.45 |
| Example 246 | A-246 | 4-acetyl diphenyl sulfide | 1.00% | Thioether group | 0.36 |
| Example 247 | A-247 | 9-mercapto fluorene | 0.02% | Mercapto group | 0.20 |
| Example 248 | A-248 | 9-mercapto fluorene | 0.02% | Mercapto group | 0.20 |
| Example 249 | A-249 | 9-mercapto fluorene | 0.02% | Mercapto group | 0.20 |
| Example 250 | A-250 | 2-naphthalenethiol | 0.02% | Mercapto group | 0.33 |
| Example 251 | A-251 | 2-naphthalenethiol | 0.02% | Mercapto group | 0.33 |
| Example 252 | A-252 | 2-naphthalenethiol | 0.02% | Mercapto group | 0.33 |
| Example 253 | A-253 | 2-naphthalenethiol | 0.02% | Mercapto group | 0.33 |
| | Photosensitive layer | | | | |
| | Compound A | | | | |
| | Integrated absorbance | | | | |
| | value at wavelength range | Thickness | Moisture-heat | Xe | Content of |
| | of 250 to 400 nm | of layer | resistance | durability | chloride ions |
| Example 237 | 0.3 | 5 μm | A | A | Less than 0.5 ppm |
| Example 238 | 0.3 | 5 μm | A | A | Less than 0.5 ppm |
| Example 239 | 0.3 | 5 μm | A | A | Less than 0.5 ppm |
| Example 240 | 0.3 | 5 μm | A | A | Less than 0.5 ppm |
| Example 241 | 22.4 | 5 μm | A | C | Less than 0.5 ppm |
| Example 242 | 1.3 | 5 μm | A | A | Less than 0.5 ppm |
| Example 243 | 3.5 | 5 μm | A | A | Less than 0.5 ppm |
| Example 244 | 5.4 | 5 μm | A | B | Less than 0.5 ppm |
| Example 245 | 21.1 | 5 μm | A | C | Less than 0.5 ppm |
| Example 246 | 19.3 | 5 μm | A | C | Less than 0.5 ppm |
| Example 247 | 0.8 | 5 μm | A | A | Less than 0.5 ppm |
| Example 248 | 0.8 | 5 μm | A | A | Less than 0.5 ppm |
| Example 249 | 0.8 | 5 μm | A | A | Less than 0.5 ppm |
| Example 250 | 0.3 | 5 μm | A | A | Less than 0.5 ppm |
| Example 251 | 0.3 | 5 μm | A | A | Less than 0.5 ppm |
| Example 252 | 0.3 | 5 μm | A | A | Less than 0.5 ppm |
| Example 253 | 0.3 | 5 μm | A | A | Less than 0.5 ppm |

### Examples 301a to 301D

A transfer material and a laminate were produced in the same manner as in Example 201 except that the temporary support and the protective film in Example 201 were changed as shown in Table 17, and the transfer material and the laminate were evaluated in the same manner as in Example 201. All had the same evaluation results as in Example 201.

TABLE 17

| | Temporary support | Protective film |
|---|---|---|
| Example | Lumirror (registered trademark) 16FB40 | Lumirror (registered trademark) 16FB40 |
| 301A | manufactured by Toray Industries, Inc. | manufactured by Toray Industries, Inc. |
| Example | Lumirror (registered trademark) 16FB40 | ALPHAN (registered trademark) FG-201 |
| 301B | manufactured by Toray Industries, Inc. | manufactured by Oji F-Tex Co., Ltd. |
| Example | Lumirror (registered trademark) 16FB40 | ALPHAN (registered trademark) E-201F |
| 301C | manufactured by Toray Industries, Inc. | manufactured by Oji F-Tex Co., Ltd. |
| Example | Cosmo Shine (registered trademark) A4100 | ALPHAN (registered trademark) FG-201 |
| 301D | (film thickness of 50 μm) | manufactured by Oji F-Tex Co., Ltd. |
| | manufactured by TOYOBO Co., Ltd. | |

### Examples 302a to 353D

Changes in the same temporary support and protective film as in Examples 301A to 301D with respect to Example 201 were also performed for Examples 202 to 253 to produce transfer materials and laminates, which were evaluated in the same manner as in Example 201.

In each case, the evaluation results were the same as those in Examples before changing the temporary support and the protective film.

### Examples 401A to 401G

Transfer materials and laminates were produced in the same manner as in Example 233, except that the LUMIRROR 16KS40 temporary support side to which the composition for forming a photosensitive layer was applied was exposed to a metal halide lamp (manufactured by Dr. Hönle AG) with the exposure amount (i ray) shown in Table 18, and the composition for forming a photosensitive layer was then applied, and were evaluated in the same manner as Example 233. All had the same evaluation results as in Example 233.

The following peelability evaluations were performed on the photosensitive transfer materials of Examples 401A to 401G. The results are shown in Table 16.

<Peelability of Protective Film>

For each of the photosensitive transfer materials of Examples 401A to 401G, the protective film was peeled off from the photosensitive layer so that an angle between the temporary support and the protective film was 90° and was evaluated by the following A or B.

A: Area where the photosensitive layer remains on the protective film side is 10% or less.

B: Area where the photosensitive layer remains on the protective film side is more than 10%.

<Temporary Support Peelability after UV Exposure>

Regarding each of the photosensitive transfer materials of Examples 401A to 401G, the protective film was peeled off, a surface of the photosensitive layer exposed was laminated on the coating layer side of the transparent conductive film produced above to obtain a laminate having a structure of temporary support/photosensitive layer/silver nanowire layer/cycloolefin polymer film. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each laminate described above was exposed with an exposure amount of 60 mJ/cm² (i ray), without peeling off the temporary support. After the exposure, the laminate was left for 1 hour, the temporary support of the laminate described above was peeled off so that an angle between the transparent conductive film and the temporary support was 90° and was evaluated by the following A to C.

A: No photosensitive layer remains on the temporary support.

B: Area where the temporary support remains on the photosensitive layer is more than 0% and 10% or less.

C: Area where the photosensitive layer remains on the temporary support is more than 10%.

TABLE 18

| | | UV irradiation | | Peelability of temporary |
|---|---|---|---|---|
| | | amount to | Peelability of | support after UV |
| | Temporary support | temporary support | protective film | exposure |
| Example | Lumirror (registered trademark) 16KS40 | 25 mJ/cm² | B | A |
| 401A | manufactured by Toray Industries, Inc. | | | |
| Example | Lumirror (registered trademark) 16KS40 | 50 mJ/cm² | A | A |
| 401B | manufactured by Toray Industries, Inc. | | | |
| Example | Lumirror (registered trademark) 16KS40 | 100 mJ/cm² | A | A |
| 401C | manufactured by Toray Industries, Inc. | | | |
| Example | Lumirror (registered trademark) 16KS40 | 150 mJ/cm² | A | A |
| 401D | manufactured by Toray Industries, Inc. | | | |
| Example | Lumirror (registered trademark) 16KS40 | 200 mJ/cm² | A | A |
| 401E | manufactured by Toray Industries, Inc. | | | |
| Example | Lumirror (registered trademark) 16KS40 | 500 mJ/cm² | A | B |
| 401F | manufactured by Toray Industries, Inc. | | | |
| Example | Lumirror (registered trademark) 16KS40 | 1,000 mJ/cm² | A | C |
| 401G | manufactured by Toray Industries, Inc. | | | |

### Examples 501 to 512

<Evaluation of Xe Durability (with UV Absorbing Layer)>

Regarding each of the photosensitive transfer materials of Examples 241 and 245 or 246, the protective film was peeled off, a surface of the photosensitive layer exposed was laminated on the coating layer side of the transparent conductive film with a coating layer produced above to obtain a laminate having a structure of temporary support/photosensitive layer/coating layer/silver nanowire layer/cycloolefin polymer film. In the laminating conditions, a roll temperature was set as 110° C., a linear pressure was set as 0.6 MPa, and a linear velocity (laminating speed) was set as 2.0 m/min. Using a proximity type exposure machine (manufactured by Hitachi High-Tech Electronic Engineering Corporation) having an ultra-high pressure mercury lamp, each laminate described above was exposed with an exposure amount of 60 mJ/cm² (i ray), without peeling off the temporary support. After the exposure, the laminate left for 1 hour, the temporary support of each laminate described above was peeled off, exposure was then further performed with an exposure amount of 375 mJ/cm² (i ray) to cure the photosensitive layer. The cured photosensitive layer side and gorilla glass (manufactured by Corning Precision Materials Co., Ltd.) with a thickness of 700 μm were bonded through an acrylic pressure sensitive adhesive (8146-2, manufactured by 3M), and each laminate having a structure of gorilla glass/pressure sensitive adhesive/photosensitive layer/coating layer/silver nanowire layer/cycloolefin polymer film was obtained. The gorilla glass side of the above-described laminate and the UV absorbing layer described in Table 19 were bonded through an acrylic pressure sensitive adhesive (8146-2, manufactured by 3M), and each of laminates in Examples 501 to 512, which has a structure of UV absorbing layer/gorilla glass/pressure sensitive adhesive/photosensitive layer/coating layer/silver nanowire layer/cycloolefin polymer film, was obtained. The sheet resistance of the laminate produced above was measured using a noncontact eddy current-type resistance measuring instrument EC-80P (manufactured by NAPSON). That is, a probe of the resistance measuring instrument was pressed against the cycloolefin polymer film side of the laminate produced above to be closely attached, and resistance values were measured at 9 points within a 10 cm square, and an average value thereof was regarded as a measured value.

The produced laminate was placed on a black acrylic plate, and the UV absorbing layer side was irradiated with light for 24 hours at an illuminance of 0.8 W/m² under an environment of a temperature of 35° C. and a humidity of 55% RH, by using xenon weather meter (XL75, light source: xenon long life arc lamp 7.5 kW) manufactured by Suga Test Instruments Co., Ltd.). Sheet resistance values were measured before and after performing the irradiation with the xenon lamp and evaluated by the following evaluation standards A to C based on a rate of change of the resistance values before and after the test. The rate of change was calculated by subtracting the resistance value before the test from the resistance value after the test and dividing the absolute value of the amount of change in the resistance value by the resistance value before the test.

A: Rate of change was 0% to 5%.

B: Rate of change was more than 5% and 10% or less.

C: Rate of change was more than 10% and 20% or less.

<Integration of Absorbance of UV Absorbing Layer at Wavelength Range of 300 nm to 400 nm>

For each UV absorbing layer, an absorption spectrum at a wavelength range of 300 nm to 400 nm was measured with a spectrophotometer UV1800 (manufactured by Shimadzu Corporation, absorbance mode, measurement pitch: 1 nm).

The sum of the absorbances at each wavelength of the obtained absorption spectrum at a wavelength range of 300 nm to 400 nm was calculated. This value was used as an integrated absorbance value of the UV absorbing layer in the wavelength range of 300 nm to 400 nm.

TABLE 19

| | Photosensitive layer | | | | |
|---|---|---|---|---|---|
| | Composition for | Compound A | | | |
| | forming | | | Metal | |
| | photosensitive | | | coordinating | |
| | layer | Kind | Ratio | group | I/O ratio |
| Example 241 | A-241 | 2-naphthalenethiol | 1.00% | Mercapto group | 0.33 |
| Example 501 | A-241 | 2-naphthalenethiol | 1.00% | Mercapto group | 0.33 |
| Example 502 | A-241 | 2-naphthalenethiol | 1.00% | Mercapto group | 0.33 |
| Example 503 | A-241 | 2-naphthalenethiol | 1.00% | Mercapto group | 0.33 |
| Example 504 | A-241 | 2-naphthalenethiol | 1.00% | Mercapto group | 0.33 |
| Example 245 | A-245 | 4-methylthio acetophenone | 1.00% | Thioether group | 0.45 |
| Example 505 | A-245 | 4-methylthio acetophenone | 1.00% | Thioether group | 0.45 |
| Example 506 | A-245 | 4-methylthio acetophenone | 1.00% | Thioether group | 0.45 |
| Example 507 | A-245 | 4-methylthio acetophenone | 1.00% | Thioether group | 0.45 |
| Example 508 | A-245 | 4-methylthio acetophenone | 1.00% | Thioether group | 0.36 |
| Example 246 | A-246 | 4-acetyl diphenyl sulfide | 1.00% | Thioether group | 0.36 |
| Example 509 | A-246 | 4-acetyl diphenyl sulfide | 1.00% | Thioether group | 0.36 |
| Example 510 | A-246 | 4-acetyl diphenyl sulfide | 1.00% | Thioether group | 0.36 |
| Example 511 | A-246 | 4-acetyl diphenyl sulfide | 1.00% | Thioether group | 0.36 |
| Example 512 | A-246 | 4-acetyl diphenyl sulfide | 1.00% | Thioether group | 0.36 |

| | Photosensitive layer | | | | |
|---|---|---|---|---|---|
| | Compound A | | UV absorb ng layer | | |
| | Integrated | | | Integrated | Xe durability |
| | absorbance value | | | absorbance value at | UV absorbing |
| | at wavelength | Thickness of | | wavelength range of | layer being |
| | range of 250 to 400 nm | layer | Contents | 300 to 400 nm | provided) |
| Example 241 | 22.4 | 5 μm | None | — | C |
| Example 501 | 22.4 | 5 μm | Soda glass | 16 | B |
| Example 502 | 22.4 | 5 μm | SC-37 | 198 | A |
| Example 503 | 22.4 | 5 μm | SC-40 | 328 | A |
| Example 504 | 22.4 | 5 μm | Polarizing plate | 422 | A |
| Example 245 | 21.1 | 5 μm | None | — | C |
| Example 505 | 21.1 | 5 μm | Soda glass | 16 | B |
| Example 506 | 21.1 | 5 μm | SC-37 | 198 | A |
| Example 507 | 21.1 | 5 μm | SC-40 | 328 | A |
| Example 508 | 19.3 | 5 μm | Polarizing plate | 422 | A |
| Example 246 | 19.3 | 5 μm | None | — | C |
| Example 509 | 19.3 | 5 μm | Soda glass | 16 | B |
| Example 510 | 19.3 | 5 μm | SC-37 | 198 | A |
| Example 511 | 19.3 | 5 μm | SC-40 | 328 | A |
| Example 512 | 19.3 | 5 μm | Polarizing plate | 422 | A |

The materials used for the UV absorbing layer shown in Table 19 are shown below.

Soda glass: Soda glass with a thickness of 0.7 mm (manufactured by Hiraoka Special Glass Mfg. co., Ltd.)

SC-37: UV absorption filter SC-37 (manufactured by FUJIFILM Corporation)

SC-40: UV absorption filter SC-40 (manufactured by FUJIFILM Corporation)

Polarizer layer: Polarizer produced by a method described below was used.

<Production of Polarizer (Polarizer Layer)>

A polymer film (“VF-PS #7500” manufactured by Kuraray Co., Ltd.) containing a polyvinyl alcohol-based resin with a thickness of 75 μm as a main component was placed in 5 baths under conditions of [1] to [5] below, was immersed while applying tension in a longitudinal direction of the film, and was stretched so that the final stretching ratio was 6.2 times the original length of the film. This stretched film was dried in an air circulation oven (internal atmospheric temperature of 40° C.) for 1 minute to produce a polarizer.

—Conditions—

[1] Swelling bath: Pure water having a liquid temperature of 30° C.

[2] Dyeing bath: An aqueous solution containing 0.032 parts by mass of iodine and 0.2 parts by mass of potassium iodide with respect to 100 parts by mass of water and having a liquid temperature of 30° C.

[3] First cross-linking bath: An aqueous solution containing 3% by mass of potassium iodide and 3% by mass of boric acid and having a liquid temperature of 40° C.

[4] Second cross-linking bath: An aqueous solution containing 5% by mass of potassium iodide and 4% by mass of boric acid and having a liquid temperature of 60° C.

[5] Water washing bath: An aqueous solution containing 3% by mass of potassium iodide and having a liquid temperature of 25° C.

The entirety of the disclosure of Japanese Patent Application No. 2019-228174 filed on Dec. 18, 2019, disclosure of Japanese Patent Application No. 2020-030705 filed on Feb. 26, 2020, disclosure of Japanese Patent Application No. 2020-112165 filed on Jun. 29, 2020, disclosure of Japanese Patent Application No. 2020-168543 filed on Oct. 5, 2020, and disclosure of Japanese Patent Application No. 2020-188157 filed on Nov. 11, 2020 is incorporated into the present specification by reference.

All of documents, patent applications, and technical standards described in the present specification are incorporated into the present specification by reference to approximately the same extent as a case where it is specifically and respectively described that the respective documents, patent applications, and technical standards are incorporated by reference.

### EXPLANATION OF REFERENCES

10: Photosensitive transfer material
12: Temporary support
16: Protective film
18, 18A: Photosensitive layer (metal conductive material protective film, resin layer)
20: Antistatic layer
32: Substrate
56: Lead wire
70: First metal conductive material
72: Second metal conductive material
74: Image display region
75: Image non-display region
90: Touch panel
112: First island-shaped electrode portion
114: Second island-shaped electrode portion
116: First wiring portion
118: Second wiring portion (bridge wiring)
120: Through-hole
124: Transparent substrate (transparent film substrate)
130: Protective layer
132: Overcoat layer
134: First electrode pattern
136: Second electrode pattern
200: Transparent laminate
P: Extension direction of first electrode pattern
Q: Extension direction of second electrode pattern

What is claimed is:

1. A film comprising:
a metal; and
a resin layer that contains a binder polymer, and a compound A containing at least one group selected from the group consisting of a metal reducing group and a metal coordinating group.

2. The film according to claim 1, wherein the compound A includes a compound containing the metal reducing group.

3. The film according to claim 2, wherein the metal reducing group is an aldehyde group.

4. The film according to claim 1, wherein the compound A includes a compound containing the metal coordinating group.

5. The film according to claim 4, wherein the metal coordinating group is a thioether group.

6. The film according to claim 4, wherein the metal coordinating group is a mercapto group.

7. The film according to claim 6, wherein the mercapto group is a mercapto group substituted with an aryl group.

8. The film according to claim 1, wherein an I/O ratio of the compound A is 0.20 or more.

9. The film according to claim 1, wherein an integrated absorbance value of the compound A at a wavelength range of 250 nm to 400 nm is 0 or more and 30 or less.

10. The film according to claim 1, wherein the compound A includes a compound containing a metal reducing group and a metal coordinating group.

11. The film according to claim 1, wherein a content of chloride ions of the resin layer is 50 ppm or less with respect to a total mass of the resin layer.

12. The film according to claim 1, wherein a content of the compound A of the resin layer is 0.01% by mass or more and 10% by mass or less with respect to a total mass of the resin layer.

13. The film according to claim 1, wherein the metal is a metal fiber.

14. The film according to claim 1, wherein the metal includes silver.

15. A touch panel comprising:
the film according to claim 1.

16. A method of suppressing deterioration of a metal in a film including the metal and a resin layer, wherein the resin layer contains a compound A containing at least one group selected from the group consisting of a metal reducing group and a metal coordinating group.

17. A laminate comprising, in the following order:
a substrate having a surface on which a metal conductive material is disposed;
a resin layer contains a compound A containing at least one group selected from the group consisting of a metal reducing group and a metal coordinating group; and
a UV absorbing layer in which an integrated absorbance for each 1 nm in a wavelength range of 300 nm to 400 nm is 10 or more.

18. The laminate according to claim 17, wherein the compound A contains at least one group selected from the group consisting of a thioether group and a mercapto group, as the metal coordinating group.

19. The laminate according to claim 17, wherein the compound A has an aromatic ring in a molecule.
